(19) United States
(12) Patent Application Publication
(10) Pub. No.: US 2024/0431178 A1
(43) Pub. Date: Dec. 26, 2024

(54) Display Apparatus, Electronic Device, And Operation Method Of Light-Emitting Apparatus

(71) Applicant: Semiconductor Energy Laboratory Co., Ltd, Kanagawa-ken (JP)

(72) Inventors: Kazuaki OHSHIMA, Atsugi, Kanagawa (JP); Tatsunori INOUE, Yamato, Kanagawa (JP)

(73) Assignee: Semiconductor Energy Laboratory Co., Ltd., Kanagawa-ken (JP)

(21) Appl. No.: 18/696,212

(22) PCT Filed: Sep. 22, 2022
(86) PCT No.: PCT/IB2022/058947

§ 371 Date: Mar. 27, 2024

(30) Foreign Application Priority Data
Sep. 30, 2021 (JP) 2021-161688

(51) Int. Cl. H10K 59/65; G02B 27/01

(52) U.S. Cl. CPC H10K 59/65; G02B 27/017; G02B 2027/0178

(57) ABSTRACT

A display apparatus capable of capturing an image and an electronic device with a reduced number of components are provided. The display apparatus includes a display portion including a first region and a second region. The first region includes an image capturing pixel, and the second region includes a light-emitting pixel. The light-emitting pixel includes a light-emitting device emitting one of infrared light and visible light, and the image capturing pixel includes a light-receiving device receiving one of infrared light and visible light. Specifically, the center portion of the display portion is a region of a circle centered at the intersection of two diagonal lines running across the display portion, and the radius of the circle is less than or equal to L/8, where L is the length of the diagonal line of the display portion. The first region and the center portion overlap with each other in a region. It is preferable that the second region have a tetragonal frame shape and the first region be positioned inside the frame shape.

### TECHNICAL FIELD

One embodiment of the present invention relates to a display apparatus, an electronic device, and an operation method of a light-emitting apparatus.

Note that one embodiment of the present invention is not limited to the above technical field. The technical field of the invention disclosed in this specification and the like relates to an object, a driving method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an image capturing apparatus, a memory device, a signal processing device, a processor, an electronic device, a system, a driving method thereof, a manufacturing method thereof, and a testing method thereof.

### BACKGROUND ART

Display apparatuses included in electronic devices for XR (Extended Reality or Cross Reality) such as VR (Virtual Reality) or AR (Augmented Reality), mobile phones such as smartphones, tablet information terminals, and notebook PCs (personal computers) have undergone improvements in recent years. For example, display apparatuses have been developed aiming for higher screen resolution, higher color reproducibility (NTSC ratio), a smaller driver circuit, lower power consumption, and the like.

In particular, eye tracking technology for XR electronic devices has been attracting attention. Eye tracking, a method in which the movement of an eyeball of a user is measured and a gaze destination of the user is tracked, is expected to be applied to a user interface for sports, education, marketing, danger sensing, health management, and an electronic device, for example. Thus, in recent years, a variety of gaze tracking methods have been proposed. For example, Patent Document 1 discloses a technique obtained by improving a cornea reflection method (a PCCR method), in which a cornea is irradiated with light and the movement of the eyeball is calculated from a captured image of the pupil and the reflection point of the light.

### REFERENCE

### Patent Document

[Patent Document 1] United States Patent Application Publication No. 2006/0238707

### SUMMARY OF THE INVENTION

### Problems to be Solved by the Invention

Eye tracking requires an image capturing apparatus for capturing an image of an eyeball and an image capturing light source for irradiating the eyeball with light. Therefore, an XR electronic device is sometimes configured such that the image capturing apparatus and the image capturing light source will be positioned around the eye of the user wearing the XR electronic device. In other words, the XR electronic device is sometimes provided with many image capturing apparatuses that will be positioned around the user's eye, and the portion of the XR electronic device that will be positioned around the user's eye is bulky in some cases. Conversely, combining the image capturing apparatus and the image capturing light source into one structure can make the XR electronic device less bulky.

The structure into which the image capturing apparatus and the image capturing light source are combined can be applied to a light-emitting apparatus provided in an electronic device (an imaging device) such as a microscope in some cases.

An object of one embodiment of the present invention is to provide a display apparatus capable of performing eye tracking. Another object of one embodiment of the present invention is to provide a display apparatus or a light-emitting apparatus capable of capturing an image. Another object of one embodiment of the present invention is to provide a less bulky electronic device. Another object of one embodiment of the present invention is to provide a novel display apparatus, a novel light-emitting apparatus, or a novel electronic device.

Another object of one embodiment of the present invention is to provide an operation method of a light-emitting apparatus capable of capturing an image. Another object of one embodiment of the present invention is to provide an operation method of a novel light-emitting apparatus.

Note that the objects of one embodiment of the present invention are not limited to the objects listed above. The objects listed above do not preclude the existence of other objects. Note that the other objects are objects that are not described in this section and will be described below. The objects that are not described in this section can be derived from the description of the specification, the drawings, or the like and can be extracted as appropriate from the description by those skilled in the art. Note that one embodiment of the present invention is to achieve at least one of the objects listed above and the other objects. Note that one embodiment of the present invention does not necessarily achieve all the objects listed above and the other objects.

### Means for Solving the Problems

(1)

One embodiment of the present invention is a display apparatus that includes a display portion including a first region and a second region. The first region includes an image capturing pixel, and the second region includes a light-emitting pixel. The light-emitting pixel includes a light-emitting device having a function of emitting one of infrared light and visible light, and the image capturing pixel includes a light-receiving device having a function of receiving light emitted from the light-emitting pixel. A center portion of the display portion is a region of a circle centered at an intersection of two diagonal lines running across the display portion. A radius of the circle is less than or equal to ⅛ of the diagonal line of the display portion. The first region includes a region overlapping with the center portion.

(2)

In (1), according to another embodiment of the present invention, the second region may have a tetragonal frame shape, and the first region may be positioned inside the frame shape.

(3)

Another embodiment of the present invention is an electronic device that includes the display apparatus in (1) or (2) and a housing. Specifically, the housing is shaped to be capable of being worn on a head of a human. When the housing is worn on a head of a human, the first region preferably includes a region overlapping with an eye of the human in a front view.

(4)

Another embodiment of the present invention is an operation method of a light-emitting apparatus that includes an image capturing portion including a plurality of light-emitting pixels and a plurality of image capturing pixels. The light-emitting pixels each include a light-emitting device emitting one of infrared light and visible light, and the image capturing pixels each include a light-receiving device receiving one of infrared light and visible light. The operation method of the light-emitting apparatus includes a first step and a second step. A first region is a region in which the light-receiving device included in the first region performs image capturing, a second region is a region in which the light-emitting device included in the second region emits light, and a third region is a region in which the light-emitting pixel and the image capturing pixel included in the third region are in a standby state. The first step includes a step of setting the first region, the second region, and the third region in the image capturing portion. The second step includes a step of resetting, to the second region or the third region, the first region set in the image capturing portion, resetting, to the first region or the third region, the second region set in the image capturing portion, and resetting, to the first region or the second region, part of the third region set in the image capturing portion.

(5)

Another embodiment of the present invention is an operation method of a light-emitting apparatus that includes an image capturing portion including a plurality of light-emitting pixels and a plurality of image capturing pixels and that is different from the light-emitting apparatus in (4) above. The light-emitting pixels each include a light-emitting device emitting one of infrared light and visible light, and the image capturing pixels each include a light-receiving device receiving one of infrared light and visible light. The operation method of the light-emitting apparatus includes a first step and a second step. A first region is a region in which the light-receiving device included in the first region performs image capturing, and a second region is a region in which the light-emitting device included in the second region emits light. The first step includes a step of setting the first region and the second region in the image capturing portion. The second step includes a step of resetting, to the second region, the first region set in the image capturing portion, and resetting, to the first region, the second region set in the image capturing portion.

### Effect of the Invention

According to one embodiment of the present invention, a display apparatus capable of performing eye tracking can be provided. According to another embodiment of the present invention, a display apparatus or a light-emitting apparatus capable of capturing an image can be provided. According to another embodiment of the present invention, a less bulky electronic device can be provided. According to another embodiment of the present invention, a novel display apparatus, a novel light-emitting apparatus, or a novel electronic device can be provided.

According to another embodiment of the present invention, an operation method of a light-emitting apparatus capable of capturing an image can be provided. According to another embodiment of the present invention, an operation method of a novel light-emitting apparatus can be provided.

Note that the effects of one embodiment of the present invention are not limited to the effects listed above. The effects listed above do not preclude the existence of other effects. Note that the other effects are effects that are not described in this section and will be described below. The effects that are not described in this section can be derived from the description of the specification, the drawings, or the like and can be extracted as appropriate from the description by those skilled in the art. Note that one embodiment of the present invention has at least one of the effects listed above and the other effects. Accordingly, depending circumstances, one embodiment of the present invention does not have the effects listed above in some cases.

### BRIEF DESCRIPTION OF THE DRAWINGS

FIG. 1A to FIG. 1C are schematic views illustrating examples of regions of a display portion provided in a display apparatus.

FIG. 2A and FIG. 2B are schematic views illustrating structure examples of an electronic device.

FIG. 3A to FIG. 3C are schematic views illustrating examples of regions of a display portion provided in a display apparatus.

FIG. 4A to FIG. 4E are schematic views illustrating examples of regions of a display portion provided in a display apparatus.

FIG. 5A to FIG. 5D are block diagrams illustrating examples of a pixel circuit included in a display apparatus.

FIG. 6A and FIG. 6B are schematic cross-sectional views illustrating structure examples of a display apparatus.

FIG. 7A is a schematic plan view illustrating an example of a display portion provided in a display apparatus, and FIG. 7B is a schematic plan view illustrating an example of a driver circuit region of the display apparatus.

FIG. 8 is a schematic plan view illustrating a structure example of a display apparatus.

FIG. 9 is a block diagram illustrating a structure example of part of a display apparatus.

FIG. 10 is a block diagram illustrating a structure example of a display apparatus.

FIG. 11A is a perspective view illustrating an example of an electronic device, FIG. 11B is a cross-sectional view illustrating the example of the electronic device, and FIG. 11C is a diagram illustrating an example of using the electronic device. FIG. 11D is a perspective view illustrating an example of an electronic device, and FIG. 11E is a diagram illustrating an example of using the electronic device.

FIG. 12A to FIG. 12E are schematic views illustrating examples of regions of an image capturing portion provided in a light-emitting apparatus.

FIG. 13 is a flowchart illustrating an operation example of a light-emitting apparatus.

FIG. 14A to FIG. 14D are schematic views illustrating examples of regions of an image capturing portion provided in a light-emitting apparatus.

FIG. 15 is a flowchart illustrating an operation example of a light-emitting apparatus.

FIG. 16 is a schematic cross-sectional view illustrating a structure example of a display apparatus.

FIG. 17A to FIG. 17D are schematic views illustrating structure examples of a light-emitting device.

FIG. 18 is a schematic cross-sectional view illustrating a structure example of a display apparatus.

FIG. 19A and FIG. 19B are schematic cross-sectional views illustrating structure examples of a display apparatus.

FIG. 20A and FIG. 20B are schematic cross-sectional views illustrating structure examples of a display apparatus.

FIG. 21A and FIG. 21B are schematic cross-sectional views illustrating structure examples of a display apparatus.

FIG. 22A and FIG. 22B are schematic cross-sectional views illustrating structure examples of a display apparatus.

FIG. 23A to FIG. 23F are cross-sectional views illustrating an example of a method for fabricating a display apparatus.

FIG. 24A is a circuit diagram illustrating a structure example of a pixel circuit included in a display apparatus, and FIG. 24B is a schematic perspective view illustrating the structure example of the pixel circuit included in the display apparatus.

FIG. 25A to FIG. 25D are circuit diagrams illustrating structure examples of pixel circuits included in a display apparatus.

FIG. 26A to FIG. 26D are circuit diagrams illustrating structure examples of pixel circuits included in a display apparatus.

FIG. 27A and FIG. 27B are plan views illustrating structure examples of light-emitting devices and light-receiving devices included in a display apparatus.

FIG. 28A to FIG. 28D are schematic cross-sectional views illustrating structure examples of light-emitting devices, light-receiving devices, and a connection electrode included in a display apparatus.

FIG. 29A to FIG. 29G are plan views illustrating examples of pixels.

FIG. 30A to FIG. 30F are plan views illustrating examples of pixels.

FIG. 31A to FIG. 31H are plan views illustrating examples of a pixel.

FIG. 32A to FIG. 32D are plan views illustrating examples of a pixel.

FIG. 33A to FIG. 33D are plan views illustrating examples of pixels, and FIG. 33E is a cross-sectional view illustrating an example of a display apparatus.

FIG. 34A and FIG. 34B are diagrams illustrating a structure example of a display module.

FIG. 35A to FIG. 35F are diagrams illustrating structure examples of an electronic device.

FIG. 36A to FIG. 36D are diagrams illustrating structure examples of electronic devices.

FIG. 37A to FIG. 37C are diagrams illustrating structure examples of an electronic device.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), a device including the circuit, or the like. The semiconductor device also means all devices that can function by utilizing semiconductor characteristics. For example, an integrated circuit, a chip including an integrated circuit, and an electronic component including a chip in a package are each an example of the semiconductor device. For example, a memory device, a display apparatus, a light-emitting apparatus, a lighting device, and an electronic device themselves are semiconductor devices in some cases and include a semiconductor device in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y. Note that a switch has a function of being controlled to be turned on or off. That is, the switch has a function of being in a conducting state (on state) or a non-conducting state (off state) to control whether current flows or not.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (a step-up circuit or a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

This specification describes a circuit structure in which a plurality of elements are electrically connected to a wiring (a wiring for supplying a constant potential or a wiring for transmitting a signal). For example, in the case where X is directly connected to a wiring and Y is directly connected to the wiring, this specification may describe that X and Y are directly electrically connected to each other.

The expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used, for example. Alternatively, the expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit structure is defined by an expression similar to the above examples, a source and a drain of a transistor can be distinguished from each other to specify the technical scope. Note that these expressions are examples and the expression is not limited to these expressions. Here, each of X and Y denotes an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” sometimes includes a wiring having a resistance value, a transistor in which current flows between its source and drain, a diode, and a coil. Thus, the term “resistor” can be sometimes replaced with the terms “resistance”, “load”, “region having a resistance value”, or the like. Conversely, the term “resistor”, “load”, “region having a resistance value”, or the like can be sometimes replaced with the term “resistor element”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The terms “capacitor”, “parasitic capacitance”, “gate capacitance”, and the like can be replaced with the term “capacitance” or the like in some cases. Conversely, the term “capacitance” can be replaced with the term “capacitor”, “parasitic capacitance”, “gate capacitance”, or the like in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, “pair of terminals”, or the like. In addition, the terms “one of a pair of terminals” and “the other of the pair of terminals” are sometimes referred to as a first terminal and a second terminal, respectively, for example. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conducting state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source”, “drain”, and the like can be sometimes rephrased with one another in this specification and the like. In this specification and the like, expressions “one of a source and a drain” (or a first electrode or a first terminal) and “the other of the source and the drain” (or a second electrode or a second terminal) are used in description of the connection relationship of a transistor. Depending on the transistor structure, a transistor may include a back gate in addition to the above three terminals. In that case, one of the gate and the back gate of the transistor may be referred to as a first gate and the other of the gate and the back gate of the transistor may be referred to as a second gate in this specification and the like. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

In this specification and the like, circuit elements such as a “light-emitting device” and a “light-receiving device” sometimes have polarities called an “anode” and a “cathode”. In the case of a “light-emitting device”, the “light-emitting device” can sometimes emit light when a forward bias is applied (a positive potential with respect to a “cathode” is applied to an “anode”). In the case of a “light-receiving device”, current is sometimes generated between an “anode” and a “cathode” when a zero bias or a reverse bias is applied (a negative potential with respect to a “cathode” is applied to an “anode”) and the “light-receiving device” is irradiated with light. As described above, an “anode” and a “cathode” are sometimes regarded as input/output terminals of the circuit elements such as a “light-emitting device” and a “light-receiving device”. In this specification and the like, an “anode” and a “cathode” of the circuit element such as a “light-emitting device” or a “light-receiving device” are sometimes called terminals (a first terminal, a second terminal, and the like). For example, one of an “anode” and a “cathode” is called a first terminal and the other of the “anode” and the “cathode” is called a second terminal in some cases.

The case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. For another example, the case where a single capacitor is illustrated in a circuit diagram may indicate a case where two or more capacitors are electrically connected to each other in parallel. For another example, the case where a single transistor is illustrated in a circuit diagram may indicate a case where two or more transistors are electrically connected to each other in series and their gates are electrically connected to each other. Similarly, for another example, the case where a single switch is illustrated in a circuit diagram may indicate a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal or a wiring can be referred to as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, “current” in this specification and the like refers to a charge transfer phenomenon (electrical conduction) caused by carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of current” in a wiring or the like refers to the direction in which a carrier with positive charge moves, and the amount of current is expressed as a positive value. In other words, the direction in which a carrier with negative charge moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A”, for example. The description “current is input to element A” can be rephrased as “current is output from element A”, for example.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relationship between components with reference to drawings. The positional relationship between components is changed as appropriate in accordance with the direction in which the components are described. Thus, the positional relationship is not limited to the terms described in the specification and the like, and can be described with another term as appropriate depending on the situation. For example, the expression “an insulator positioned over (on) the top surface of a conductor” can be replaced with the expression “an insulator positioned under (on) a bottom surface of a conductor” when the direction of a drawing showing these components is rotated by 180°.

Furthermore, the term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed over and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be changed into the term “conductive film” in some cases. For another example, the term “insulating film” can be changed into the term “insulating layer” in some cases. Alternatively, the terms “film” and “layer” are not used and can be interchanged with another term depending on circumstances or conditions. For example, the term “conductive layer” or “conductive film” can be changed into the term “conductor” in some cases. For another example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode”, “wiring”, or the like also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, or “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region” or the like depending on circumstances.

In this specification and the like, the terms “wiring”, “signal line”, “power supply line”, and the like can be interchanged with each other depending on circumstances or conditions. For example, the term “wiring” can be changed into the term “signal line” in some cases. For another example, the term “wiring” can be changed into the term “power supply line” or the like in some cases. Conversely, the term “signal line”, “power supply line”, or the like can be changed into the term “wiring” in some cases. The term “power supply line” or the like can be changed into the term “signal line” or the like in some cases. Conversely, the term “signal line” or the like can be changed into the term “power supply line” or the like in some cases. The term “potential” that is applied to a wiring can be changed into the term “signal” or the like depending on circumstances or conditions. Conversely, the term “signal” or the like can be changed into the term “potential” in some cases.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also collectively referred to as a metal oxide in some cases. A metal oxide containing nitrogen may be called a metal oxynitride.

In this specification and the like, an impurity in a semiconductor refers to, for example, an element other than a main component of a semiconductor layer. For example, an element with a concentration lower than 0.1 atomic % is an impurity. When an impurity is contained, for example, the density of defect states in a semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components; specific examples include hydrogen (contained also in water), lithium, sodium, silicon, boron, phosphorus, carbon, and nitrogen.

In this specification and the like, a switch has a function of being in a conducting state (on state) or a non-conducting state (off state) to control whether current flows or not. Alternatively, a switch has a function of selecting and changing a current path. Thus, a switch may include two or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device with a single structure includes one light-emitting unit between a pair of electrodes, and the light-emitting unit preferably includes one or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, a light-emitting device can be configured to emit white light as a whole. When white light emission is obtained using three or more light-emitting layers, a light-emitting device is configured to emit white light as a whole by combining emission colors of the three or more light-emitting layers.

A device with a tandem structure includes two or more light-emitting units between a pair of electrodes, and each light-emitting unit preferably includes one or more light-emitting layers. To obtain white light emission, the structure is made such that light from light-emitting layers of the plurality of light-emitting units can be combined to be white light. Note that a structure for obtaining white light emission is similar to that in the case of a single structure. In the device with a tandem structure, an intermediate layer such as a charge-generation layer is suitably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. To reduce power consumption, the light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, the structure described in each embodiment can be combined with the structures described in the other embodiments as appropriate to constitute one embodiment of the present invention. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be formed.

Embodiments described in this specification are described with reference to the drawings. Note that the embodiments can be implemented in many different modes, and it will be readily appreciated by those skilled in the art that modes and details can be changed in various ways without departing from the spirit and scope thereof. Therefore, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, some components might be omitted for clarity of the drawings.

In this specification, a plan view is sometimes used to explain a structure in each embodiment. A plan view is, for example, a diagram showing a plane of a structure seen in a direction perpendicular to a horizontal plane or a diagram showing a plane (section) of a structure cut in a horizontal direction (any of the planes is sometimes referred to as a plan view). Hidden lines (e.g., dashed lines) in a plan view can indicate the positional relationship between a plurality of components included in a structure or the overlapping relationship between the plurality of components. In this specification and the like, the term “plan view” can be replaced with the term “projection view”, “top view”, or “bottom view”. A plane (section) of a structure cut in a direction other than the horizontal direction may be referred to as a plan view depending on conditions.

In this specification, a cross-sectional view is sometimes used to explain a structure in each embodiment. A cross-sectional view is, for example, a diagram showing a plane of a structure seen in a direction perpendicular to a horizontal plane or a diagram showing a plane (section) of a structure cut in a perpendicular direction (any of the planes is sometimes referred to as a cross-sectional view). In this specification and the like, the term “cross-sectional view” can be replaced with the term “front view” or “side view”. A plane (section) of a structure cut in a direction other than the perpendicular direction may be referred to as a cross-sectional view depending on conditions.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes denoted without such identification signs in this specification and the like when the components do not need to be distinguished from each other.

In the drawings in this specification, the size, the layer thickness, or the region is exaggerated for clarity in some cases. Therefore, they are not limited to the illustrated scale. The drawings are schematic views showing ideal examples, and embodiments of the present invention are not limited to shapes, values, or the like shown in the drawings. For example, variations in signal, voltage, or current due to noise, variations in signal, voltage, or current due to difference in timing, or the like can be included.

### Embodiment 1

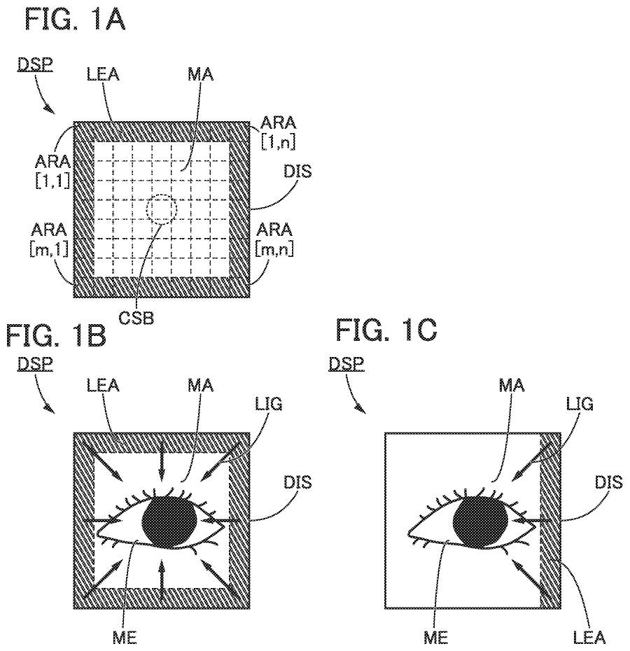

FIG. 1A illustrates a display apparatus of one embodiment of the present invention. A display apparatus DSP includes a display portion DIS, and the display portion DIS is divided into a plurality of display regions.

The display portion DIS is divided into m rows and n columns of display regions (m is an integer greater than or equal to 1, and n is an integer greater than or equal to 1), for example. Thus, the display portion DIS includes a region ARA[1,1] to a region ARA[m,n]. Note that FIG. 1A illustrates, as an example, the display portion DIS of the case where m=9 and n=9 (the case where the display portion is divided into 9 rows and 9 columns of display regions). In FIG. 1A, as examples, the reference numerals of the region ARA[1,1], the region ARA[m,1], the region ARA[1,n], and the region ARA[m,n] are selectively shown.

In each of the region ARA[1,1] to the region ARA[m,n], a plurality of display pixels and a plurality of image capturing pixels are arranged in a matrix, for example. The display pixels and the image capturing pixels will be described later. Each of the region ARA[1,1] to the region ARA[m,n] may include a plurality of light-emitting pixels functioning as image capturing light sources.

In particular, the display pixels included in the divided regions ARA are driven by driver circuits for display (e.g., a gate driver circuit and a source driver circuit) corresponding to the regions ARA. That is, in the display apparatus DSP in FIG. 1A, each of a plurality of the regions ARA is provided with the driver circuit for display.

The image capturing pixels included in the divided regions ARA are driven by driver circuits for image capturing (e.g., a circuit transmitting a trigger signal for performing image capturing and a circuit selecting image capturing pixels) corresponding to the regions ARA. That is, in the display apparatus DSP in FIG. 1A, each of the plurality of regions ARA is provided with the driver circuit for image capturing.

In the display portion DIS of the display apparatus DSP, an image capturing light source region LEA and an image capturing region MA are provided. Specifically, in the display apparatus DSP in FIG. 1A, the region ARA[1,1] to the region ARA[1,n] provided in the first row of the display portion DIS, the region ARA[m,1] to the region ARA[m,n] provided in the m-th row of the display portion DIS, the region ARA[2,1] to the region ARA[m−1,1] provided in the first column of the display portion DIS, and the region ARA[2,n] to the region ARA[m−1,n] provided in the n-th column of the display portion DIS serve as the image capturing light source region LEA, and the other regions ARA of the display portion DIS serve as the image capturing region MA.

That is, in FIG. 1A, the image capturing light source region LEA is set in the regions ARA positioned along the four sides of the display portion DIS, and the image capturing region MA is set in the other regions ARA of the display portion DIS. In other words, the image capturing light source region LEA has a tetragonal frame shape, and the image capturing region MA is set inside the frame shape.

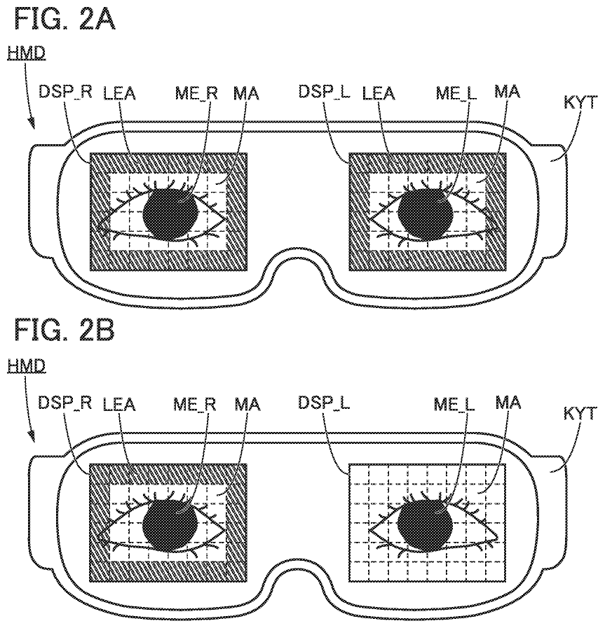

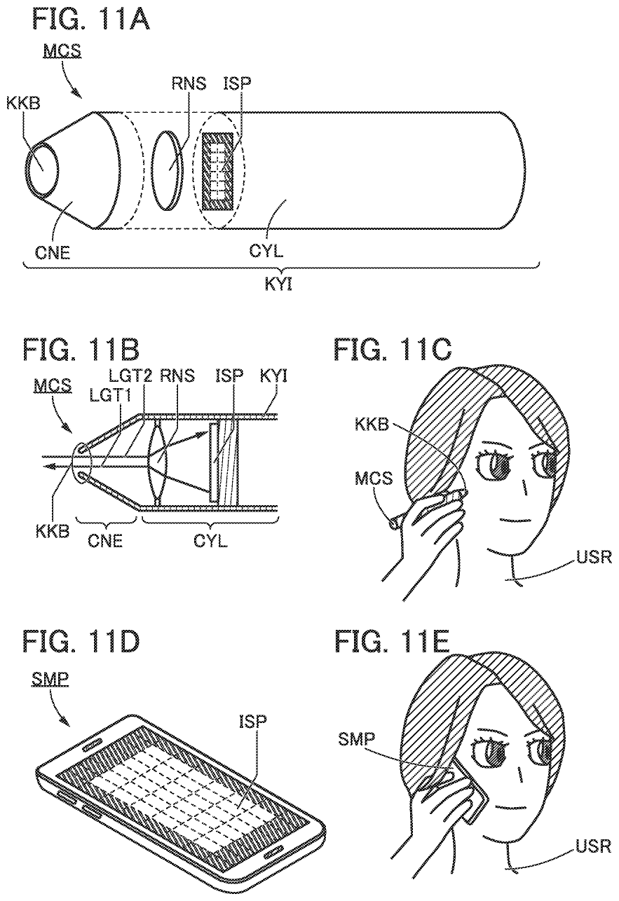

The image capturing region MA functions as a region for capturing an image of a subject with the use of the image capturing pixels of the plurality of regions ARA included in the image capturing region MA, for example. The image capturing region MA may function as a region for displaying an image with the use of the display pixels of the plurality of regions ARA included in the image capturing region MA, for example. For example, the image capturing region MA in the display apparatus DSP provided in an electronic device described later with reference to FIG. 2A and FIG. 2B and the image capturing region MA in a light-emitting apparatus ISP provided in an electronic device such as a smartphone SMP described later with reference to FIG. 11D and FIG. 11E each preferably function as a region for displaying an image as well as a region for capturing an image of a subject. Meanwhile, for example, the image capturing region MA in the light-emitting apparatus ISP provided in an electronic device illustrated in FIG. 11A to FIG. 11C functions as a region for capturing an image of a subject but does not necessarily function as a region for displaying an image.

The image capturing light source region LEA functions as a region that emits light necessary for an image capturing operation performed by the image capturing pixels of the plurality of regions ARA included in the image capturing region MA, for example. The circuits that emit the light can be the display pixels. In the case where the regions ARA of the image capturing light source region LEA include the display pixels and the light-emitting pixels, the circuits that emit the light can be the light-emitting pixels.

In the display apparatus of one embodiment of the present invention, the image capturing region MA of the display portion DIS may be defined first, and the image capturing light source region LEA may be set in the remaining region of the display portion DIS. In that case, the image capturing region MA is preferably set to overlap with a center portion CSB of the display portion DIS as illustrated in FIG. 1A. Therefore, the display apparatus DSP preferably includes a region where the center portion CSB of the display portion DIS overlaps with some of the plurality of regions ARA included in the image capturing region MA.

In this specification and the like, the center portion of the display portion DIS refers to a region that includes the intersection of two diagonal lines running across the display portion DIS. Specifically, the center portion of the display portion DIS can be a region of a circle centered at the intersection of the two diagonal lines. The radius of the circle is preferably less than or equal to L/8, further preferably less than or equal to L/16, still further preferably less than or equal to L/32, yet still further preferably less than or equal to L/64, yet still further preferably less than or equal to L/128, where L is the length of the diagonal line (the diagonal size) of the display portion DIS.

For example, the radius of the circle in the center portion is less than or equal to L/8, where L is the diagonal size, in the case where the display portion DIS of the display apparatus DSP has a screen ratio (aspect ratio) of 16:9 and is divided into 4 rows and 8 columns of regions. For another example, the radius of the circle in the center portion is less than or equal to L/16, where L is the diagonal size, in the case where the display portion DIS of the display apparatus DSP has a screen ratio (aspect ratio) of 16:9 and is divided into 8 rows and 16 columns of regions.

Thus, the shape of the image capturing light source region LEA can be any of a variety of shapes, without being limited to the shape shown in FIG. 1A.

### <Eye Tracking>

Here, an electronic device (a head-mounted display) as a VR device provided with the display apparatus DSP is considered.

Since the electronic device is provided with the display apparatus DSP, an image of an eye of the user wearing the electronic device can be captured by the display apparatus DSP. In addition, capturing an image of the user's eye enables the electronic device to perform eye tracking (gaze tracking).

For example, an image of a user's eye ME can be captured by the display apparatus DSP provided in the electronic device when the position of the display apparatus DSP is set such that the display portion DIS of the display apparatus DSP overlaps with the user's eye ME in a front view as illustrated in FIG. 1B.

In that case, the image of the user's eye ME is preferably captured by the image capturing pixels in the plurality of regions ARA included in the image capturing region MA. During the image capturing, the display pixels or the light-emitting pixels included in the image capturing light source region LEA serve as image capturing light sources.

As illustrated in FIG. 1B, when the image capturing light source region LEA is set in the display portion DIS to surround the user's eye ME in a front view, the user's eye ME positioned inside the image capturing light source region LEA can be irradiated with light LIG for image capturing from the image capturing light source region LEA. In addition, since the image capturing light source region LEA surrounds the user's eye ME in a front view, a plurality of rays of the light LIG are emitted from the image capturing light source region LEA toward the center of the user's eye ME. Accordingly, the user's eye ME is irradiated evenly with the light LIG, and thus, shadows are inhibited.

As illustrated in FIG. 1C, the image capturing light source region LEA may be set at the right end of the display portion DIS in a front view. In that case, the image capturing region MA is wider than that in FIG. 1B, so that a larger image can be displayed with the display pixels included in the regions ARA of the image capturing region MA.

Meanwhile, in the case where the image capturing light source region LEA is set at the right end of the display portion DIS as illustrated in FIG. 1C, the distance between the right side of the user's eye ME and the image capturing light source region LEA is short, so that the right side of the user's eye ME is likely to be irradiated with the light LIG from the image capturing light source region LEA. By contrast, the distance between the left side of the user's eye ME and the image capturing light source region LEA is long, so that the left side of the user's eye is unlikely to be irradiated with the light LIG from the image capturing light source region LEA. That is, the amount of light (sometimes referred to as intensity of light) irradiated from the image capturing light source region LEA onto the right side of the user's eye ME is different from the amount of light irradiated from the image capturing light source region LEA onto the left side of the user's eye ME. In the case where the image capturing light source region LEA is set at the right end of the display portion DIS as illustrated in FIG. 1C, a region not irradiated with the light LIG (shadow) may be generated unlike in FIG. 1B. Therefore, to capture a clear image of the user's eye ME, the image capturing light source region LEA preferably has the shape illustrated in FIG. 1B.

When the image capturing light source region LEA is set in the display portion DIS to surround the user's eye ME in a front view as illustrated in FIG. 1B, the region of the user's eye ME can be irradiated substantially uniformly with light from the image capturing light source region LEA, making it possible to capture a clear image of the user's eye ME. Capturing a clear image of the user's eye ME enables highly accurate eye tracking.

Note that the image capturing is preferably performed by a method in which all the image capturing pixels in the plurality of regions ARA included in the image capturing region MA of the display apparatus DSP perform image capturing at a time (sometimes referred to as global shutter method). Alternatively, a method may be employed in which the plurality of regions ARA included in the image capturing region MA are sequentially selected and image capturing is performed. In this method, the plurality of image capturing pixels in the region ARA included in the image capturing region MA may perform image capturing at a time or sequentially. In the case where sequential image capturing is performed, the image capturing is preferably performed at a high frame frequency.

### <Structure Example of Electronic Device>

FIG. 2A illustrates, as an example, an electronic device HMD that is provided with the display apparatus DSP and that is a head-mounted display, a type of a VR device.

The electronic device HMD includes a housing KYT, for example. The housing KYT is shaped to be capable of being worn on a human head. The housing KYT is provided with a display apparatus DSP_L and a display apparatus DSP_R, each of which corresponds to the display apparatus DSP described above.

Specifically, the display apparatus DSP_L is provided in the housing KYT so as to be in front of a left eye ME_L of a user who wears the electronic device HMD. That is, in a front view, the left eye ME_L of the user and the display apparatus DSP_L overlap with each other in a region. The display apparatus DSP_R is provided in the housing KYT so as to be in front of the right eye of the user who wears the electronic device HMD. That is, in a front view, a right eye ME_R of the user and the display apparatus DSP_R overlap with each other in a region.

In the case where the electronic device HMD performs eye tracking, the display apparatus DSP_L and the display apparatus DSP_R can respectively track a gaze of the left eye of the user and a gaze of the right eye of the user as illustrated in FIG. 2A.

The electronic device HMD may perform eye tracking for one of the left eye and the right eye, instead of both eyes. For example, to perform eye tracking for the left eye, the image capturing light source region LEA may be provided in the display portion DIS of the display apparatus DSP_L as illustrated in FIG. 2B, and an image of the left eye may be captured with the image capturing pixels included in the image capturing region MA. Here, the image capturing light source region LEA is not necessarily provided in the display portion DIS of the display apparatus DSP_R, in which case the entire display portion DIS is the image capturing region MA.

Although FIG. 2B illustrates the case where eye tracking is performed for the left eye, the display apparatus DSP_L and the display apparatus DSP_R may be replaced with each other and eye tracking may be performed for the right eye.

### <Image Display Depending on Difference in Image Capturing Light Source>

Here, a difference in an image displayed on the display apparatus DSP due to a difference in an image capturing light source is described.

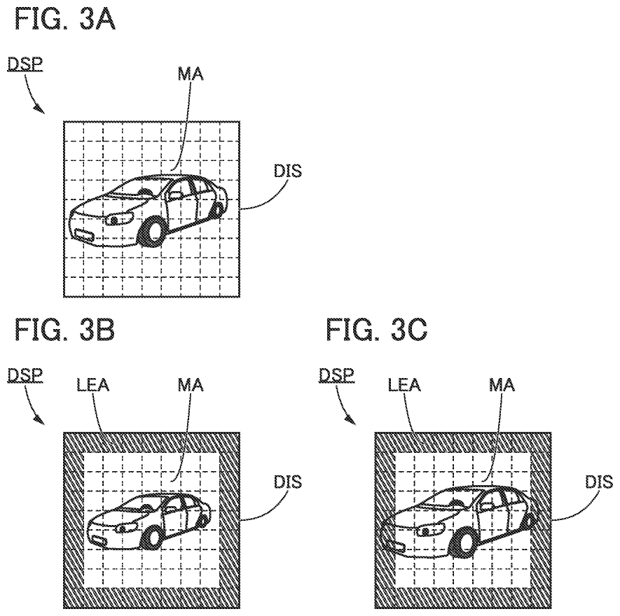

FIG. 3A illustrates a state of an image displayed on the image capturing region MA of the display portion DIS of the case where the image capturing light source region LEA is not provided in the display portion DIS (i.e., the case where image capturing is not performed). Note that FIG. 3A illustrates, as an example, a state where an automobile is displayed on the image capturing region MA.

Next, the case is considered where light emitted from the image capturing light source region LEA of the display apparatus DSP is visible light. That is, the case is considered where the display pixels or the light-emitting pixels included in the regions ARA of the image capturing light source region LEA are the circuits that emit visible light. In this case, the image capturing pixels included in the regions ARA of the image capturing region MA each include a light-receiving device that receives visible light.

In the display apparatus DSP in FIG. 1A, the regions ARA positioned along the four sides of the display portion DIS are used as the image capturing light source region LEA and accordingly, the region that can display an image on the display portion DIS is the remaining image capturing region MA. Specifically, the display pixels or the light-emitting pixels included in the regions ARA positioned along the four sides of the display portion DIS serve as light sources for image capturing, making it difficult to display an image on the image capturing light source region LEA.

Thus, the image capturing region MA in the display portion DIS in FIG. 1A is smaller than the image capturing region MA in the display portion DIS in FIG. 3A. For example, when the display apparatus DSP in FIG. 1A displays the same image as that in FIG. 3A, the image is as illustrated in FIG. 3B. That is, the image displayed on the image capturing region MA of the display portion DIS in which the image capturing light source region LEA in FIG. 1A is set is scaled down as compared with the image displayed on the display portion DIS in FIG. 3A.

Meanwhile, the case is considered where light emitted from the image capturing light source region LEA of the display apparatus DSP is infrared light (which is sometimes referred to as IR). In this case, the regions ARA of the image capturing light source region LEA each include a plurality of light-emitting pixels emitting infrared light. Furthermore, in this case, the image capturing pixels included in the regions ARA of the image capturing region MA each include a light-receiving device that receives infrared light.

The user's eye ME cannot perceive infrared light, which is invisible. Thus, when light that contains visible light and invisible light enters the user's eye ME, the user's eye ME can perceive only the visible light.

For example, when the display pixels included in the regions ARA of the image capturing light source region LEA emit light corresponding to an image and similarly, the light-emitting pixels included in the regions ARA emit infrared light in the display apparatus DSP in FIG. 1A, the user's eye ME can perceive only the light from the display pixels.

Thus, when the light emitted from the image capturing light source region LEA is infrared light, the image capturing light source region LEA can also perform image display. In that case, when the display apparatus DSP in FIG. 1A displays the same image as that in FIG. 3A, for example, the image is as illustrated in FIG. 3C. That is, the display portion DIS in which the image capturing light source region LEA in FIG. 1A is set can display an image having the same size as the image in FIG. 3A.

### <Shape of Image Capturing Light Source Region LEA>

Although the regions ARA positioned along the four sides of the display portion DIS of the display apparatus DSP are used as the image capturing light source region LEA in the example illustrated in FIG. 1A, the image capturing light source region LEA in the display portion DIS of the display apparatus DSP of one embodiment of the present invention is not necessarily set as illustrated in FIG. 1A.

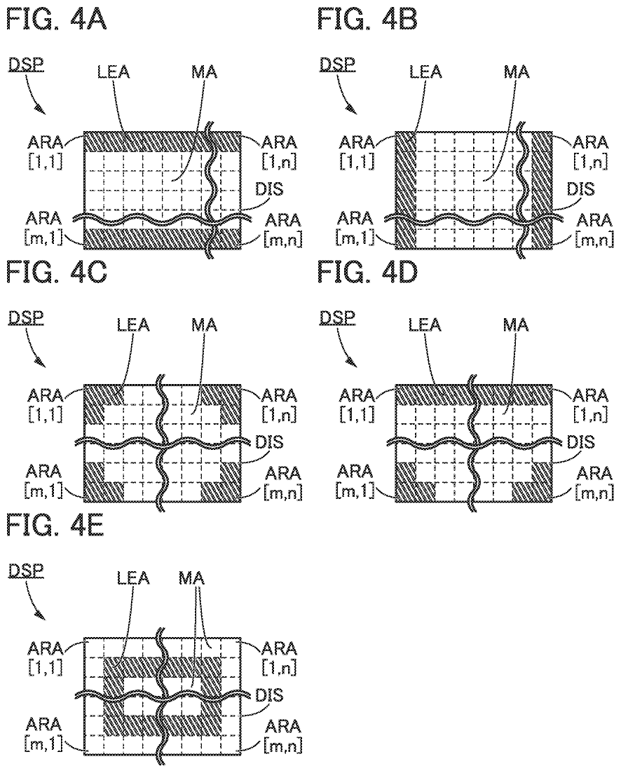

For example, as illustrated in FIG. 4A, the image capturing light source regions LEA set in the display portion DIS of the display apparatus DSP may be the region ARA[1,1] to the region ARA[1,n] provided in the first row of the display portion DIS and the region ARA[m,1] to the region ARA[m,n] provided in the m-th row of the display portion DIS.

For another example, as illustrated in FIG. 4B, the image capturing light source regions LEA set in the display portion DIS of the display apparatus DSP may be the region ARA[1,1] to the region ARA[m,1] provided in the first column of the display portion DIS and the region ARA[1,n] to the region ARA[m,n] provided in the n-th column of the display portion DIS.

For another example, the image capturing light source regions LEA set in the display portion DIS of the display apparatus DSP may be the regions ARA at the corners of the display portion DIS and the nearby regions ARA. Specifically, as illustrated in FIG. 4C, the image capturing light source regions LEA may be the region ARA[1,1], the region ARA[m,1], the region ARA[1,n], the region ARA[m,n], and the nearby regions ARA in the display portion DIS, for example.

For another example, the image capturing light source region LEA set in the display portion DIS of the display apparatus DSP may have a shape formed by combining the image capturing light source regions LEA illustrated in FIG. 4A to FIG. 4C. For example, as illustrated in FIG. 4D, the image capturing light source regions LEA may be the region ARA[1,1] to the region ARA[1,n] provided in the first row of the display portion DIS, the region ARA[m,1] and the nearby regions ARA, and the region ARA[m,n] and the nearby regions ARA.

For another example, unlike in FIG. 4A to FIG. 4D, the image capturing light source region LEA set in the display portion DIS of the display apparatus DSP is not necessarily set in the peripheral regions ARA of the display portion DIS. For example, as illustrated in FIG. 4E, the peripheral regions ARA and the central regions ARA of the display portion DIS may be the image capturing regions MA, and the other regions ARA may be the image capturing light source region LEA.

In the case where the image capturing region MA and the image capturing light source regions LEA of the display apparatus DSP are arranged as shown in any one of FIG. 4A to FIG. 4D, image capturing is preferably performed by a global shutter method, in which all the image capturing pixels in the plurality of regions ARA included in the image capturing region MA perform image capturing at a time. Alternatively, a method may be employed in which the plurality of regions ARA included in the image capturing region MA are sequentially selected and image capturing is performed.

### <Display Pixel, Image Capturing Pixel, and Light-Emitting Pixel>

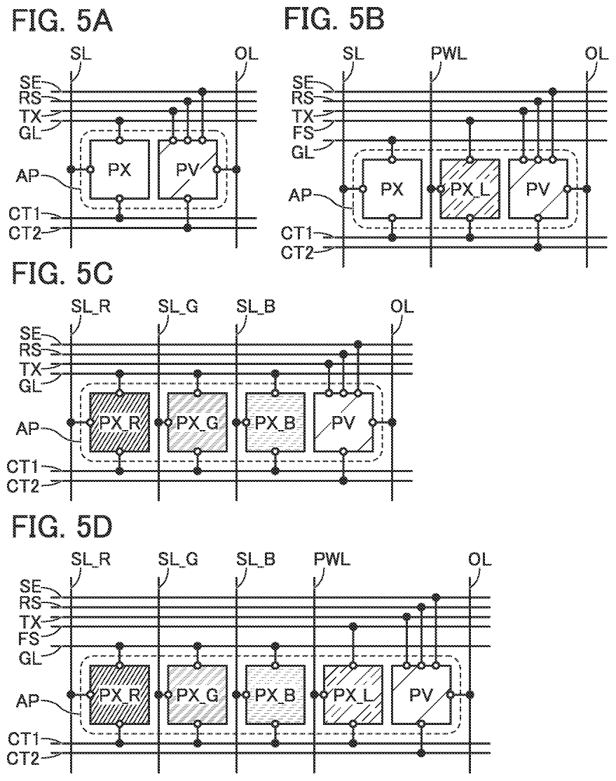

FIG. 5A is a block diagram illustrating a display pixel and an image capturing pixel that can be provided in the region ARA of the display apparatus DSP. A circuit AP illustrated in FIG. 5A includes a circuit PX and a circuit PV.

The circuit PX has a function of a display pixel, for example. The display pixel can be, for example, a pixel including at least one of a liquid crystal display device and a light-emitting device. Examples of the light-emitting device include a light-emitting device containing an organic EL material and an LED (including a micro LED). Note that in the description in this embodiment, the circuit PX includes a light-emitting device containing an organic EL material. In particular, the luminance of light emitted from a light-emitting device capable of emitting light with high luminance can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m². Note that the structure of the display pixel applicable to the circuit PX or the like will be described in detail in Embodiment 3.

The circuit PV has a function of an image capturing pixel, for example. The image capturing pixel includes a light-receiving device functioning as an image capturing device, for example.

The circuit PX is electrically connected to a wiring SL, a wiring GL, and a wiring CT1, for example.

The wiring SL functions as a wiring transmitting an image data signal to the circuit PX, for example. Alternatively, the wiring SL may be, for example, a wiring supplying a constant potential or a variable potential (e.g., a pulse voltage).

The wiring GL functions as a wiring transmitting a selection signal for selecting the circuit PX to be a supply destination of an image data signal, for example. Alternatively, the wiring GL may be, for example, a wiring supplying a constant potential.

The wiring CT1 functions as a wiring supplying a constant potential to the circuit PX, for example. The wiring CT1 is electrically connected to a terminal of the light-emitting device included in the circuit PX, for example. In this case, the constant potential is preferably a ground potential or a negative potential, for example. Alternatively, the wiring CT1 may be a wiring supplying a variable potential (e.g., a pulse voltage), for example.

The circuit PV is electrically connected to a wiring TX, a wiring RS, a wiring SE, a wiring OL, and a wiring CT2, for example.

The wiring TX functions as a wiring transmitting a trigger signal for making the light-receiving device included in the circuit PV perform image capturing, for example. Alternatively, the wiring TX may be, for example, a wiring supplying a constant potential.

The wiring RS functions as a wiring transmitting a trigger signal for erasing image capturing data captured by the light-receiving device included in the circuit PV, for example. Note that an operation of erasing image capturing data can be rephrased as, for example, an initialization operation of a potential corresponding to image capturing data retained in the circuit PV that is performed to allow the circuit PV to perform another image capturing. Alternatively, the wiring RS may be, for example, a wiring supplying a constant potential.

The wiring SE functions as a wiring transmitting a trigger signal for reading image capturing data captured by the light-receiving device included in the circuit PV, for example. Alternatively, the wiring SE may be, for example, a wiring supplying a constant potential.

The wiring OL functions as a wiring transmitting, as a signal, image capturing data captured by the light-receiving device included in the circuit PV, for example. Alternatively, the wiring OL may be, for example, a wiring supplying a constant potential, a variable potential (e.g., a pulse voltage), or the like.

The wiring CT2 functions as a wiring supplying a constant potential to the circuit PV. The wiring CT2 is electrically connected to a terminal of the light-receiving device included in the circuit PV, for example.

Although various wirings are illustrated in FIG. 5A, a wiring other than the wiring SL, the wiring GL, the wiring TX, the wiring RS, the wiring SE, the wiring OL, the wiring CT1, and the wiring CT2 may be electrically connected to one or both of the circuit PX and the circuit PV. For example, although not illustrated in FIG. 5A, a wiring supplying a power supply voltage for driving one or both of the circuit PX and the circuit PV may be electrically connected to the circuit AP.

The number of at least one of the various wirings illustrated in FIG. 5A may be two or more. For example, the number of wirings GL illustrated in FIG. 5A may be two or more. For another example, the number of wirings RS illustrated in FIG. 5A may be two or more.

Although FIG. 5A illustrates the structure of the circuit AP that includes the circuit PX functioning as the display pixel and the circuit PV functioning as the image capturing pixel, the circuit AP may include a light-emitting element functioning as an image capturing light source. For example, as illustrated in FIG. 5B, the circuit AP may include a circuit PX_L that includes a light-emitting element functioning as an image capturing light source, in addition to the circuit PX and the circuit PV.

The circuit PX_L includes a light-emitting device, for example. The light-emitting device preferably emits white light, for example, in the case where the light-receiving device included in the circuit PV has a function of receiving white light. The light-emitting device preferably emits infrared light, for example, in the case where the light-receiving device included in the circuit PV has a function of receiving infrared light.

The circuit PX_L is electrically connected to a wiring PWL, a wiring FS, and the wiring CT1, for example.

The wiring PWL functions as, for example, a wiring supplying a constant potential or a constant current to the light-emitting device included in the circuit PX_L.

The wiring CT1 functions as a wiring supplying a constant potential to the circuit PX_L as well as the circuit PX, for example. The wiring CT1 is electrically connected to a terminal of the light-emitting device included in the circuit PX_L, for example.

The wiring FS functions as, for example, a wiring to which a trigger signal for making the light-emitting device included in the circuit PX_L emit light is transmitted when image capturing is performed in the circuit PV. For example, the circuit PX_L can be configured such that supply of the trigger signal to the wiring FS causes a constant potential or a constant current to be supplied from the wiring PWL to the light-emitting device included in the circuit PX_L to make the light-emitting device emit light.

Note that in the case where the light-receiving device included in the circuit PV has a function of receiving white light, the circuit PX may be used as an image capturing light source, not as a display pixel. That is, in that case, the circuit AP does not necessarily include the circuit PX_L, which is an image capturing light source, as illustrated in FIG. 5A.

Although FIG. 5A illustrates the structure in which the circuit AP includes one circuit PX as the display pixel, the circuit AP may include a plurality of display pixels. In particular, the plurality of display pixels can exhibit, for example, three colors of red (R), green (G), and blue (B). Alternatively, for example, the plurality of display pixels may exhibit four or more colors; at least one color selected from cyan (C), magenta (M), yellow (Y), and white (W) may be exhibited in addition to the above-described three colors of red (R), green (G), and blue (B). Note that in the case where display pixels expressing different colors are each called a sub-display pixel and white is expressed by a plurality of sub-display pixels expressing different colors, the plurality of sub-display pixels are sometimes collectively called a display pixel.

FIG. 5C illustrates the structure of the circuit AP that includes three display pixels of a circuit PX_R serving as a red (R) display pixel, a circuit PX_G serving as a green (G) display pixel, and a circuit PX_B serving as a blue (B) display pixel, for example. In FIG. 5C, a wiring SL_R, a wiring SL_G, and a wiring SL_B that correspond to the wiring SL in FIG. 5A are illustrated; the wiring SL_R is electrically connected to the circuit PX_R, the wiring SL_G is electrically connected to the circuit PX_G, and the wiring SL_B is electrically connected to the circuit PX_B, for example.

Note that the arrangement order of the display pixels and the image capturing pixel is not limited to the order illustrated in FIG. 5C, and the arrangement order may be changed depending on conditions.

In the case where the circuit AP in FIG. 5C needs to include an image capturing light source in addition to the circuit PX_R, the circuit PX_G, and the circuit PX_B, the circuit AP in FIG. 5C may be provided with the above-described circuit PX_L as illustrated in FIG. 5D.

### <Structure Example of Display Apparatus>

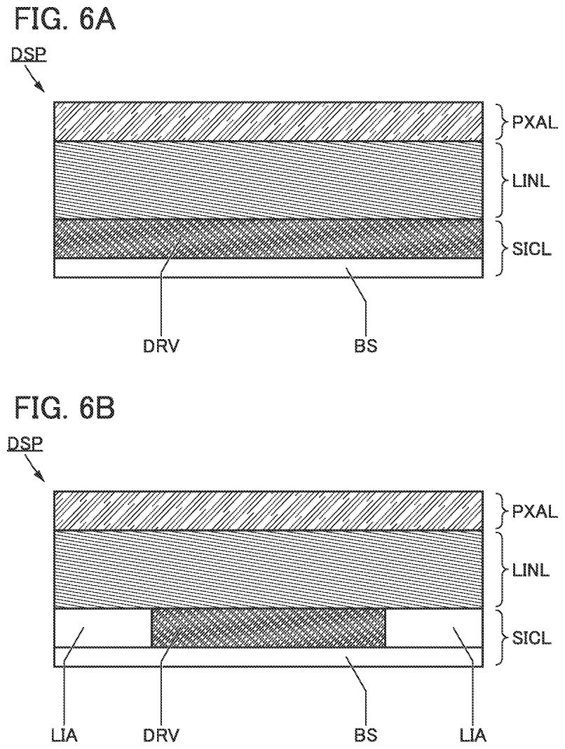

Next, a specific structure example of the display apparatus DSP in FIG. 1A is described. FIG. 6A is a schematic cross-sectional view of the display apparatus DSP in FIG. 1A. The display apparatus DSP includes a pixel layer PXAL, a wiring layer LINL, and a circuit layer SICL, for example.

The wiring layer LINL is provided over the circuit layer SICL, and the pixel layer PXAL is provided over the wiring layer LINL. Note that the pixel layer PXAL overlaps with a region including a later-described driver circuit region DRV.

The circuit layer SICL includes a substrate BS and the driver circuit region DRV.

As the substrate BS, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate BS. Examples of the glass substrate include barium borosilicate glass, aluminoborosilicate glass, and soda lime glass. As examples of the flexible substrate, the attachment film, and the base material film, plastics typified by polyethylene terephthalate (PET), polyethylene naphthalate (PEN), polyether sulfone (PES), and polytetrafluoroethylene (PTFE) can be given. Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the fabrication process of the display apparatus DSP includes heat treatment, a highly heat-resistant material is preferably selected for the substrate BS.

In the description of this embodiment, the substrate BS is a semiconductor substrate containing silicon as a material. Therefore, a transistor included in the driver circuit region DRV can be a transistor including silicon in a channel formation region (hereinafter referred to as a Si transistor).

The driver circuit region DRV is provided over the substrate BS.

The driver circuit region DRV includes, for example, a driver circuit for driving a pixel included in the pixel layer PXAL to be described later. Note that a specific structure example of the driver circuit region DRV will be described later.

The wiring layer LINL is provided over the circuit layer SICL.

A wiring is provided in the wiring layer LINL, for example. The wiring included in the wiring layer LINL functions as, for example, a wiring that electrically connects the driver circuit included in the driver circuit region DRV provided below the wiring layer LINL and the circuit included in the pixel layer PXAL provided above the wiring layer LINL.

The pixel layer PXAL includes, for example, a plurality of display pixels (e.g., the circuits PX in FIG. 5A or the circuits PX_R, the circuits PX_G, or the circuits PX_B in FIG. 5C), and a plurality of image capturing pixels (e.g., the circuits PV in FIG. 5A). The plurality of display pixels and the plurality of image capturing pixels may be arranged in a matrix in the pixel layer PXAL. In some cases, the pixel layer PXAL may include a plurality of the circuits PX_L functioning as image capturing light sources, as illustrated in FIG. 5B and FIG. 5D.

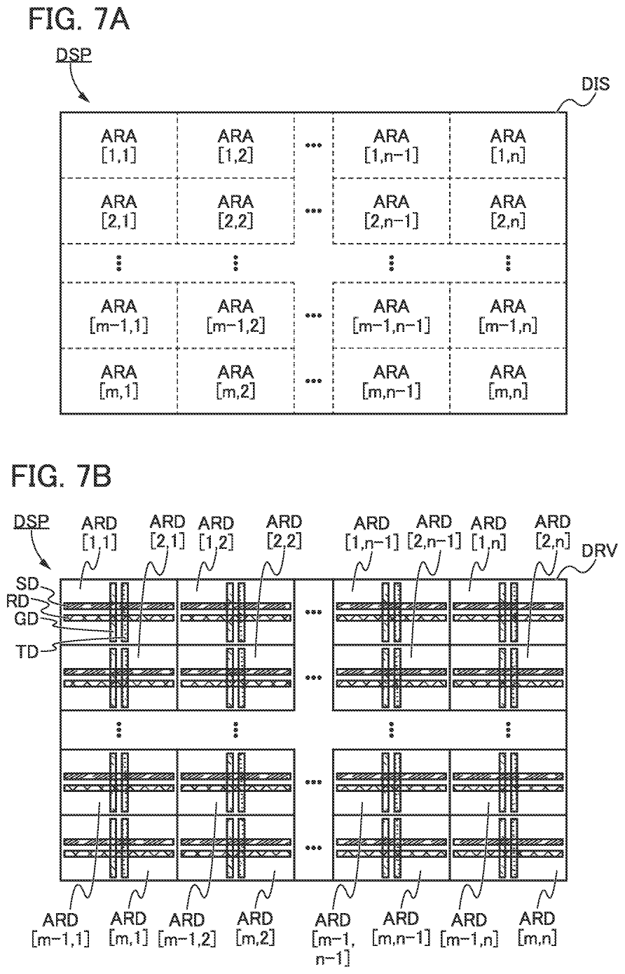

FIG. 7A is an example of a plan view of the display apparatus DSP and illustrates only the display portion DIS. Note that the display portion DIS can be a plan view of the pixel layer PXAL.

In the display apparatus DSP in FIG. 7A, the display portion DIS is divided into m rows and n columns of regions (m is an integer greater than or equal to 1, and n is an integer greater than or equal to 1), for example. Thus, the display portion DIS includes the region ARA[1,1] to the region ARA[m,n]. Note that FIG. 7A selectively illustrates, as examples, the region ARA[1,1], the region ARA[2,1], the region ARA[m−1,1], the region ARA[m,1], the region ARA[1,2], the region ARA[2,2], the region ARA[m−1,2], the region ARA[m,2], the region ARA[1,n−1], the region ARA[2,n−1], the region ARA[m−1,n−1], the region ARA[m,n−1], the region ARA[1,n], the region ARA[2,n], the region ARA[m−1,n], and the region ARA[m,n].

For example, in the case where the display portion DIS is to be divided into 32 regions, m=4 and n=8 in FIG. 7A. In the case where the display apparatus DSP has a definition of 8K4K, the number of display pixels is 7680×4320. In the case where the colors of sub-display pixels of the display portion DIS are three colors, red (R), green (G), and blue (B), the total number of sub-display pixels is 7680× 4320×3. Here, in the case where a pixel array of the display portion DIS with a definition of 8K4K is divided into 32 regions, the number of display pixels per region is 960×1080, and when the colors of the sub-display pixels of the display apparatus DSP are three colors, red (R), green (G), and blue (B), the number of sub-display pixels per region is 960×1080×3.

Here, the driver circuit region DRV included in the circuit layer SICL of the case where the display portion DIS of the display apparatus DSP in FIG. 7A is divided into m rows and n columns of regions is considered.

FIG. 7B is an example of a plan view of the display apparatus DSP, and illustrates only the driver circuit region DRV included in the circuit layer SICL.

Since the display portion DIS of the display apparatus DSP in FIG. 7A is divided into m rows and n columns of regions, each of the region ARA[1,1] to the region ARA[m,n] into which the display portion DIS is divided needs a corresponding driver circuit. Specifically, the driver circuit region DRV may also be divided into m rows and n columns of regions and a driver circuit may be provided in each of the divided regions.

The driver circuit region DRV of the display apparatus DSP in FIG. 7B is divided into m rows and n columns of regions. Thus, the driver circuit region DRV includes a circuit region ARD[1,1] to a circuit region ARD[m,n]. Note that FIG. 7B selectively illustrates, as examples, the circuit region ARD[1,1], the circuit region ARD[2,1], the circuit region ARD[m−1,1], the circuit region ARD[m,1], the circuit region ARD[1,2], the circuit region ARD[2,2], the circuit region ARD[m−1,2], the circuit region ARD[m,2], the circuit region ARD[1,n−1], the circuit region ARD[2,n−1], the circuit region ARD[m−1,n−1], the circuit region ARD[m,n−1], the circuit region ARD[1,n], the circuit region ARD[2,n], the circuit region ARD[m−1,n], and the circuit region ARD[m,n].

Each of the circuit region ARD[1,1] to the circuit region ARD[m,n] includes a driver circuit SD, a driver circuit GD, a driver circuit TD, and a driver circuit RD. For example, the driver circuit SD and the driver circuit GD included in the circuit region ARD[i,j] (not illustrated in FIG. 7B) positioned in the i-th row and the j-th column (i is an integer greater than or equal to 1 and less than or equal to m, and j is an integer greater than or equal to 1 and less than or equal to n) can drive a plurality of display pixels included in the region ARA[i,j] positioned in the i-th row and the j-th column of the display portion DIS. For example, the driver circuit TD and the driver circuit RD included in the circuit region ARD positioned in the i-th row and the j-th column can drive the image capturing pixel and the image capturing light source included in the region ARA[i,j] positioned in the i-th row and the j-th column of the display portion DIS.

The driver circuit SD functions as, for example, a source driver circuit that transmits an image signal to a plurality of display pixels included in the corresponding region ARA. The driver circuit SD may include a digital-analog conversion circuit that converts an image signal as digital data into analog data. Thus, the driver circuit SD is preferably electrically connected to the wiring SL (the wiring SL_R, the wiring SL_G, and the wiring SL_B) in each of FIG. 5A to FIG. 5D.

The driver circuit GD functions as, for example, a gate driver circuit for selecting a plurality of display pixels to which an image signal is transmitted in the corresponding region ARA. Thus, the driver circuit GD is preferably electrically connected to the wiring GL in each of FIG. 5A to FIG. 5D.

The driver circuit TD has a function of transmitting a trigger signal for making the circuit PV perform image capturing, a function of selecting the circuit PV row by row to read image capturing data from the circuit PV, and a function of transmitting a trigger signal for resetting the image capturing data retained in the circuit PV, for example. Thus, the driver circuit TD is preferably electrically connected to the wiring SE, the wiring RS, and the wiring TX in each of FIG. 5A to FIG. 5D.

The driver circuit RD has a function of retaining the image capturing data supplied from the circuit PV column by column and performing noise removal processing, for example. As the noise removal processing, for example, CDS (Correlated Double Sampling) processing or the like may be performed. The driver circuit RD may have a function of amplifying image capturing data, a function of performing AD conversion on image capturing data, or the like. Thus, the driver circuit RD is preferably electrically connected to the wiring OL in each of FIG. 5A to FIG. 5D.

Note that the display apparatus DSP illustrated in FIG. 6A, FIG. 7A, and FIG. 7B has a structure in which the region ARA[i,j] in the display portion DIS and the circuit region ARD[i,j] overlap with each other, but the display apparatus of one embodiment of the present invention is not limited to this structure. In a structure of the display apparatus of one embodiment of the present invention, the region ARA[i,j] and the circuit region ARD[i,j] do not necessarily overlap with each other.

For example, as illustrated in FIG. 6B, the display apparatus DSP may have a structure in which not only the driver circuit region DRV but also a region LIA is provided over the substrate BS.

A wiring is provided in the region LIA, for example. The wiring included in the region LIA may be electrically connected to a wiring included in the wiring layer LINL. In that case, the display apparatus DSP may have a structure in which a circuit included in the driver circuit region DRV and a circuit included in the pixel layer PXAL are electrically connected to each other through the wiring included in the region LIA and the wiring included in the wiring layer LINL. The display apparatus DSP may have a structure in which the circuit included in the driver circuit region DRV is electrically connected to the wiring or circuit included in the region LIA through the wiring included in the wiring layer LINL.

The region LIA may include a GPU (Graphics Processing Unit), for example. In the case where the display apparatus DSP includes a touch panel, the region LIA may include a sensor controller for controlling a touch sensor included in the touch panel. In the case where a liquid crystal element is used as a display element of the display apparatus DSP, the region LIA may include a gamma correction circuit. The region LIA may also include a controller having a function of processing an input signal from the outside of the display apparatus DSP. The region LIA may include a voltage generation circuit for generating a voltage to be supplied to the above-described circuit and the driver circuit included in the circuit region ARD.

In the case where a light-emitting device fabricated using an organic EL material is used as a display element of the display apparatus DSP, the region LIA may include an EL correction circuit. The EL correction circuit has a function of appropriately adjusting the amount of current input to the light-emitting device containing an organic EL material, for example. Since the emission luminance of the light-emitting device containing an organic EL material is proportional to current, the luminance of light emitted from the light-emitting device might be lower than a desired luminance when the characteristics of a driving transistor electrically connected to the light-emitting device are not favorable. For example, the EL correction circuit monitors the amount of current flowing through the light-emitting device and increases the amount of current flowing through the light-emitting device when the amount of current is smaller than a desired amount of current, whereby the luminance of light emitted from the light-emitting device can be increased. By contrast, when the amount of current is larger than a desired amount of current, the amount of current flowing through the light-emitting device may be adjusted to be small.

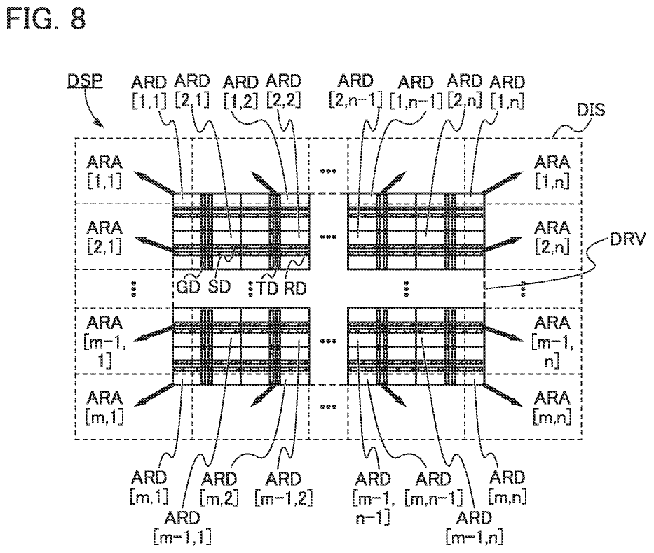

FIG. 8 is an example of a plan view of the display apparatus DSP illustrated in FIG. 6B and illustrates only the circuit layer SICL. The display apparatus DSP in FIG. 8 has an example structure in which the driver circuit region DRV is surrounded by the region LIA. Thus, as illustrated in FIG. 8, the driver circuit region DRV is provided to overlap with the inner portion of the display portion DIS in the plan view.

In the display apparatus DSP illustrated in FIG. 8, the display portion DIS is divided into the region ARA[1,1] to the region ARA[m,n] as in FIG. 7A, and the driver circuit region DRV is divided into the circuit region ARD[1,1] to the circuit region ARD[m,n].

In FIG. 8, a thick arrow indicates example relationship between the region ARA and the circuit region ARD that includes the driver circuit for driving the pixel included in the region ARA. Specifically, the driver circuit included in the circuit region ARD[1,1] drives the pixel included in the region ARA[1,1], and the driver circuit included in the circuit region ARD[2,1] drives the pixel included in the region ARA[2,1]. The driver circuit included in the circuit region ARD[m−1,1] drives the pixel included in the region ARA[m−1,1], and the driver circuit included in the circuit region ARD[m,1] drives the pixel included in the region ARA[m,1]. The driver circuit included in the circuit region ARD[1,n] drives the pixel included in the region ARA[1,n], and the driver circuit included in the circuit region ARD[2,n] drives the pixel included in the region ARA[2,n]. The driver circuit included in the circuit region ARD[m−1,n] drives the pixel included in the region ARA[m−1,n], and the driver circuit included in the circuit region ARD[m,n] drives the pixel included in the region ARA[m,n]. That is, although not illustrated in FIG. 8, the driver circuit included in the circuit region ARD[i,j] positioned in the i-th row and the j-th column drives the pixel included in the region ARA[i,j].

In FIG. 6B, when the driver circuit included in the circuit region ARD in the circuit layer SICL and the pixel included in the region ARA in the pixel layer PXAL are electrically connected to each other through a wiring included in the wiring layer LINL, the display apparatus DSP can have a structure in which the region ARA[i,j] and the circuit region ARD[i,j] do not necessarily overlap with each other. Accordingly, the positional relationship between the driver circuit region DRV and the display portion DIS is not limited to the plan view of the display apparatus DSP in FIG. 8, and the position of the driver circuit region DRV can be freely determined.

In the display apparatus of one embodiment of the present invention, the positions of the driver circuit SD, the driver circuit GD, the driver circuit TD, and the driver circuit RD in each of the circuit region ARD[1,1] to the circuit region ARD[m,n] are not limited to those in the structures illustrated in FIG. 7B and FIG. 8. The driver circuit SD, the driver circuit GD, the driver circuit TD, and the driver circuit RD do not necessarily have the shapes illustrated in FIG. 7B and FIG. 8 and may be arranged to have any of various shapes in one circuit region ARD, for example. In a plan view of the circuit region ARD, for example, the driver circuit SD, the driver circuit RD, the driver circuit GD, and the driver circuit TD may be placed in the upper left portion, the lower left portion, the upper right portion, and the lower right portion, respectively, without overlapping with one another.

The circuits included in the plurality of regions ARA can be driven independently when the display portion DIS is divided into the plurality of regions ARA and driver circuits corresponding to the respective regions ARA are provided as illustrated in FIG. 7A to FIG. 8.

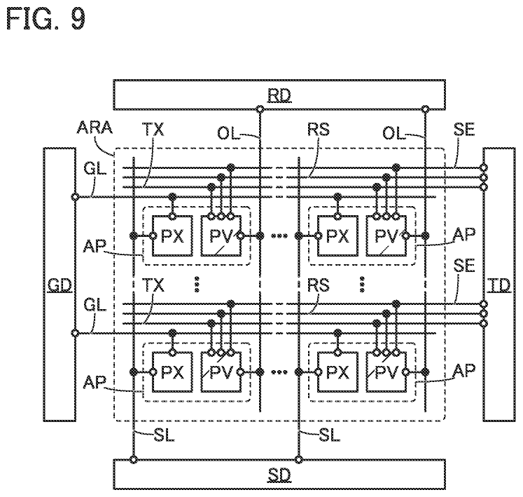

Next, a structure example of the region ARA will be described. FIG. 9 is a block diagram illustrating an example of the region ARA. In FIG. 9, the region ARA can include a plurality of the circuits AP shown in FIG. 5A, for example. Note that the circuit AP included in the region ARA may be any one of the circuits AP shown in FIG. 5B to FIG. 5D instead of the circuit AP shown in FIG. 5A.

FIG. 9 also illustrates the driver circuit SD, the driver circuit GD, the driver circuit TD, and the driver circuit RD to show electrical connection with the circuits AP included in the region ARA. Note that as illustrated in FIG. 6A to FIG. 8, the driver circuit SD, the driver circuit GD, the driver circuit TD, and the driver circuit RD overlap with the pixel layer PXAL that includes the region ARA; however, for convenience, FIG. 9 illustrates the driver circuit SD, the driver circuit GD, the driver circuit TD, and the driver circuit RD positioned outside the region ARA.

In FIG. 9, the plurality of circuits AP are arranged in a matrix in the region ARA. Thus, a plurality of the wirings GL, a plurality of the wirings SE, a plurality of the wirings RS, and a plurality of the wirings TX extend in the row direction in the region ARA. Similarly, a plurality of the wirings SL and a plurality of the wirings OL extend in the column direction in the region ARA.

The plurality of wirings GL are electrically connected to the driver circuit GD, for example. The plurality of wirings SL are electrically connected to the driver circuit SD, for example. The plurality of wirings SE, the plurality of wirings RS, and the plurality of wirings TX are electrically connected to the driver circuit TD, for example. The plurality of wirings OL are electrically connected to the driver circuit RD, for example.

The number of circuits AP included in one region ARA depends on the definition of the display portion DIS of the display apparatus DSP and the values of m and n shown in FIG. 7A, for example.

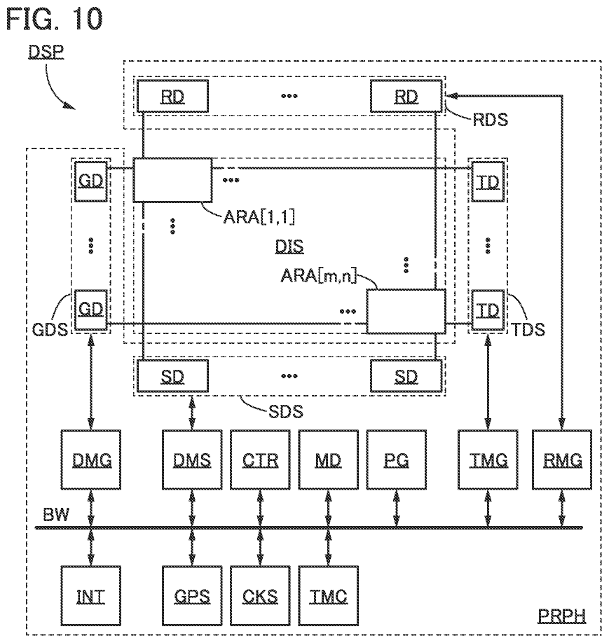

Next, examples of components included in the display apparatus DSP will be described. FIG. 10 is a block diagram illustrating an example of the display apparatus DSP. The display apparatus DSP shown in FIG. 10 includes the display portion DIS and a peripheral circuit PRPH.

The peripheral circuit PRPH includes a circuit GDS including a plurality of the driver circuits GD; a circuit SDS including a plurality of the driver circuits SD; a circuit RDS including a plurality of the driver circuits RD; a circuit TDS including a plurality of the driver circuits TD; a distribution circuit DMG; a distribution circuit DMS; a distribution circuit TMG; a distribution circuit RMG; a control portion CTR; a memory device MD; a voltage generation circuit PG; a timing controller TMC; a clock signal generation circuit CKS; an image processing portion GPS; and an interface INT.

Note that in the display apparatus DSP, the driver circuit region DRV including the plurality of driver circuits GD overlaps with the pixel layer PXAL including the plurality of regions ARA as illustrated in FIG. 6A to FIG. 8; however, FIG. 10 illustrates the plurality of driver circuits GD arranged in a column outside the display portion DIS, for convenience. Similarly, the driver circuit region DRV including the plurality of driver circuits SD overlaps with the pixel layer PXAL including the plurality of regions ARA; however, FIG. 10 illustrates the plurality of driver circuits SD arranged in a row outside the display portion DIS, for convenience. Similarly, the driver circuit region DRV including the plurality of driver circuits TD overlaps with the pixel layer PXAL including the plurality of regions ARA; however, FIG. 10 illustrates the plurality of driver circuits TD arranged in a column outside the display portion DIS, for convenience. Similarly, the driver circuit region DRV including the plurality of driver circuits RD overlaps with the pixel layer PXAL including the plurality of regions ARA; however, FIG. 10 illustrates the plurality of driver circuits RD arranged in a row outside the display portion DIS, for convenience.

The peripheral circuit PRPH is included in the circuit layer SICL illustrated in FIG. 6A and FIG. 6B, for example. The circuit GDS and the circuit SDS included in the peripheral circuit PRPH are included in the driver circuit region DRV illustrated in FIG. 6A and FIG. 6B, for example.

In the case of the display apparatus DSP in FIG. 6A, the distribution circuit DMG, the distribution circuit DMS, the distribution circuit TMG, the distribution circuit RMG, the control portion CTR, the memory device MD, the voltage generation circuit PG, the timing controller TMC, the clock signal generation circuit CKS, the image processing portion GPS, and the interface INT may each be electrically connected to a circuit included in the driver circuit region DRV, as an external circuit, for example.

In the case of the display apparatus DSP in FIG. 6B, one or more selected from the distribution circuit DMG, the distribution circuit DMS, the distribution circuit TMG, the distribution circuit RMG, the control portion CTR, the memory device MD, the voltage generation circuit PG, the timing controller TMC, the clock signal generation circuit CKS, the image processing portion GPS, and the interface INT may be included in the region LIA. Among the above-described circuits, the circuit not included in the region LIA may be electrically connected to one or more selected from the circuit included in the region LIA and the circuit included in the driver circuit region DRV, as an external circuit.

The distribution circuit DMG, the distribution circuit DMS, the distribution circuit TMG, the distribution circuit RMG, the control portion CTR, the memory device MD, the voltage generation circuit PG, the timing controller TMC, the clock signal generation circuit CKS, the image processing portion GPS, and the interface INT transmit and receive a variety of signals mutually through a bus wiring BW.

The interface INT has a function of a circuit for taking, into the circuit in the peripheral circuit PRPH, image information for displaying an image on the display apparatus DSP output from an external device, for example. Examples of the external device include a recording media player and a nonvolatile memory device such as an HDD (Hard Disk Drive) or an SSD (Solid State Drive). The interface INT may be a circuit that outputs a signal from a circuit inside the peripheral circuit PRPH to a device outside the display apparatus DSP.

In the case where image information is input from the external device to the interface INT by wireless communication, the interface INT can include, for example, an antenna receiving the image information, a mixer, an amplifier circuit, and an analog-digital conversion circuit.

The control portion CTR has functions of processing a variety of control signals transmitted from the external device through the interface INT and controlling a variety of circuits included in the peripheral circuit PRPH.

The memory device MD has a function of temporarily retaining information and an image signal. In this case, the memory device MD serves as a frame memory (sometimes referred to as a frame buffer), for example. The memory device MD may have a function of temporarily retaining at least one of information transmitted from the external device through the interface INT and information processed in the control portion CTR. Note that at least one of an SRAM (Static Random Access Memory) and a DRAM (Dynamic Random Access Memory) can be used as the memory device MD.

The voltage generation circuit PG has a function of generating power supply voltages to be supplied to a pixel circuit included in the display portion DIS and a circuit included in the peripheral circuit PRPH. Note that the voltage generation circuit PG may have a function of selecting a circuit to which a voltage is to be supplied. For example, the voltage generation circuit PG stops supply of voltages to the circuit GDS, the circuit SDS, the image processing portion GPS, the timing controller TMC, and the clock signal generation circuit CKS in a period in which a still image is displayed on the display portion DIS, resulting in a reduction in the total power consumption of the display apparatus DSP.

The timing controller TMC has a function of generating timing signals used in the plurality of driver circuits GD included in the circuit GDS and the plurality of driver circuits SD included in the circuit SDS. For the generation of the timing signal, a clock signal generated by the clock signal generation circuit CKS can be used.

The image processing portion GPS has a function of performing processing for drawing an image on the display portion DIS. For example, the image processing portion GPS may include a GPU (Graphics Processing Unit). Specifically, the image processing portion GPS is configured to perform pipeline processing in parallel and thus can perform high-speed processing of the image data to be displayed on the display portion DIS. The image processing portion GPS can also have a function of a decoder for decoding an encoded image.

The image processing portion GPS may also have a function of correcting color tone of an image displayed on the display portion DIS. In that case, the image processing portion GPS is preferably provided with one or both of a dimming circuit and a toning circuit. In the case where the display pixel included in the display portion DIS includes an organic EL element, the image processing portion GPS may be provided with an EL correction circuit.

The above-described image correction may be performed using artificial intelligence. For example, current flowing through a display device included in a pixel (or a voltage applied to the display device) may be monitored and acquired, an image displayed on the display portion DIS may be acquired with an image sensor or the like, the current (or voltage) and the image may be used as input data in an arithmetic operation of the artificial intelligence (e.g., an artificial neural network), and the output result may be used to determine whether the image should be corrected.

Such an arithmetic operation of artificial intelligence can be applied not only to image correction but also to upconversion processing of image data. Accordingly, upconversion of low-definition image data can be performed in accordance with the definition of the display portion DIS, which enables a high-display-quality image to be displayed on the display portion DIS.

Note that the above-described arithmetic operation of artificial intelligence can be performed using the GPU included in the image processing portion GPS, for example. That is, the GPU can be used to perform arithmetic operations for various kinds of correction (e.g., color irregularity correction or upconversion).

Note that in this specification and the like, a GPU performing an arithmetic operation of artificial intelligence is referred to as an AI accelerator. That is, the GPU may be replaced with an AI accelerator in the description in this specification and the like.

The clock signal generation circuit CKS has a function of generating a clock signal. The clock signal generation circuit CKS may be configured to be capable of changing the frame frequency of a clock signal depending on an image displayed on the display portion DIS, for example.

The distribution circuit DMG has a function of transmitting a signal received from the bus wiring BW to the driver circuit GD, which drives the display pixel included in one of the plurality of regions ARA, in accordance with the contents of the signal.

The distribution circuit DMS has a function of transmitting a signal received from the bus wiring BW to the driver circuit SD, which drives the display pixel included in one of the plurality of regions ARA, in accordance with the contents of the signal.

The distribution circuit TMG has a function of transmitting a signal received from the bus wiring BW to the driver circuit TD, which drives the image capturing pixel included in one of the plurality of regions ARA, in accordance with the contents of the signal.

The distribution circuit RMG has a function of transmitting a signal received from the bus wiring BW to the driver circuit RD, which drives the image capturing pixel included in one of the plurality of regions ARA, in accordance with the contents of the signal.

Although not illustrated in FIG. 10, a level shifter may be included in the peripheral circuit PRPH. The level shifter has a function of converting a signal input to any of the circuits into a signal having an appropriate level, for example.

Note that the structure of the peripheral circuit PRPH of the display apparatus DSP illustrated in FIG. 10 is an example, and the circuit structure included in the peripheral circuit PRPH may be changed depending on conditions. For example, in the case where the display apparatus DSP receives driving voltages of circuits from the outside, the display apparatus DSP does not need to generate the driving voltages. In this case, the display apparatus DSP may have a structure without the voltage generation circuit PG.

Note that this embodiment can be combined with any of the other embodiments described in this specification as appropriate.

### Embodiment 2

In this embodiment, electronic devices that include the display apparatus described in Embodiment 1 will be described.

### [Microscope]

FIG. 11A illustrates a structure example of a microscope, which is an example of the electronic device. A microscope is a kind of optical device and thus is sometimes referred to as an optical device in this specification and the like. A microscope MCS includes a housing KYI, a lens RNS, and the light-emitting apparatus ISP. FIG. 11B is a schematic cross-sectional view of the microscope MCS in FIG. 11A.

In the microscope MCS in FIG. 11A, the housing KYI has a shape obtained by combining a cylindrical shape CYL and a conical shape CNE whose tip has an opening, for example. Note that in FIG. 11A and FIG. 11B, a region where the tip of the conical shape CNE has the opening is illustrated as an opening portion KKB.

In FIG. 11A, a region of the cylindrical shape CYL of the housing KYI is denoted by dashed lines so that the positions of the lens RNS and the light-emitting apparatus ISP can be understood.

The light-emitting apparatus ISP and the lens RNS overlap with each other and are provided in regions overlapping with the opening portion KKB.

The display apparatus DSP described in Embodiment 1 can be applied to the light-emitting apparatus ISP, for example. Note that the light-emitting apparatus ISP can be the display apparatus DSP not provided with the display pixel. In this structure example, the light-emitting apparatus ISP includes the image capturing light source and the image capturing pixel in the display apparatus DSP.

Light LGT1 from the light-emitting pixel included in the light-emitting apparatus ISP and functioning as an image capturing light source is emitted from the opening portion KKB through the lens RNS. When an object is irradiated with the light LGT1, light LGT2 reflected from the object enters the image capturing pixel provided in the light-emitting apparatus ISP through the opening portion KKB and the lens RNS.

In the light-emitting apparatus ISP, the image capturing light source and the image capturing pixel can be formed over one substrate as in the display apparatus DSP described in Embodiment 1. That is, the image capturing light source and the image capturing pixel can be combined into the light-emitting apparatus ISP; thus, when the light-emitting apparatus ISP is applied to the microscope MCS illustrated in FIG. 11A and FIG. 11B, the number of components of the microscope MCS can be reduced. Accordingly, the size of the microscope MCS can be reduced.

As a specific application example of the microscope MCS, skin surface analysis can be given. For example, as illustrated in FIG. 11C, a user USR presses the opening portion KKB, which is positioned at the tip of the microscope MCS, to the user USR's skin and can thus check the conditions of the skin.

At this time, the light-emitting apparatus ISP can perform image capturing with the image capturing light source region LEA and the image capturing region MA that are separate regions as shown in any one of FIG. 1B, FIG. 3B, and FIG. 4A to FIG. 4E. Specifically, the light-emitting pixels included in the image capturing light source region LEA emit the light LGT1, and the image capturing pixels included in the image capturing region MA obtain the light LGT2.

An image of the surface of the user USR's skin can be captured when the image capturing light source included in the image capturing light source region LEA is the light-emitting pixel that emits visible light and the image capturing element included in the image capturing pixel of the image capturing region MA is the image capturing element that obtains the visible light.

An image of an inner portion of the user USR's skin can be captured when the image capturing light source included in the image capturing light source region LEA is the light-emitting pixel that emits infrared light and the image capturing element included in the image capturing pixel of the image capturing region MA is the image capturing element that obtains the infrared light.

The health degree of a skin can be measured through image analysis performed using a captured image of a surface of the skin and a captured image of an inner portion of the skin. The health degree of a skin is indicated by, for example, the texture of the skin, spots (melanin amount), sagging, and the size of pores. The image analysis can quantify the texture of the skin, spots (melanin amount), and the size of pores, making it possible to obtain the values of them.

Note that in the image analysis, an arithmetic operation of artificial intelligence (an arithmetic operation by a model of an artificial neural network) may be performed, for example. As the model of the artificial neural network that can be used for the image analysis, deep learning is preferably used, for example. Examples of the deep learning include a convolutional neural network (CNN), a recurrent neural network (RNN), an autoencoder (AE), a variational autoencoder (VAE), and a generative adversarial network (GAN). Examples of the calculation model used for the image analysis other than the artificial neural network include random forest, a support vector machine, and gradient boosting.

The microscope MCS may be used not only for measuring the health degree of a skin as described above but also for observing injuries and rashes such as pimples on a skin. The microscope MCS may also be used for observing a scalp, for example. Like the above-described image analysis using a captured image of a skin, image analysis of a scalp may be performed by capturing an image of the scalp, and the health conditions of the scalp may be checked.

### [Portable Information Terminal]

FIG. 11D illustrates a structure example of a smartphone, which is an example of the electronic device. A smartphone is an example of a portable information terminal and thus is sometimes referred to as a portable information terminal in this specification and the like. The smartphone SMP includes the light-emitting apparatus ISP.

Since the smartphone SMP illustrated in FIG. 11D includes the display apparatus DSP described in Embodiment 1, the smartphone SMP is referred to as an optical device in some cases.

In this structure example, the light-emitting apparatus ISP of the smartphone SMP can be provided with the display apparatus DSP described in Embodiment 1. When the light-emitting apparatus ISP is provided with the display apparatus DSP described in Embodiment 1, an image of light entering the light-emitting apparatus ISP can be captured by the image capturing pixels included in the light-emitting apparatus ISP. Note that the light-emitting apparatus ISP in this structure example may be provided with display pixels unlike the light-emitting apparatus ISP in FIG. 11A to FIG. 11C.

Like the microscope MCS, the smartphone SMP may be used to check the conditions of a skin. For example, as illustrated in FIG. 11E, the user USR presses the light-emitting apparatus ISP of the smartphone SMP to the user USR's skin and can thus check the conditions of the skin.

At this time, the light-emitting apparatus ISP preferably perform image capturing with the image capturing light source region LEA and the image capturing region MA that are separate regions as shown in any one of FIG. 1B, FIG. 3B, and FIG. 4A to FIG. 4E.

### [Image Capturing Method]

In the case where the light-emitting apparatus ISP described in this embodiment employs a method in which the plurality of regions ARA included in the image capturing region MA are sequentially selected and image capturing is performed (hereinafter referred to as a first method), instead of a method in which all the image capturing pixels of the plurality of regions ARA included in the image capturing region MA perform image capturing at a time, the positions of the image capturing light source region LEA and the image capturing region MA in the light-emitting apparatus ISP are not limited to those in FIG. 1B, FIG. 3B, and FIG. 4A to FIG. 4E. In the case where the first method is employed, the positions of the image capturing light source region LEA and the image capturing region MA may be sequentially switched during image capturing.

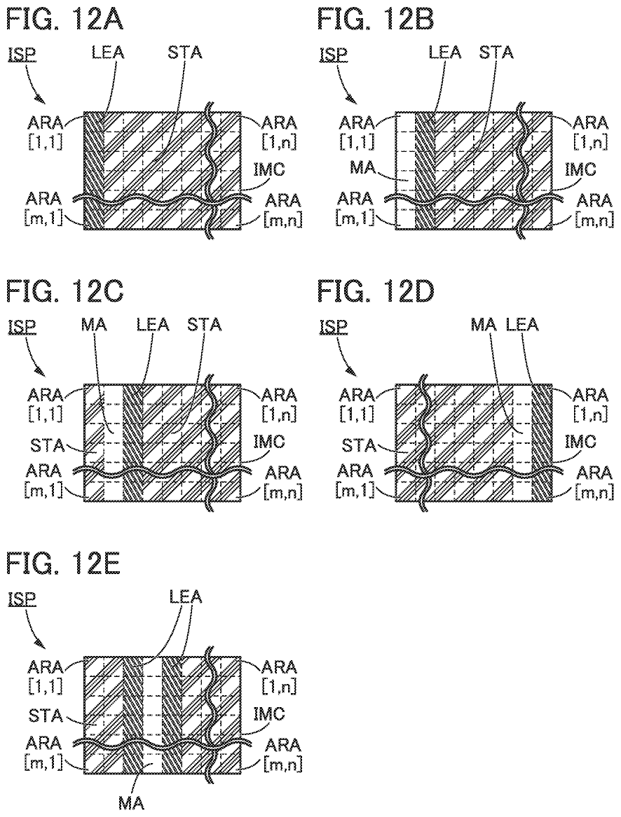

For example, FIG. 12A to FIG. 12D illustrate an example of an image capturing method of the light-emitting apparatus ISP employing the first method. Note that the light-emitting apparatus ISP illustrated in FIG. 12A to FIG. 12D includes an image capturing portion IMC, and the image capturing portion IMC is a device divided into m rows and n columns (m is an integer greater than or equal to 1, and n is an integer greater than or equal to 1) of regions ARA like the display portion DIS described in Embodiment 1 with reference to FIG. 1A.

FIG. 12A illustrates the positions of the image capturing light source region LEA and a standby region STA in the image capturing portion IMC immediately after an image capturing operation starts. Note that the standby region STA refers to a region where neither the image capturing pixels nor the display pixels included in the regions ARA are driven.

In the image capturing portion IMC in FIG. 12A, the image capturing light source region LEA includes all the regions ARA positioned in the first column. The standby region STA includes the regions ARA other than those in the image capturing light source region LEA of the image capturing portion IMC.

FIG. 12B illustrates the positions of the image capturing region MA, the image capturing light source region LEA, and the standby region STA in the image capturing portion IMC after the image capturing operation shown in FIG. 12A.

In the image capturing portion IMC in FIG. 12B, the image capturing region MA includes all the regions ARA positioned in the first column. Note that the image capturing region MA in this embodiment is a region where the image capturing pixels can be driven. The expression “image capturing pixels can be driven” means that writing of a captured image to the image capturing pixels is possible or reading from the image capturing pixels is possible. The display pixels included in the regions ARA of the image capturing region MA in this embodiment are not necessarily driven. The image capturing light source region LEA includes all the regions ARA positioned in the second column. The standby region STA includes the regions ARA other than those in the image capturing region MA and the image capturing light source region LEA of the image capturing portion IMC.

FIG. 12C illustrates the positions of the image capturing region MA, the image capturing light source region LEA, and the standby region STA in the image capturing portion IMC after the image capturing operation shown in FIG. 12B.

In the image capturing portion IMC in FIG. 12C, the image capturing region MA includes all the regions ARA positioned in the second column. The image capturing light source region LEA includes all the regions ARA positioned in the third column. The standby regions STA include the regions ARA other than those in the image capturing region MA and the image capturing light source region LEA of the image capturing portion IMC.

That is, in FIG. 12A to FIG. 12C, the regions ARA are sequentially selected as the image capturing light source region LEA from the first column of the image capturing portion IMC. At the timing at which the regions ARA in the next column are selected as the image capturing light source region LEA, the image capturing light source region LEA that has been selected at the previous timing is switched to the image capturing region MA.

In a manner similar to that in FIG. 12A to FIG. 12C, the selection for the image capturing light source region LEA continues in the fourth and following columns of the image capturing portion IMC. FIG. 12D illustrates the positions of the image capturing region MA, the image capturing light source region LEA, and the standby region STA when the selection for the image capturing light source region LEA has been performed to reach the n-th column of the image capturing portion IMC.

The light-emitting apparatus ISP can perform image capturing in the following manner: the selection for the image capturing region MA and the image capturing light source region LEA is sequentially performed column by column in the image capturing portion IMC as illustrated in FIG. 12A to FIG. 12D, and every time when the selection is performed, the image capturing pixels of the regions ARA included in the image capturing region MA are driven.

In FIG. 12A to FIG. 12D, for example, the regions ARA in the j-th column (here, j is an integer greater than or equal to 2 and less than or equal to n) of the image capturing portion IMC serve as the image capturing light source region LEA, and the regions ARA in the j−1-th column of the image capturing portion IMC serve as the image capturing region MA; however, in an image capturing method of the light-emitting apparatus ISP of one embodiment of the present invention, the regions ARA in the j−1-th column of the image capturing portion IMC may serve as the image capturing light source region LEA, and the regions ARA in the j-th column of the image capturing portion IMC may serve as the image capturing region MA (not shown). Note that in FIG. 12A, the image capturing region MA is not set when the image capturing light source region LEA is in the first column.

As illustrated in FIG. 12E, the regions ARA in the k-th column (here, k is an integer greater than or equal to 2 and less than or equal to n−1) of the image capturing portion IMC may serve as the image capturing region MA, and the regions ARA in the k−1-th column and the k+1-th column of the image capturing portion IMC may serve as the image capturing light source regions LEA. The light-emitting apparatus ISP can perform image capturing also in the following manner: the selection for the image capturing region MA is sequentially performed column by column in the image capturing portion IMC by changing the value of k from 2 to n−1, and every time when the selection is performed, the image capturing pixels included in the image capturing region MA are driven.

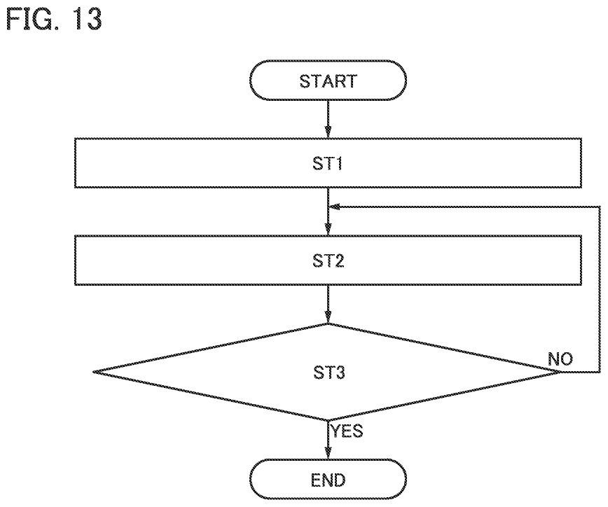

The above-described operation example of the light-emitting apparatus ISP can be expressed by the flow chart shown in FIG. 13. The operation method of the light-emitting apparatus ISP that is the operation example shown in the flow chart of FIG. 13 includes Step ST1 to Step ST3. In the flow chart of FIG. 13, “START” shows the start of the operation and “END” shows the end of the operation.

Step ST1 includes a step in which the light-emitting apparatus ISP sets the image capturing region MA, the image capturing light source region LEA, and the standby region STA in the image capturing portion IMC.

Step ST1 includes a step of performing image capturing after the image capturing region MA, the image capturing light source region LEA, and the standby region STA are set in the image capturing portion IMC.

Step ST2 includes a step in which the light-emitting apparatus ISP resets, to the image capturing light source region LEA or the standby region STA, the image capturing region MA that has been set at the previous timing; the light-emitting apparatus ISP resets, to the image capturing region MA or the standby region STA, the image capturing light source region LEA that has been set at the previous timing; and the light-emitting apparatus ISP resets, to the image capturing light source region LEA, part of the standby region STA that has been set at the previous timing. Although not illustrated in FIG. 12A to FIG. 12D, part of the standby region STA that has been set at the previous timing may be reset to the image capturing region MA instead of the image capturing light source region LEA. Note that the previous timing can be Step ST1 or Step ST2, for example.

In other words, Step ST2 includes a step in which the image capturing region MA set in the image capturing portion IMC is reset to the image capturing light source region LEA or the standby region STA, the image capturing light source region LEA set in the image capturing portion IMC is reset to the image capturing region MA or the standby region STA, and part of the standby region STA set in the image capturing portion IMC is reset to the image capturing light source region LEA.

Step ST2 includes a step of performing image capturing after the image capturing region MA, the image capturing light source region LEA, and the standby region STA are reset in the image capturing portion IMC.

Step ST3 includes a step of determining whether the image capturing has been completed in all the intended regions of the image capturing portion IMC of the light-emitting apparatus ISP. When the image capturing has been completed in all the intended regions of the image capturing portion IMC (denoted as “YES” in FIG. 13), the operation of the flow chart in FIG. 13 ends. In the case where the image capturing has not been completed in all the intended regions of the image capturing portion IMC (denoted as “NO” in FIG. 13), the process proceeds to Step ST2. Note that the intended regions may be all the regions ARA in the image capturing portion IMC or some of the regions ARA in the image capturing portion IMC.

The light-emitting apparatus ISP can perform image capturing through the above-described operation, in which the image capturing region MA, the image capturing light source region LEA, and the standby region STA are repeatedly set and every time when these regions are set, the image capturing pixels included in the image capturing portion IMC are driven.

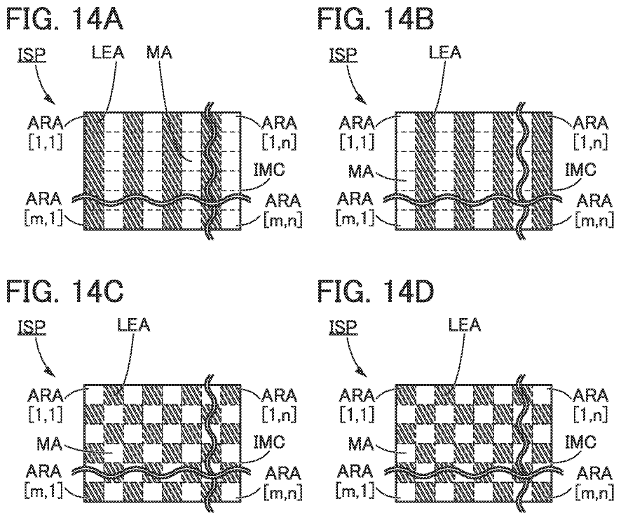

FIG. 14A and FIG. 14B illustrate an example of an image capturing method of the light-emitting apparatus ISP, which is different from the above-described one.

FIG. 14A illustrates example positions of the image capturing light source regions LEA and the image capturing regions MA in the image capturing portion IMC immediately after an image capturing operation starts.

In the image capturing portion IMC in FIG. 14A, the image capturing light source regions LEA include all the regions ARA positioned in the odd-numbered columns. The image capturing regions MA include all the regions ARA positioned in the even-numbered columns.

FIG. 14B illustrates the positions of the image capturing regions MA and the image capturing light source regions LEA in the image capturing portion IMC after the image capturing operation shown in FIG. 14A.

In the image capturing portion IMC in FIG. 14B, the image capturing light source regions LEA include all the regions ARA positioned in the even-numbered columns. The image capturing regions MA include all the regions ARA positioned in the odd-numbered columns.

Although the n-th column of the image capturing portion IMC illustrated in FIG. 14A and FIG. 14B is an even-numbered column, the n-th column of the image capturing portion IMC in the light-emitting apparatus ISP that performs this operation example may be an odd-numbered column.

The light-emitting apparatus ISP can perform image capturing in the following manner: the regions ARA positioned in the even-numbered columns of the image capturing portion IMC are set to the image capturing regions MA as illustrated in FIG. 14A, the image capturing pixels included in the regions ARA positioned in the even-numbered columns are driven, the regions ARA positioned in the odd-numbered columns of the image capturing portion IMC are then set to the image capturing regions MA as illustrated in FIG. 14B, and the image capturing pixels included in the regions ARA positioned in the odd-numbered columns are driven.

Note that the order of the image capturing operation of the light-emitting apparatus ISP is not limited to the above-described order. The image capturing operation may be performed in the following order, which is different from the above-described order: the image capturing pixels in the regions ARA positioned in the odd-numbered columns of the image capturing portion IMC are driven as illustrated in FIG. 14B and then, the image capturing pixels in the regions ARA positioned in the even-numbered columns of the image capturing portion IMC are driven as illustrated in FIG. 14A.

FIG. 14C and FIG. 14D illustrate an example of an image capturing method of the light-emitting apparatus ISP, which is different from the above-described one.

FIG. 14C illustrates example positions of the image capturing light source regions LEA and the image capturing regions MA in the image capturing portion IMC immediately after an image capturing operation starts.

In the image capturing portion IMC in FIG. 14C, when i+j (here, i is an integer greater than or equal to 1 and less than or equal to m, and j is an integer greater than or equal to 1 and less than or equal to n) is an odd number, the region ARA positioned in the i-th row and the j-th column is included in the image capturing light source region LEA. When i+j is an even number, the region ARA positioned in the i-th row and the j-th column is included in the image capturing region MA.

FIG. 14D illustrates the positions of the image capturing regions MA and the image capturing light source regions LEA in the image capturing portion IMC after the image capturing operation shown in FIG. 14C.

In the image capturing portion IMC in FIG. 14D, when i+j is an odd number, the region ARA positioned in the i-th row and the j-th column is included in the image capturing region MA. When i+j is an even number, the region ARA positioned in the i-th row and the j-th column is included in the image capturing light source region LEA.

Although the n-th column of the image capturing portion IMC illustrated in FIG. 14C and FIG. 14D is an even-numbered column, the n-th column of the image capturing portion IMC in the light-emitting apparatus ISP that performs this operation example may be an odd-numbered column.

The light-emitting apparatus ISP can perform image capturing in the following manner: the image capturing pixels included in the image capturing regions MA in FIG. 14C are driven and then, the image capturing pixels included in the image capturing regions MA in FIG. 14D are driven.

Note that the order of the image capturing operation of the light-emitting apparatus ISP is not limited to the above-described order. The image capturing operation may be performed in the following order, which is different from the above-described order: the image capturing pixels included in the image capturing regions MA shown in FIG. 14D are driven and then, the image capturing pixels included in the image capturing regions MA shown in FIG. 14C are driven.

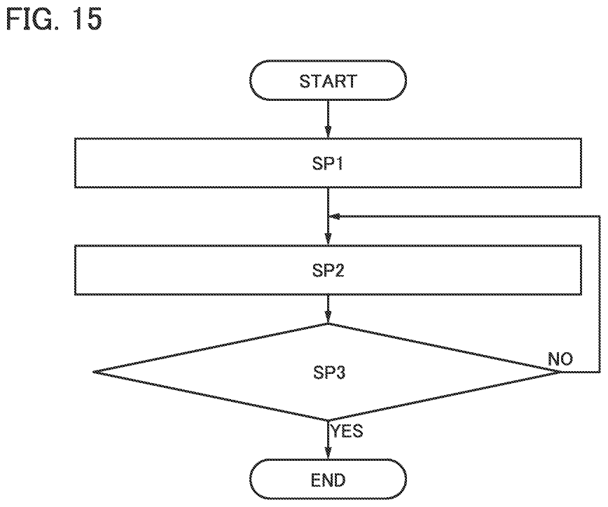

The above-described operation example of the light-emitting apparatus ISP can be expressed by the flow chart shown in FIG. 15. The operation method of the light-emitting apparatus ISP that is the operation example shown in the flow chart of FIG. 15 includes Step SP1 to Step SP3. In the flow chart of FIG. 15, “START” shows the start of the operation and “END” shows the end of the operation.

Step SP1 includes a step in which the image capturing regions MA and the image capturing light source regions LEA are set in the image capturing portion IMC.

Step SP1 includes a step of performing image capturing after the image capturing regions MA and the image capturing light source regions LEA are set in the image capturing portion IMC.

Step SP2 has a function of resetting, to the image capturing light source regions LEA, the image capturing regions MA that have been set at the previous timing and resetting, to the image capturing regions MA, the image capturing light source regions LEA that have been set at the previous timing. Note that the previous timing can be Step SP1 or Step SP2, for example.

In other words, Step SP2 includes a step in which the image capturing regions MA set in the image capturing portion IMC are reset to the image capturing light source regions LEA and the image capturing light source regions LEA set in the image capturing portion IMC are reset to the image capturing regions MA.

Step SP2 includes a step of performing image capturing after the image capturing regions MA and the image capturing light source regions LEA are reset in the image capturing portion IMC.

Step SP3 includes a step of determining whether the image capturing has been completed in all the intended regions of the image capturing portion IMC of the light-emitting apparatus ISP. When the image capturing has been completed in all the intended regions of the image capturing portion IMC (denoted as “YES” in FIG. 15), the operation of the flow chart in FIG. 15 ends. In the case where the image capturing has not been completed in all the intended regions of the image capturing portion IMC (denoted as “NO” in FIG. 15), the process proceeds to Step SP2. Note that the intended regions may be all the regions ARA in the image capturing portion IMC or some of the regions ARA in the image capturing portion IMC.

The light-emitting apparatus ISP can perform image capturing through the above-described operation, in which the image capturing regions MA and the image capturing light source regions LEA are repeatedly set and every time when these regions are set, the image capturing pixels included in the image capturing portion IMC are driven.

The light-emitting apparatus ISP can perform image capturing also by employing the above-described operation method. In particular, it is preferable to employ any of the operation methods described in this embodiment with reference to FIG. 12A to FIG. 15 when the light-emitting apparatus ISP of the smartphone SMP is large. For example, when the arrangement of the image capturing light source region LEA and the image capturing region MA in the display portion DIS illustrated in FIG. 1B is employed, light from the light-emitting pixels included in the image capturing light source region LEA may fail to enter the vicinity of the center of the display portion DIS. That is, in the case where the light-emitting apparatus ISP is large in FIG. 11D, a method in which the image capturing light source region LEA is placed in the vicinity of the center of the image capturing portion IMC is preferably employed and thus, any of the operation methods illustrated in FIG. 12A to FIG. 15 is suitably used.

Note that this embodiment can be combined with any of the other embodiments described in this specification as appropriate.

### Embodiment 3

In this embodiment, a display apparatus that can be provided in an electronic device of one embodiment of the present invention will be described. Note that the display apparatus described in this embodiment can be used in the display portion DIS described in the above embodiments.

### <Structure Example of Display Apparatus>

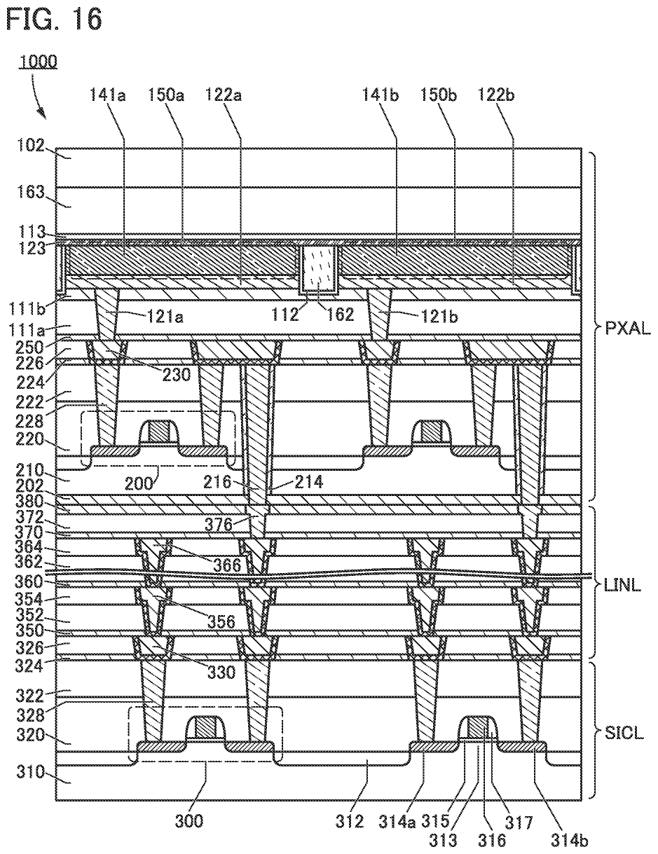

FIG. 16 is a cross-sectional view illustrating an example of a display apparatus of one embodiment of the present invention. A display apparatus 1000 illustrated in FIG. 16 has a structure in which a pixel circuit, a driver circuit, and the like are provided over a substrate 310, for example. Note that the display apparatus DSP and the like described in the above embodiments can have the structure of the display apparatus 1000 in FIG. 16. The pixel circuit described in this embodiment can be the display pixel described in the above embodiments.

Specifically, for example, the circuit layer SICL, the wiring layer LINL, and the pixel layer PXAL in the display apparatus DSP can be those in the display apparatus 1000 in FIG. 16. The circuit layer SICL includes the substrate 310, for example, and a transistor 300 is formed over the substrate 310. The wiring layer LINL is provided above the transistor 300, and the wiring layer LINL includes a wiring that is electrically connected to the transistor 300, a transistor 200 to be described later, a light-emitting device 150a to be described later, or a light-emitting device 150b. The pixel layer PXAL is provided above the wiring layer LINL, and the pixel layer PXAL includes, for example, the transistor 200 and a light-emitting device 150 (the light-emitting device 150a and the light-emitting device 150b in FIG. 16).

As the substrate 310, a semiconductor substrate (e.g., a single crystal substrate containing silicon or germanium as a material) can be used, for example. Besides the semiconductor substrate, for example, an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 310. Examples of the glass substrate include barium borosilicate glass, aluminoborosilicate glass, and soda lime glass. Examples of the flexible substrate, the attachment film, the base material film, and the like include plastics typified by polyethylene terephthalate (PET), polyethylene naphthalate (PEN), polyether sulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the fabrication process of the display apparatus 1000 includes heat treatment, a highly heat-resistant material is preferably selected for the substrate 310.

In the description of this embodiment, the substrate 310 is a semiconductor substrate containing silicon as a material.

The transistor 300 is provided on the substrate 310 and includes an element isolation layer 312, a conductor 316, an insulator 315, an insulator 317, a semiconductor region 313 that is part of the substrate 310, and a low-resistance region 314a and a low-resistance region 314b that function as a source region and a drain region. Thus, the transistor 300 is a Si transistor. Although FIG. 16 illustrates a structure in which one of the source and the drain of the transistor 300 is electrically connected to a conductor 330, a conductor 356, and a conductor 366, which are described later, through a conductor 328 described later, the electrical connection in the display apparatus of one embodiment of the present invention is not limited thereto. The display apparatus of one embodiment of the present invention may have a structure in which, for example, a gate of the transistor 300 is electrically connected to the conductor 330, the conductor 356, and the conductor 366 through the conductor 328.

The transistor 300 can be a Fin type when, for example, the top surface of the semiconductor region 313 and the side surface thereof in the channel width direction are covered with the conductor 316 with the insulator 315 functioning as a gate insulating film therebetween. The effective channel width can be increased in the Fin-type transistor 300, so that the on-state characteristics of the transistor 300 can be improved. In addition, contribution of the electric field of the gate electrode can be increased, so that the off-state characteristics of the transistor 300 can be improved.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using a material containing germanium (Ge), silicon germanium (SiGe), gallium arsenide (GaAs), aluminum gallium arsenide (GaAlAs), or gallium nitride (GaN). Alternatively, a structure using silicon whose effective mass is controlled by applying stress to the crystal lattice and changing the lattice spacing may be employed. Alternatively, the transistor 300 may be a HEMT (High Electron Mobility Transistor) using gallium arsenide and aluminum gallium arsenide.

For the conductor 316 functioning as a gate electrode, a semiconductor material such as silicon containing an element that imparts n-type conductivity, e.g., arsenic or phosphorus, or an element that imparts p-type conductivity, e.g., boron or aluminum, or a conductive material such as a metal material, an alloy material, or a metal oxide material can be used.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Note that the transistor 300 illustrated in FIG. 16 is an example and the structure is not limited thereto; an appropriate transistor is used in accordance with a circuit structure, a driving method, or the like. For example, the transistor 300 may have a planar structure instead of a Fin-type structure.

Over the transistor 300 illustrated in FIG. 16, an insulator 320, an insulator 322, an insulator 324, and an insulator 326 are stacked in this order from the substrate 310 side.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride can be used, for example.

The insulator 322 may have a function of a planarization film for eliminating a level difference caused by the transistor 300 or the like covered with the insulator 320 and the insulator 322. For example, the top surface of the insulator 322 may be planarized by planarization treatment using a chemical mechanical polishing (CMP) method or the like to have improved planarity.

For the insulator 324, it is preferable to use a barrier insulating film preventing diffusion of impurities such as water and hydrogen from the substrate 310 or the transistor 300 to a region above the insulator 324 (e.g., the region where the transistor 200, the light-emitting device 150a, the light-emitting device 150b, and the like are provided). Accordingly, for the insulator 324, it is preferable to use an insulating material which has a function of inhibiting diffusion of impurities such as a hydrogen atom, a hydrogen molecule, and a water molecule (through which the above impurities are less likely to pass). Furthermore, depending on conditions, for the insulator 324, it is preferable to use an insulating material which has a function of inhibiting diffusion of impurities such as a nitrogen atom, a nitrogen molecule, a nitrogen oxide molecule (e.g., N₂O, NO, or NO₂), and a copper atom (through which the above impurities are less likely to pass). In addition, it is preferable that the insulator 324 have a function of inhibiting diffusion of oxygen (e.g., one or both of an oxygen atom and an oxygen molecule).

For the film having a barrier property against hydrogen, silicon nitride formed by a CVD (Chemical Vapor Deposition) method can be used, for example.

The amount of released hydrogen can be analyzed by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5× 10¹⁵ atoms/cm² in TDS analysis in a film-surface temperature range of 50° C. to 500° C., for example.

Note that the permittivity of the insulator 326 is preferably lower than that of the insulator 324. For example, the dielectric constant of the insulator 326 is preferably lower than 4, further preferably lower than 3. The dielectric constant of the insulator 326 is, for example, preferably 0.7 times or less, further preferably 0.6 times or less the dielectric constant of the insulator 324. When a material with a low permittivity is used for an interlayer film, the parasitic capacitance generated between wirings can be reduced.

In addition, the conductor 328 and the conductor 330 that are connected to the light-emitting devices and the like provided above the insulator 326 are embedded in the insulator 320, the insulator 322, the insulator 324, and the insulator 326. Note that the conductor 328 and the conductor 330 each function as a plug or a wiring. A plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material of each of plugs and wirings (the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 16, an insulator 350, an insulator 352, and an insulator 354 are provided to be stacked in this order above the insulator 326 and the conductor 330. Furthermore, the conductor 356 is formed in the insulator 350, the insulator 352, and the insulator 354. The conductor 356 has a function of a plug or a wiring that is connected to the transistor 300. Note that the conductor 356 can be provided using a material similar to those for the conductor 328 and the conductor 330.

Note that like the insulator 324, for example, the insulator 350 is preferably formed using an insulator having a barrier property against hydrogen, oxygen, and water. Like the insulator 326, the insulator 352 and the insulator 354 are preferably formed using an insulator having a relatively low dielectric constant to reduce parasitic capacitance generated between wirings. An insulator 362 and an insulator 364 each have functions of an interlayer insulating film and a planarization film. Furthermore, the conductor 356 preferably includes a conductor having a barrier property against hydrogen, oxygen, and water.

For the conductor having a barrier property against hydrogen, tantalum nitride is preferably used, for example. The use of a stack including tantalum nitride and tungsten that has high conductivity can inhibit diffusion of hydrogen from the transistor 300 while the conductivity of a wiring is kept. In that case, a tantalum nitride layer having a barrier property against hydrogen is preferably in contact with the insulator 350 having a barrier property against hydrogen.

An insulator 360, the insulator 362, and the insulator 364 are stacked in this order over the insulator 354 and the conductor 356.

Like the insulator 324 or the like, the insulator 360 is preferably formed using an insulator having a barrier property against impurities such as water and hydrogen. Thus, the insulator 360 can be formed using any of the materials that can be used for the insulator 324 or the like, for example.

The insulator 362 and the insulator 364 each have functions of an interlayer insulating film and a planarization film. Like the insulator 324, the insulator 362 and the insulator 364 are preferably formed using an insulator having a barrier property against impurities such as water and hydrogen. Thus, one or both of the insulator 362 and the insulator 364 can be formed using any of the materials usable for the insulator 324.

An opening portion is formed in regions of the insulator 360, the insulator 362, and the insulator 364 that overlap with part of the conductor 356, and the conductor 366 is provided to fill the opening portion. The conductor 366 is also formed over the insulator 362. The conductor 366 has a function of a plug or a wiring connected to the transistor 300, for example. Note that the conductor 366 can be provided using a material similar to those for the conductor 328 and the conductor 330.

An insulator 370 and an insulator 372 are stacked in this order over the insulator 364 and the conductor 366.

Like the insulator 324, the insulator 370 is preferably formed using an insulator having a barrier property against impurities such as water and hydrogen. Thus, the insulator 370 can be formed using any of the materials that can be used for the insulator 324 or the like, for example.

The insulator 372 has functions of an interlayer insulating film and a planarization film. Like the insulator 324, the insulator 372 is preferably formed using an insulator having a barrier property against impurities such as water and hydrogen. Thus, the insulator 372 can be formed using any of the materials that can be used for the insulator 324.

An opening portion is formed in regions of the insulator 370 and the insulator 372 that overlap with part of the conductor 366, and a conductor 376 is provided to fill the opening portion. The conductor 376 is also formed over the insulator 372. After that, the conductor 376 is patterned into a form of a wiring, a terminal, or a pad by etching treatment or the like.

For example, copper, aluminum, tin, zinc, tungsten, silver, platinum, or gold can be used for the conductor 376. The material used for the conductor 376 preferably contains the same component as the material used for a later-described conductor 216 included in the pixel layer PXAL.

Then, an insulator 380 is formed to cover the insulator 372 and the conductor 376 and is subsequently subjected to planarization treatment by a chemical mechanical polishing (CMP) method until the conductor 376 is exposed. In this manner, the conductor 376 serving as a wiring, a terminal, a pad, or the like can be formed over the substrate 310.

Like the insulator 324, the insulator 380 is preferably formed using a film having a barrier property that prevents diffusion of impurities such as water and hydrogen, for example. That is, the insulator 380 is preferably formed using any of the materials that can be used for the insulator 324. Like the insulator 326, the insulator 380 may be formed using an insulator having a relatively low dielectric constant to reduce parasitic capacitance generated between wirings, for example. That is, the insulator 380 may be formed using any of the materials that can be used for the insulator 326.

The pixel layer PXAL is provided with, for example, a substrate 210, the transistor 200, the light-emitting device 150 (the light-emitting device 150a and the light-emitting device 150b in FIG. 16), and a substrate 102. Moreover, the pixel layer PXAL is provided with, for example, an insulator 220, an insulator 222, an insulator 226, an insulator 250, an insulator 111a, an insulator 111b, an insulator 112, an insulator 113, an insulator 162, and a resin layer 163. Furthermore, the pixel layer PXAL is provided with, for example, the conductor 216, a conductor 228, a conductor 230, a conductor 121 (a conductor 121a and a conductor 121b in FIG. 16), a conductor 122, and a conductor 123.

An insulator 202 in FIG. 16 functions as a bonding layer together with the insulator 380, for example. The insulator 202 preferably contains, for example, the same component as the material used for the insulator 380.

The substrate 210 is provided above the insulator 202. In other words, the insulator 202 is formed on the bottom surface of the substrate 210. The substrate 210 is preferably a substrate that can be used as the substrate 310, for example. Note that in the description of the display apparatus 1000 in FIG. 16, the substrate 310 is a semiconductor substrate containing silicon as a material.

On the substrate 210, the transistor 200 is formed, for example. Being formed on the substrate 210 that is a semiconductor substrate containing silicon as a material, the transistor 200 functions as a Si transistor. Note that refer to the description of the transistor 300 for the structure of the transistor 200.

Above the transistor 200, the insulator 220 and the insulator 222 are provided. Like the insulator 320, the insulator 220 has functions of an interlayer insulating film and a planarization film, for example. Like the insulator 322, the insulator 222 has functions of an interlayer insulating film and a planarization film, for example.

A plurality of opening portions are provided in the insulator 220 and the insulator 222. The plurality of opening portions are formed in regions overlapping with a source and a drain of the transistor 200, a region overlapping with the conductor 376, and the like. The conductor 228 is formed in each of the opening portions formed in the regions overlapping with the source and the drain of the transistor 200, among the plurality of opening portions. An insulator 214 is formed on the side surface of the opening portion formed in the region overlapping with the conductor 376, among the other opening portions, and the conductor 216 is formed in the remaining space of the opening portion. The conductor 216 is sometimes particularly referred to as a TSV (Through Silicon Via).

For the conductor 216 or the conductor 228, any of the materials usable for the conductor 328 can be used, for example. In particular, the conductor 216 is preferably formed using the same material as the conductor 376.

The insulator 214 has a function of insulating the conductor 216 from the substrate 210, for example. Note that the insulator 214 is preferably formed using, for example, any of the materials that can be used for the insulator 320 or the insulator 324.

The insulator 380 and the conductor 376 that are formed over the substrate 310 are bonded to the insulator 202 and the conductor 216 that are formed on the substrate 210 by a bonding step, for example.

Before the bonding step, for example, planarization treatment is performed to make the surfaces of the insulator 380 and the conductor 376 level with each other on the substrate 310 side. In a similar manner, planarization treatment is performed to make the surfaces of the insulator 202 and the conductor 216 level with each other on the substrate 210 side.

In the case where bonding of the insulator 380 and the insulator 202, i.e., bonding of insulating layers, is performed in the bonding step, a hydrophilic bonding method or the like can be employed in which, after high planarity is obtained by polishing or the like, the surfaces subjected to hydrophilicity treatment with oxygen plasma or the like are brought into contact to be bonded to each other temporarily, and then dehydrated by heat treatment to perform final bonding. The hydrophilic bonding method can also cause bonding at an atomic level; thus, mechanically excellent bonding can be obtained.

When bonding of the conductor 376 and the conductor 216, i.e., bonding of the conductors, is performed, a surface activated bonding method can be employed in which an oxide film, a layer adsorbing impurities, and the like on the surface are removed by sputtering treatment or the like and the cleaned and activated surfaces are brought into contact to be bonded to each other. Alternatively, a diffusion bonding method in which the surfaces are bonded to each other by using temperature and pressure together can be employed, for example. Both methods cause bonding at an atomic level; thus, not only electrically but also mechanically excellent bonding can be obtained.

Through the above-described bonding step, the conductor 376 on the substrate 310 side can be electrically connected to the conductor 216 on the substrate 210 side. In addition, mechanically strong connection can be established between the insulator 380 on the substrate 310 side and the insulator 202 on the substrate 210 side.

In the case where the substrate 310 and the substrate 210 are bonded to each other, the insulating layers and the metal layers coexist on their bonding surfaces; thus, the surface activated bonding method and the hydrophilic bonding method are performed in combination, for example. For example, it is possible to employ a method in which the surfaces are made clean after polishing, the surfaces of the metal layers are subjected to antioxidant treatment and then hydrophilicity treatment, and bonding is performed. Furthermore, hydrophilicity treatment may be performed on the surfaces of the metal layers being hardly oxidizable metal such as gold.

Note that the substrate 310 and the substrate 210 may be bonded to each other by a bonding method other than the above-described methods. For example, as the bonding method of the substrate 310 and the substrate 210, flip-chip bonding may be employed. In the case of employing flip-chip bonding, a connection terminal such as a bump may be provided above the conductor 376 on the substrate 310 side or below the conductor 216 on the substrate 210 side. Flip-chip bonding can be performed by, for example, injecting a resin containing anisotropic conductive particles between the insulator 380 and the insulator 202 and between the conductor 376 and the conductor 216, or by using a Sn—Ag solder. Alternatively, an ultrasonic bonding method can be employed in the case where the bump and a conductor connected to the bump are each gold. To reduce thermal stress, physical stress such as an impact, or the like, the above-described flip-chip bonding may be combined with injection of an underfill agent between the insulator 380 and the insulator 202 and between the conductor 376 and the conductor 216. Furthermore, a die bonding film may be used in bonding of the substrate 310 and the substrate 210, for example.

An insulator 224 and the insulator 226 are stacked in this order over the insulator 222, the insulator 214, the conductor 216, and the conductor 228.

Like the insulator 324, the insulator 224 is preferably a barrier insulating film preventing diffusion of impurities such as water and hydrogen to the region above the insulator 224. Thus, the insulator 224 is preferably formed using any of the materials that can be used for the insulator 324, for example.

Like the insulator 326, the insulator 226 is preferably an interlayer film with a low permittivity. Thus, the insulator 226 is preferably formed using any of the materials that can be used for the insulator 326, for example.

In the insulator 224 and the insulator 226, the conductor 230 electrically connected to the transistor 200, the light-emitting device 150, and the like is embedded. Note that the conductor 230 has a function of a plug or a wiring. Note that the conductor 230 can be formed using any of the materials that can be used for the conductor 328 and the conductor 330, for example.

Over the insulator 224 and the insulator 226, the insulator 250, the insulator 111a, and the insulator 111b are stacked in this order.

Like the insulator 324, the insulator 250 is preferably formed using an insulator having a barrier property against impurities such as water and hydrogen. Thus, the insulator 250 can be formed using any of the materials that can be used for the insulator 324 or the like, for example.

As each of the insulator 111a and the insulator 111b, a variety of inorganic insulating films such as an oxide insulating film, a nitride insulating film, an oxynitride insulating film, and a nitride oxide insulating film can be suitably used. As the insulator 111a, for example, an oxide insulating film or an oxynitride insulating film, such as a silicon oxide film, a silicon oxynitride film, or an aluminum oxide film, is preferably used. As the insulator 111b, for example, a nitride insulating film or a nitride oxide insulating film, such as a silicon nitride film or a silicon nitride oxide film, is preferably used. More specifically, it is preferable that a silicon oxide film be used as the insulator 111a and a silicon nitride film be used as the insulator 111b. The insulator 111b preferably functions as an etching protective film. Alternatively, a nitride insulating film or a nitride oxide insulating film may be used as the insulator 111a, and an oxide insulating film or an oxynitride insulating film may be used as the insulator 111b. Although this embodiment describes an example in which a depressed portion is provided in the insulator 111b, a depressed portion is not necessarily provided in the insulator 111b.

An opening portion is formed in regions of the insulator 250, the insulator 111a, and the insulator 111b that overlap with part of the conductor 230, and the conductor 121 is provided to fill the opening portion. Note that in this specification and the like, the conductor 121a and the conductor 121b illustrated in FIG. 16 are collectively referred to as the conductor 121. Note that the conductor 121 can be provided using a material similar to those for the conductor 328 and the conductor 330.

A pixel electrode described in this embodiment contains, for example, a material that reflects visible light, and a counter electrode contains a material that transmits visible light.

The display apparatus 1000 has a top-emission structure. Light from the light-emitting device is emitted toward the substrate 102. For the substrate 102, a material having a high visible-light-transmitting property is preferably used.

The light-emitting device 150a and the light-emitting device 150b are provided above the conductor 121.

Here, the light-emitting device 150a and the light-emitting device 150b will be described.

The light-emitting device described in this embodiment refers to a self-luminous light-emitting device such as an organic EL element (also referred to as an OLED (Organic Light Emitting Diode)). The light-emitting device electrically connected to the pixel circuit can be a self-luminous light-emitting device such as an LED (Light Emitting Diode), a micro LED, a QLED (Quantum-dot Light Emitting Diode), or a semiconductor laser.

A conductor 122a and a conductor 122b can be formed in the following manner, for example: a conductive film is formed over the insulator 111b, the conductor 121a, and the conductor 121b and the conductive film is subjected to a patterning step, an etching step, and the like.

The conductor 122a and the conductor 122b function respectively as anodes of the light-emitting device 150a and the light-emitting device 150b included in the display apparatus 1000, for example.

Indium tin oxide (sometimes referred to as ITO) or the like can be used for the conductor 122a and the conductor 122b, for example.

Each of the conductor 122a and the conductor 122b may have a stacked-layer structure of two or more layers instead of a single-layer structure. For example, a conductor having a high visible-light reflectance can be used as the first-layer conductor and a conductor having a high light-transmitting property can be used as the uppermost-layer conductor. Examples of a conductor having a high visible-light reflectance include silver, aluminum, and an alloy film of silver (Ag), palladium (Pd), and copper (Cu) (Ag—Pd—Cu (APC) film). Examples of a conductor having a high light-transmitting property include indium tin oxide described above. The conductor 122a and the conductor 122b can each be, for example, a stacked-layer film in which aluminum is held between a pair of titanium films (a film in which Ti, Al, and Ti are stacked in this order), a stacked-layer film in which silver is held between a pair of indium tin oxide films (a film in which ITO, Ag, and ITO are stacked in this order), or the like.

An EL layer 141a is provided over the conductor 122a. An EL layer 141b is provided over the conductor 122b.

The EL layer 141a and the EL layer 141b preferably include light-emitting layers emitting light of different colors. For example, the EL layer 141a can include a light-emitting layer emitting light of any one of red (R), green (G), and blue (B), and the EL layer 141b can include a light-emitting layer emitting light of one of the other two colors. Although not illustrated in FIG. 16, in the case where an EL layer different from the EL layer 141a and the EL layer 141b is provided, the EL layer can include a light-emitting layer emitting light of the remaining one color. Thus, the display apparatus 1000 may have a structure (an SBS structure) in which light-emitting layers of different colors are formed over a plurality of pixel electrodes (the conductor 121a and the conductor 121b).

Note that the combination of colors of light emitted from the light-emitting layers included in the EL layer 141a and the EL layer 141b is not limited to the above, and a color such as cyan, magenta, or yellow may also be used, for example. The number of colors of light emitted from the light-emitting devices 150 included in the display apparatus 1000, which is three in the above example, may be two, three, or four or more.

The EL layer 141a and the EL layer 141b may each include one or more of an electron-injection layer, an electron-transport layer, a hole-injection layer, and a hole-transport layer in addition to the layer containing a light-emitting organic compound (the light-emitting layer).

The EL layer 141a and the EL layer 141b can be formed, for example, by an evaporation method (a vacuum evaporation method or the like), a coating method (a dip coating method, a die coating method, a bar coating method, a spin coating method, a spray coating method, or the like), or a printing method (an inkjet method, a screen printing (stencil) method, an offset printing (planography) method, a flexography (relief printing) method, a gravure printing method, a micro-contact printing method, or the like).

In the case where a film formation method such as the coating method or the printing method is employed, a high-molecular compound (e.g., an oligomer, a dendrimer, or a polymer), a middle-molecular compound (a compound between a low-molecular compound and a high-molecular compound, which has a molecular weight greater than or equal to 400 and less than or equal to 4000, for example), an inorganic compound (e.g., a quantum dot material), or the like can be used. As the quantum dot material, a colloidal quantum dot material, an alloyed quantum dot material, a core-shell quantum dot material, a core quantum dot material, or the like can be used.

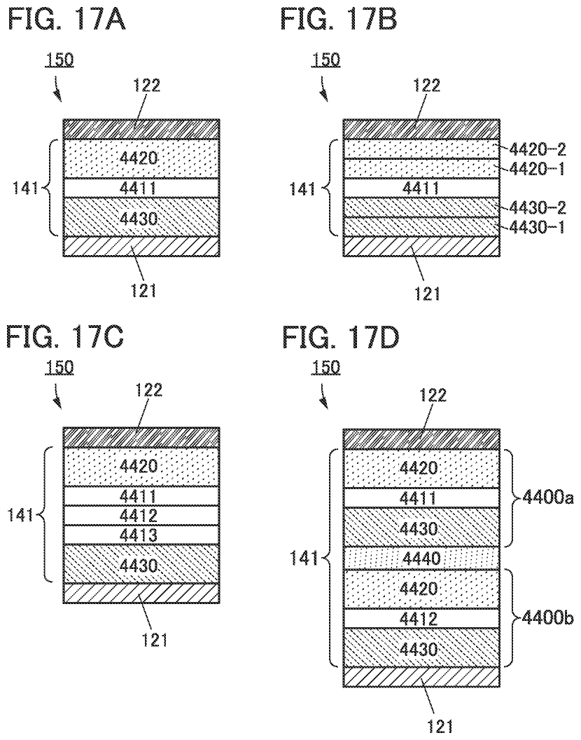

Like the light-emitting device 150 illustrated in FIG. 17A, for example, the light-emitting device 150a and the light-emitting device 150b in FIG. 16 can each include a layer that includes a layer 4420, a light-emitting layer 4411, and a layer 4430.

The layer 4420 can include, for example, a layer containing a substance with a high electron-injection property (an electron-injection layer), a layer containing a substance with a high electron-transport property (an electron-transport layer), and the like. The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes (the conductor 121 and the conductor 122 described later), can function as a single light-emitting unit, and the structure in FIG. 17A is referred to as a single structure in this specification and the like.

FIG. 17B is a modification example of the EL layer 141 included in the light-emitting device 150 illustrated in FIG. 17A. Specifically, the light-emitting device 150 illustrated in FIG. 17B includes a layer 4430-1 over the conductor 121, a layer 4430-2 over the layer 4430-1, the light-emitting layer 4411 over the layer 4430-2, a layer 4420-1 over the light-emitting layer 4411, a layer 4420-2 over the layer 4420-1, and the conductor 122 over the layer 4420-2. For example, when the conductor 121 functions as an anode and the conductor 122 functions as a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, when the conductor 121 functions as a cathode and the conductor 122 functions as an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layer structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 17C is also a variation of the single structure.

A stack including layers such as the layer 4420, the light-emitting layer 4411, and the layer 4430 is sometimes referred to as a light-emitting unit. A plurality of light-emitting units can be connected in series with an intermediate layer (a charge-generation layer) therebetween. Specifically, a light-emitting unit 4400a and a light-emitting unit 4400b, which are a plurality of light-emitting units, can be connected in series with an intermediate layer (a charge-generation layer) 4440 therebetween as illustrated in FIG. 17D. Note that such a structure is referred to as a tandem structure in this specification. A tandem structure may be rephrased as, for example, a stack structure in this specification and the like. Note that a light-emitting device capable of high-luminance light emission can be obtained when the light-emitting device has a tandem structure. By having a tandem structure, a light-emitting device presumably has increased emission efficiency and an extended lifetime, for example. In the case where the light-emitting device 150 of the display apparatus 1000 in FIG. 16 has a tandem structure, the EL layer 141 can include, for example, the layer 4420, the light-emitting layer 4411, and the layer 4430 that are included in the light-emitting unit 4400a, the intermediate layer 4440, and the layer 4420, the light-emitting layer 4412, and the layer 4430 that are included in the light-emitting unit 4400b.

In displaying white, the aforementioned SBS structure consumes lower power than the aforementioned single structure and tandem structure. To reduce power consumption, the SBS structure is thus suitably used. Meanwhile, the single structure and the tandem structure are suitable in terms of lower manufacturing cost or higher manufacturing yield because the manufacturing processes of the single structure and the tandem structure are simpler than that of the SBS structure.

The emission color of the light-emitting device 150 can be red, green, blue, cyan, magenta, yellow, or white depending on the material that constitutes the EL layer 141. Furthermore, the color purity can be further increased when the light-emitting device 150 has a microcavity structure.

The light-emitting device that emits white light preferably contains two or more kinds of light-emitting substances in the light-emitting layer. For example, when white light emission is obtained using two light-emitting layers, the two light-emitting layers are selected such that emission colors of the light-emitting layers are complementary colors. Specifically, when an emission color of a first light-emitting layer and an emission color of a second light-emitting layer are complementary colors, a light-emitting device can be configured to emit white light as a whole. When white light emission is obtained using three or more light-emitting layers, a light-emitting device is configured to emit white light as a whole by combining emission colors of the three or more light-emitting layers.

The light-emitting layer preferably contains two or more light-emitting substances that emit light of R (red), G (green), B (blue), Y (yellow), O (orange), or the like. Alternatively, the light-emitting layer preferably contains two or more light-emitting substances each of which emits light containing two or more of spectral components of R, G, and B.

As illustrated in FIG. 16, there is a gap between two EL layers of adjacent light-emitting devices. Specifically, in FIG. 16, a depressed portion is formed between the adjacent light-emitting devices, and the insulator 112 is provided to cover the side surfaces (the side surfaces of the conductor 121a, the conductor 122a, and the EL layer 141a and the side surfaces of the conductor 121b, the conductor 122b, and the EL layer 141b) and the bottom surface (a region in the insulator 111b) of the depressed portion. The insulator 162 is formed over the insulator 112 to fill the depressed portion. In this manner, the EL layer 141a and the EL layer 141b are preferably provided so as not to be in contact with each other. This suitably prevents unintentional light emission (also referred to as crosstalk) from being caused by current flowing through two adjacent EL layers (also referred to as lateral leakage current or side leakage current). As a result, the contrast can be increased to achieve a display apparatus with high display quality. Furthermore, with the structure with an extremely low lateral leakage current between light-emitting devices, for example, the display apparatus can perform black display with as little light leakage or the like as possible (such display is also referred to as completely black display).

As an example of the formation method of the EL layer 141a and the EL layer 141b, a method using a photolithography method can be given. For example, the EL layer 141a and the EL layer 141b can be formed in the following manner: an EL film to be the EL layer 141a and the EL layer 141b is formed over the conductor 122 and then subjected to patterning by a photolithography method. Accordingly, a gap can be provided between two EL layers of adjacent light-emitting devices.

In the case where the EL film is subjected to patterning by a photolithography method, damage to the light-emitting layer (e.g., processing damage) or the like might significantly degrade the reliability. In view of the above, in the fabrication of the display apparatus of one embodiment of the present invention, a mask layer or the like is preferably formed over a layer above the light-emitting layer (e.g., a carrier-transport layer or a carrier-injection layer, specifically, an electron-transport layer or an electron-injection layer), followed by the processing of the light-emitting layer into an island shape. Such a method provides a highly reliable display apparatus.

The insulator 112 can be an insulating layer containing an inorganic material. As the insulator 112, an inorganic insulating film such as an oxide insulating film, a nitride insulating film, an oxynitride insulating film, or a nitride oxide insulating film can be used, for example. The insulator 112 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. An aluminum oxide film is particularly preferable because it has high selectivity with respect to the EL layer in etching and has a function of protecting the EL layer during formation of the insulator 162 described later. In particular, when an inorganic insulating film such as an aluminum oxide film, a hafnium oxide film, or a silicon oxide film formed by an ALD (Atomic Layer Deposition) method is used as the insulator 112, the insulator 112 having a small number of pinholes and an excellent function of protecting the EL layer can be formed.

Note that in this specification and the like, an oxynitride refers to a material in which an oxygen content is higher than a nitrogen content, and a nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

The insulator 112 can be formed by a film formation method such as a sputtering method, a CVD method, a PLD (Pulsed Laser Deposition) method, or an ALD method. The insulator 112 is preferably formed by an ALD method achieving good coverage.

The insulator 162 provided over the insulator 112 has a planarization function for the depressed portion of the insulator 112, which is formed between the adjacent light-emitting devices. In other words, the insulator 162 has an effect of improving the planarity of the formation surface of the conductor 123 to be described later. As the insulator 162, for example, an insulating layer containing an organic material can be suitably used. For example, as the insulator 162, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used. For the insulator 162, for example, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. Moreover, for the insulator 162, a photosensitive resin can be used, for example. A photoresist may be used as the photosensitive resin, for example. Note that as the photosensitive resin, a positive photosensitive material or a negative photosensitive material can be used.

A difference between the top surface level of the insulator 162 and the top surface level of the EL layer 141a or the EL layer 141b is preferably less than or equal to 0.5 times, further preferably less than or equal to 0.3 times the thickness of the insulator 162, for example. The insulator 162 may be provided, for example, such that the top surface of the EL layer 141a or the EL layer 141b is at a higher level than the top surface of the insulator 162. Alternatively, the insulator 162 may be provided, for example, such that the top surface of the insulator 162 is at a higher level than the top surface of the light-emitting layer included in the EL layer 141a or the EL layer 141b.

The conductor 123 is provided over the EL layer 141a, the EL layer 141b, the insulator 112, and the insulator 162. The insulator 113 is provided over the light-emitting device 150a and over the light-emitting device 150b.

The conductor 123 functions as, for example, a common electrode for the light-emitting device 150a and the light-emitting device 150b. The conductor 123 preferably contains a conductive material having a light-transmitting property so that light emitted from the light-emitting device 150 can be extracted to above the display apparatus 1000.

The conductor 123 is preferably a light-transmitting and light-reflective material having high conductivity (sometimes referred to as a semi-transmissive and semi-reflective electrode). For example, an alloy of silver and magnesium, or indium tin oxide can be used as the conductor 123.

The insulator 113 is referred to as a protective layer in some cases, and the insulator 113 provided above the light-emitting device 150a and the light-emitting device 150b can increase the reliability of the light-emitting devices. That is, the insulator 113 functions as a passivation film that protects the light-emitting device 150a and the light-emitting device 150b. Thus, the insulator 113 is preferably formed using a material that prevents entry of water or the like. Any of the materials that can be used for the insulator 111a or the insulator 111b can be used for the insulator 113, for example. Specifically, aluminum oxide, silicon nitride, or silicon nitride oxide can be used, for example.

The resin layer 163 is provided over the insulator 113. The substrate 102 is provided over the resin layer 163.

The substrate 102 is preferably a substrate having a light-transmitting property, for example. Using a substrate having a light-transmitting property as the substrate 102 enables extraction of light emitted from the light-emitting device 150a and the light-emitting device 150b to above the substrate 102.

Note that the structure of the display apparatus of one embodiment of the present invention is not limited to that of the display apparatus 1000 illustrated in FIG. 16. The structure of the display apparatus of one embodiment of the present invention may be changed as appropriate.

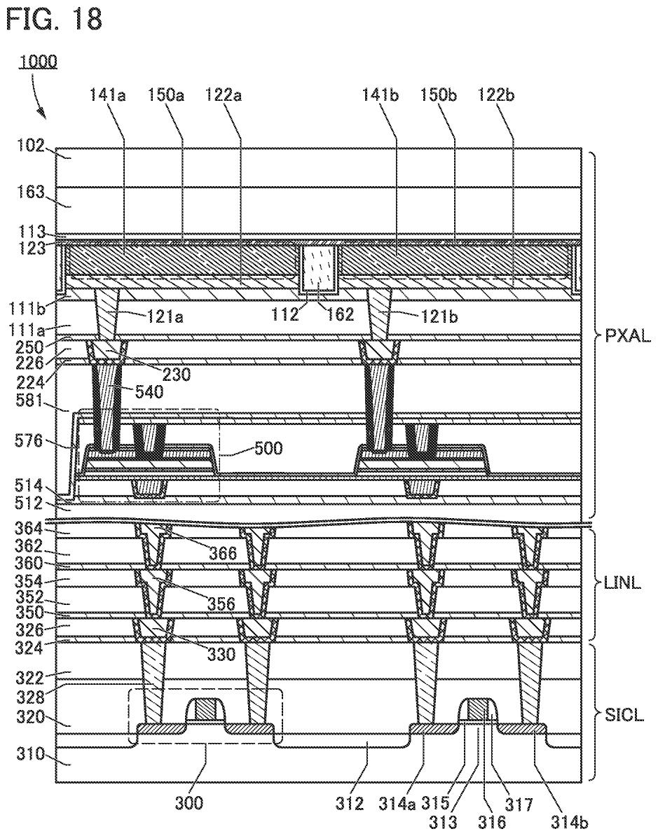

For example, the transistor 200 included in the pixel layer PXAL in the display apparatus 1000 in FIG. 16 may be a transistor including a metal oxide in a channel formation region (hereinafter, referred to as an OS transistor). In the display apparatus 1000 illustrated in FIG. 18, the light-emitting device 150 and a transistor 500 (an OS transistor) that replaces the transistor 200 are provided above the circuit layer SICL and the wiring layer LINL of the display apparatus 1000 in FIG. 16.

In FIG. 18, the transistor 500 is provided over an insulator 512. The insulator 512 is provided above the insulator 364 and the conductor 366, and the insulator 512 is preferably formed using a substance having a barrier property against oxygen and hydrogen. Specifically, for example, the insulator 512 is formed using silicon oxide, silicon oxynitride, silicon nitride oxide, silicon nitride, aluminum oxide, aluminum oxynitride, aluminum nitride oxide, or aluminum nitride.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 300. The film that inhibits hydrogen diffusion is specifically a film from which a small amount of hydrogen is released.

A material similar to that for the insulator 320 can be used for the insulator 512, for example. When a material with a relatively low permittivity is used for these insulators, parasitic capacitance generated between wirings can be reduced. A silicon oxide film, a silicon oxynitride film, or the like can be used as the insulator 512, for example.

An insulator 514 is provided over the insulator 512, and the transistor 500 is provided over the insulator 514. An insulator 576 is formed over the insulator 512 to cover the transistor 500. An insulator 581 is formed over the insulator 576.

As the insulator 514, it is preferable to use a film with a barrier property that prevents diffusion of impurities such as water and hydrogen from the substrate 310, a region where the circuit element or the like below the insulator 512 is provided, or the like into a region where the transistor 500 is provided. Thus, silicon nitride formed by a CVD method can be used for the insulator 514, for example.

The transistor 500 illustrated in FIG. 18 is an OS transistor that includes a metal oxide in a channel formation region, as described above. As the metal oxide, for example, a metal oxide such as an In-M-Zn oxide containing indium, an element M, and zinc (the element M is one or more selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, and magnesium) can be used. Specifically, an oxide containing indium, gallium, and zinc (sometimes referred to as IGZO) may be used as the metal oxide, for example. Alternatively, an oxide containing indium, aluminum, and zinc (sometimes referred to as IAZO) may be used as the metal oxide, for example. Alternatively, an oxide containing indium, aluminum, gallium, and zinc (sometimes referred to as IAGZO) may be used as the metal oxide, for example. Alternatively, besides the above, In—Ga oxide, In—Zn oxide, or indium oxide may be used as the metal oxide.

In particular, the metal oxide functioning as a semiconductor preferably has a band gap greater than or equal to 2 eV, preferably greater than or equal to 2.5 eV. With the use of a metal oxide having such a wide band gap, the off-state current (sometimes referred to as leakage current) of the transistor can be reduced.

In particular, as a driving transistor included in a pixel circuit, a transistor having a sufficiently low off-state current even when the source-drain voltage is high, e.g., an OS transistor, is preferably used. With the use of an OS transistor as the driving transistor, the amount of off-state current flowing through the light-emitting device when the driving transistor is in an off state can be reduced, whereby the luminance of light emitted from the light-emitting device through which an off-state current flows can be sufficiently reduced. Thus, in the case where a driving transistor having a high off-state current and a driving transistor having a low off-state current are compared, a pixel circuit including the driving transistor having a low off-state current can have lower emission luminance than a pixel circuit including the driving transistor having a high off-state current when black display is performed by the pixel circuits. That is, the use of an OS transistor can inhibit black blurring when black display is performed by the pixel circuit.

The off-state current value per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than the off-state current of a Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has higher resistance to a voltage between a source and a drain than a Si transistor, a high voltage can be applied between a source and a drain of an OS transistor. Accordingly, when an OS transistor is used as the driving transistor included in the pixel circuit, a high voltage can be applied between a source and a drain of the OS transistor, so that the amount of current flowing through the light-emitting device can be increased and the emission luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting device can be controlled minutely. Therefore, the emission luminance of the light-emitting device can be controlled minutely (the number of gray levels in the pixel circuit can be increased).

Regarding saturation characteristics of current flowing when transistors operate in a saturation region, even in the case where the source-drain voltage of an OS transistor increases gradually, a more stable constant current (saturation current) can be fed through the OS transistor than through a Si transistor. Thus, by using an OS transistor as the driving transistor, a stable constant current can be fed through a light-emitting device that contains an EL material even when the current-voltage characteristics of the light-emitting device vary, for example. In other words, when an OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to achieve “inhibition of black floating”, “increase in emission luminance”, “increase in gray level”, “inhibition of variation in light-emitting devices”, and the like. Therefore, a display apparatus including the pixel circuit can display a clear and smooth image; as a result, any one or more of the image clearness (image sharpness) and a high contrast ratio can be observed. Note that image clearness (image sharpness) sometimes refers to one or both of the state where motion blur is inhibited and the state where black blurring is inhibited. When the off-state current that can flow through the driving transistor included in the pixel circuit is extremely low, black display performed by the display apparatus can be display with as little light leakage or the like as possible (completely black display).

One or both of the insulator 576 and the insulator 581 preferably function as a barrier insulating film that inhibits diffusion of impurities such as water and hydrogen from above the transistor 500 into the transistor 500. Thus, for at least one of the insulator 576 and the insulator 581, it is preferable to use an insulating material having a function of inhibiting diffusion of an impurity such as a hydrogen atom, a hydrogen molecule, a water molecule, a nitrogen atom, a nitrogen molecule, a nitrogen oxide molecule (e.g., N₂O, NO, or NO₂), or a copper atom (an insulating material through which the impurity is less likely to pass). Alternatively, it is preferable to use an insulating material having a function of inhibiting diffusion of oxygen (e.g., one or both of an oxygen atom and an oxygen molecule) (an insulating material through which the oxygen is less likely to pass).

One or both of the insulator 576 and the insulator 581 is preferably an insulator having a function of inhibiting diffusion of oxygen and impurities such as water and hydrogen. For example, aluminum oxide, magnesium oxide, hafnium oxide, gallium oxide, indium-gallium-zinc oxide, silicon nitride, or silicon nitride oxide can be used for one or both of the insulator 576 and the insulator 581.

An opening portion for forming a plug, a wiring, or the like is provided in the insulator 581, the insulator 576, and one of the source and drain electrodes of the transistor 500. A conductor 540 functioning as a plug, a wiring, or the like is formed in the opening portion.

The insulator 581 is preferably an insulator functioning as an interlayer film, a planarization film, or the like, for example.

The insulator 224 and the insulator 226 are formed above the insulator 581 and the conductor 540. Note that for the description of the insulator 224 and an insulator, a conductor, a circuit element, and the like that are positioned above the insulator 224, refer to the description of the display apparatus 1000 in FIG. 16.

Note that FIG. 16 illustrates a display apparatus formed by bonding the semiconductor substrate provided with the light-emitting device 150, the pixel circuit, and the like and the semiconductor substrate provided with a driver circuit and the like; FIG. 18 illustrates a display apparatus in which the light-emitting device 150, the pixel circuit, and the like are formed over a semiconductor substrate provided with a driver circuit; however, the display apparatus for the electronic device of one embodiment of the present invention is not limited to the those in FIG. 16 and FIG. 18. The display apparatus for the electronic device of one embodiment of the present invention may have a structure in which transistors are formed in only one layer, not a layer structure in which transistors are stacked in two or more layers.

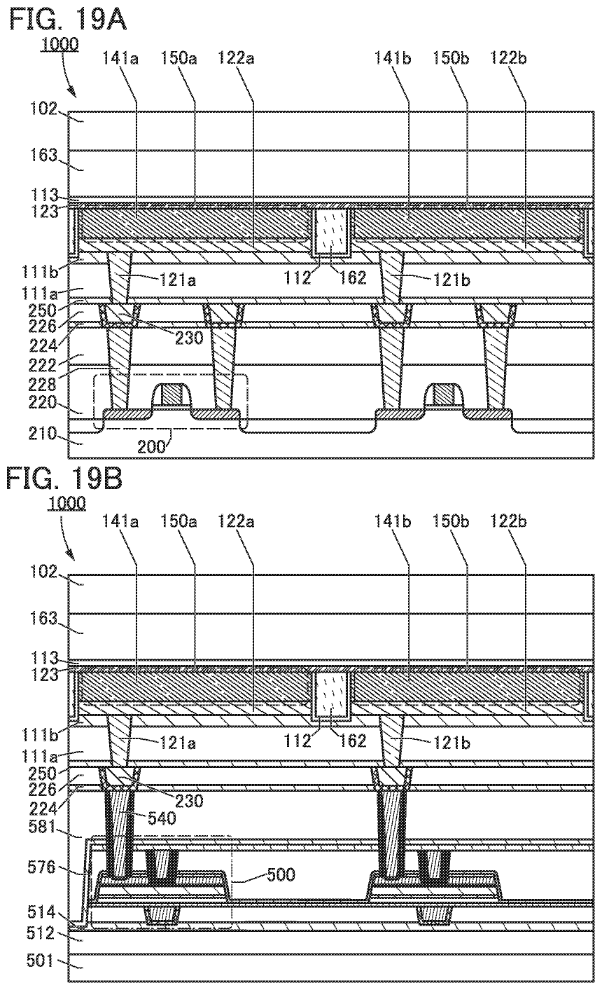

Specifically, for example, the display apparatus for the electronic device of one embodiment of the present invention may include a circuit including the transistor 200 formed over the substrate 210 and the light-emitting device 150 provided above the transistor 200, like the display apparatus 1000 illustrated in FIG. 19A. For another example, a structure may be employed in which the insulator 512 is formed over a substrate 501, the transistor 500 is provided over the insulator 512, and the light-emitting device 150 is provided above the transistor 500, as in the display apparatus 1000 illustrated in FIG. 19B. Note that as the substrate 501, a substrate that can be used as the substrate 310 can be used, for example, and in particular, a glass substrate is preferably used.

The display apparatus for the electronic device of one embodiment of the present invention may have a structure in which transistors are formed in only one layer and the light-emitting device 150 is provided above the transistors, like the display apparatus 1000 illustrated in each of FIG. 19A and FIG. 19B. Although not illustrated, the display apparatus for the electronic device of one embodiment of the present invention may have a layer structure in which transistors are formed in three or more layers.

### <Sealing Structure Example of Display Apparatus>

Next, a sealing structure of the light-emitting device 150 that can be employed for the display apparatus 1000 in FIG. 16 will be described.

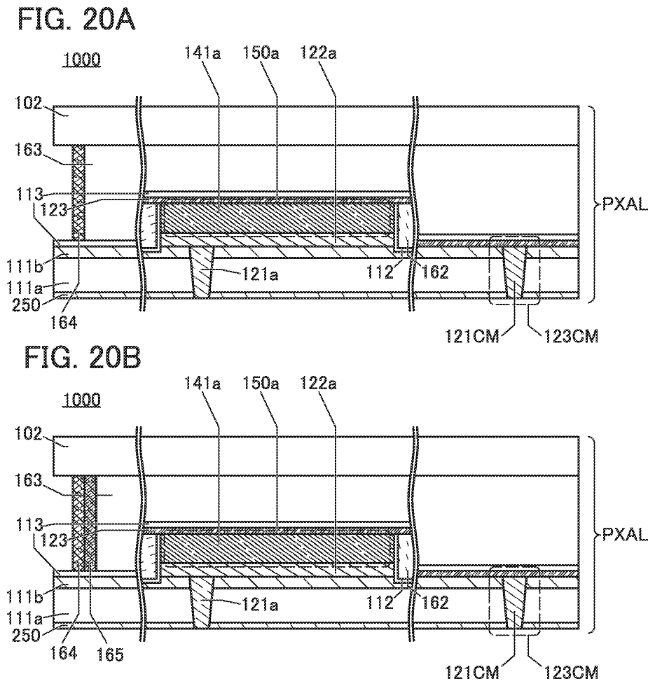

FIG. 20A is a cross-sectional view illustrating an example of a sealing structure that can be employed for the display apparatus 1000 in FIG. 16. Specifically, FIG. 20A illustrates an end portion of the display apparatus 1000 in FIG. 16 and components provided around the end portion. FIG. 20A selectively illustrates only part of the pixel layer PXAL of the display apparatus 1000. Specifically, FIG. 20A illustrates the insulator 250, and insulators, conductors, the light-emitting device 150a, and the like that are positioned above the insulator 250.

In a region 123CM illustrated in FIG. 20A, for example, an opening portion is provided. In the opening portion, a conductor 121CM is provided, for example. The conductor 123 is electrically connected to a wiring provided below the insulator 250 through the conductor 121CM. Thus, a potential (e.g., an anode potential or a cathode potential of the light-emitting device 150a or the like) can be supplied to the conductor 123 functioning as the common electrode. Note that at least one of a conductor included in the region 123CM and a conductor around the region 123CM is referred to as a connection electrode in some cases.

For the conductor 121CM, any of the materials that can be used for the conductor 121 can be used, for example.

In the display apparatus 1000 in FIG. 20A, an adhesive layer 164 is provided at or around the end portion of the resin layer 163. Specifically, the display apparatus 1000 is fabricated such that the insulator 113 and the substrate 102 are bonded to each other with the adhesive layer 164.

The adhesive layer 164 is preferably formed using, for example, a material inhibiting transmission of impurities such as moisture. Using the material for the adhesive layer 164 can increase the reliability of the display apparatus 1000.

A structure in which the insulator 113 and the substrate 102 are bonded to each other with the resin layer 163 therebetween using the adhesive layer 164 is sometimes referred to as a solid sealing structure. In the case where the resin layer 163 in the solid sealing structure has a function of bonding the insulator 113 and the substrate 102 like the adhesive layer 164, the adhesive layer 164 is not necessarily provided.

Meanwhile, a structure in which the insulator 113 and the substrate 102 are bonded to each other with an inert gas filled therebetween, instead of the resin layer 163, by using the adhesive layer 164 is sometimes referred to as a hollow sealing structure (not illustrated). Examples of an inert gas include nitrogen and argon.

In the sealing structure of the display apparatus 1000 illustrated in FIG. 20A, two or more overlapping adhesive layers may be used. For example, as illustrated in FIG. 20B, an adhesive layer 165 may be further provided on the inner side of the adhesive layer 164 (between the adhesive layer 164 and the resin layer 163). Two or more overlapping adhesive layers can inhibit transmission of impurities such as moisture more, further increasing the reliability of the display apparatus 1000.

A desiccant may be mixed into the adhesive layer 165. In that case, the desiccant adsorbs moisture contained in the resin layer 163, insulators, conductors, and EL layers that are provided on the inner side of the adhesive layer 164 and the adhesive layer 165, increasing the reliability of the display apparatus 1000.

Although the solid sealing structure is illustrated in the display apparatus 1000 in FIG. 20B, a hollow sealing structure may be employed.

Furthermore, an inert liquid may be used instead of the resin layer 163 to fill the space in each of the sealing structures of the display apparatus 1000 in FIG. 20A and FIG. 20B. Examples of the inert liquid include a fluorine-based inert liquid.

### <Modification Example of Display Apparatus>

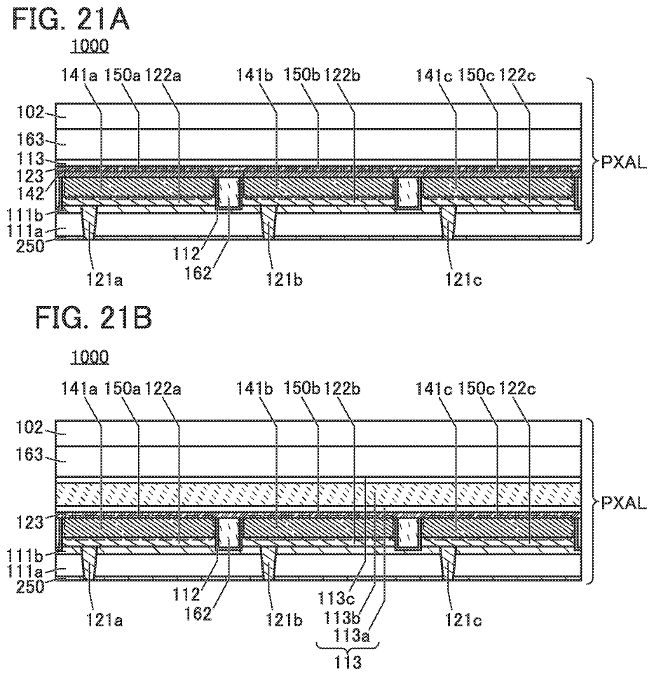

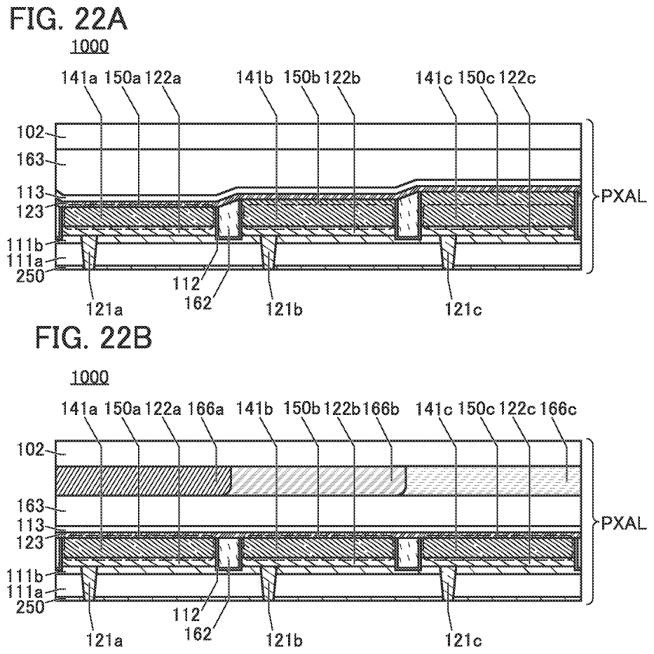

One embodiment of the present invention is not limited to the above-described structures, and the above-described structures can be changed as appropriate in accordance with circumstances. Modification examples of the display apparatus 1000 in FIG. 16 will be described below with reference to FIG. 21A to FIG. 22B. Note that FIG. 21A to FIG. 22B selectively illustrate only part of the pixel layer PXAL of the display apparatus 1000. Specifically, each of FIG. 21A to FIG. 22B illustrates the insulator 250, the insulator 111a, and insulators, conductors, the light-emitting device 150a, and the light-emitting device 150b that are positioned above the insulator 111a. In particular, each of FIG. 21A to FIG. 22B also illustrates a light-emitting device 150c, a conductor 121c, a conductor 122c, and an EL layer 141c.

Note that, for example, the color of light emitted from the EL layer 141c may be different from the colors of light emitted from the EL layer 141a and the EL layer 141b. The display apparatus 1000 may have a structure in which the number of colors of light emitted from the light-emitting device 150a to the light-emitting device 150c is two, for example. Alternatively, for example, the display apparatus 1000 may have a structure in which the number of light-emitting devices 150 is increased so that the number of colors of light emitted from the light-emitting devices is four or more (not illustrated).

The display apparatus 1000 may have a structure in which an EL layer 142 is formed over the EL layer 141a to the EL layer 141c, for example, as illustrated in FIG. 21A. Specifically, for example, in FIG. 17A, the EL layer 142 can include the layer 4420 when the EL layer 141a to the EL layer 141c each include the layer 4430 and the light-emitting layer 4411. In that case, the layer 4420 included in the EL layer 142 functions as a common layer shared by the light-emitting device 150a to the light-emitting device 150c. Similarly, for example, in FIG. 17C, the EL layer 142 can include the layer 4420 when the EL layer 141a to the EL layer 141c each include the layer 4430, the light-emitting layer 4411, the light-emitting layer 4412, and the light-emitting layer 4413, in which case the layer 4420 included in the EL layer 142 functions as a common layer shared by the light-emitting device 150a to the light-emitting device 150c. For another example, in FIG. 17D, the EL layer 142 can include the layer 4420 of the light-emitting unit 4400b when the EL layer 141a to the EL layer 141c each include the layer 4430, the light-emitting layer 4412, and the layer 4420 that are included in the light-emitting unit 4400b, the intermediate layer 4440, and the layer 4430 and the light-emitting layer 4411 that are included in the light-emitting unit 4400a, in which case the layer 4420 of the light-emitting unit 4400a included in the EL layer 142 functions as a common layer shared by the light-emitting device 150a to the light-emitting device 150c.

In the structure of the display apparatus 1000, for example, the insulator 113 may have a stacked-layer structure of two or more layers, instead of a single layer. The insulator 113 may have a three-layer structure that includes an insulator made of an inorganic material as the first layer, an insulator made of an organic material as the second layer, and an insulator made of an inorganic material as the third layer. FIG. 21B illustrates a cross-sectional view of part of the display apparatus 1000 in which the insulator 113 has a multilayer structure including an insulator 113a, an insulator 113b, and an insulator 113c; the insulator 113a is an insulator made of an inorganic material, the insulator 113b is an insulator made of an organic material, and the insulator 113c is an insulator made of an inorganic material.

In the structure of the display apparatus 1000, for example, the EL layer 141a to the EL layer 141c may each have a microcavity structure. In the microcavity structure, for example, the conductor 122 as an upper electrode (common electrode) is formed using a light-transmitting and light-reflective conductive material, the conductor 121 as a lower electrode (pixel electrode) is formed using a light-reflective conductive material, and the distance between the bottom surface of the light-emitting layer and the top surface of the lower electrode, i.e., the thickness of the layer 4430 in FIG. 17A, is set to the thickness corresponding to the wavelength of the color of light emitted from the light-emitting layer included in the EL layer 141.

For example, light that is reflected back from the lower electrode (reflected light) considerably interferes with light that directly enters the upper electrode from the light-emitting layer (incident light); therefore, the optical path length between the lower electrode and the light-emitting layer is preferably adjusted to (2n−1)λ/4 (n is a natural number greater than or equal to 1 and λ is the wavelength of emitted light to be amplified). By adjusting the optical path length, the phases of the reflected light and the incident light each having the wavelength λ can be aligned with each other, and the light emitted from the light-emitting layer can be further amplified. In the case where the reflected light and the incident light have a wavelength other than the wavelength λ, their phases are not aligned with each other, resulting in attenuation without resonation.

The EL layer included in the microcavity structure may include a plurality of light-emitting layers or a single light-emitting layer. The microcavity structure may be combined with, for example, the aforementioned tandem light-emitting device structure in which one light-emitting device is provided with a plurality of EL layers each including one or more light-emitting layers and a charge-generation layer is interposed between the EL layers.

With the microcavity structure, emission intensity with a specific wavelength in the front direction can be increased, whereby power consumption can be reduced. Particularly in the case of a device for XR such as VR or AR, light emitted from the light-emitting device in the front direction often enters the eyes of the user wearing the device; thus, a display apparatus of a device for XR suitably has a microcavity structure. Note that in the case of a display apparatus that displays videos with sub-display pixels of four colors of red, yellow, green, and blue, not only does yellow light emission have the effect of improving luminance, but also a microcavity structure suitable for the wavelength of the corresponding color can be employed in each sub-display pixel, so that the display apparatus can have excellent characteristics.

FIG. 22A shows a cross-sectional view of part of the display apparatus 1000 having a microcavity structure, for example. In the case where the light-emitting device 150a includes a light-emitting layer emitting blue (B) light, the light-emitting device 150b includes a light-emitting layer emitting green (G) light, and the light-emitting device 150c includes a light-emitting layer emitting red (R) light, it is preferable that the EL layer 141a have the smallest thickness, the EL layer 141b have the second largest thickness, and the EL layer 141c have the largest thickness as illustrated in FIG. 22A. Specifically, the thicknesses of the layers 4430 included in the EL layer 141a, the EL layer 141b, and the EL layer 141c may be determined depending on the color of the light emitted from the corresponding light-emitting layer. In that case, the layer 4430 included in the EL layer 141a has the smallest thickness and the layer 4430 included in the EL layer 141c has the largest thickness.

The display apparatus 1000 may include a coloring layer (color filter) or the like, for example. FIG. 22B illustrates a structure in which a coloring layer 166a, a coloring layer 166b, and a coloring layer 166c are included between the resin layer 163 and the substrate 102, for example. Note that the coloring layer 166a to the coloring layer 166c can be formed on the substrate 102, for example. In the case where the light-emitting device 150a includes a light-emitting layer emitting blue (B) light, the light-emitting device 150b includes a light-emitting layer emitting green (G) light, and the light-emitting device 150c includes a light-emitting layer emitting red (R) light, the coloring layer 166a is a blue coloring layer, the coloring layer 166b is a green coloring layer, and the coloring layer 166c is a red coloring layer.

The display apparatus 1000 illustrated in FIG. 22B can be fabricated in the following manner: the substrate 102 provided with the coloring layer 166a to the coloring layer 166c and the substrate 310 over which components up to the light-emitting device 150a to the light-emitting device 150c are formed are bonded to each other with the resin layer 163 therebetween. At this time, the bonding is preferably performed such that the light-emitting device 150a and the coloring layer 166a overlap with each other, the light-emitting device 150b and the coloring layer 166b overlap with each other, and the light-emitting device 150c and the coloring layer 166c overlap with each other. In the display apparatus 1000 provided with the coloring layer 166a to the coloring layer 166c, for example, light emitted from the light-emitting device 150b is not extracted to above the substrate 102 through the coloring layer 166a or the coloring layer 166c, but is extracted to above the substrate 102 through the coloring layer 166b. That is, light emitted from the light-emitting device 150 in an oblique direction (a direction at an elevation angle with the top surface of the substrate 102 used as a horizontal plane) can be blocked in the display apparatus 1000; thus, the viewing angle dependence of the display apparatus 1000 can be reduced, inhibiting the display quality of an image displayed on the display apparatus 1000 from decreasing when the image is viewed from an oblique direction.

The coloring layer 166a to the coloring layer 166c formed on the substrate 102 may be covered with, for example, a resin which is referred to as an overcoat layer. Specifically, the resin layer 163, the overcoat layer, the coloring layer 166a to the coloring layer 166c, and the substrate 102 may be stacked in this order in the display apparatus 1000 (not illustrated). Note that examples of the resin used for the overcoat layer include a thermosetting material having a light-transmitting property and being based on an acrylic resin or an epoxy resin.

The display apparatus 1000 may include, for example, a black matrix (not illustrated) in addition to the coloring layers. The black matrix provided between the coloring layer 166a and the coloring layer 166b, between the coloring layer 166b and the coloring layer 166c, and between the coloring layer 166c and the coloring layer 166a can block more light emitted from the light-emitting device 150 in an oblique direction (a direction at an elevation angle with the top surface of the substrate 102 used as a horizontal plane) in the display apparatus 1000; thus, the display quality of an image displayed on the display apparatus 1000 can be more prevented from decreasing when the image is viewed from an oblique direction.

In the case where the display apparatus includes coloring layers as illustrated in FIG. 22B or the like, the light-emitting device 150a to the light-emitting device 150c of the display apparatus may each be a light-emitting device emitting white light (not illustrated). The light-emitting device can have a single structure or a tandem structure, for example.

In the above-described structure of the display apparatus 1000, the conductor 121a to the conductor 121c serve as anodes and the conductor 122 serves as a cathode; however, the display apparatus 1000 may have a structure in which the conductor 121a to the conductor 121c serve as cathodes and the conductor 122 serves as an anode. That is, in the above-described fabrication process, the stacking order of the hole-injection layer, the hole-transport layer, the light-emitting layer, the electron-transport layer, and the electron-injection layer that are included in the EL layer 141a to the EL layer 141c and the EL layer 142 may be reversed.

### <Structure Example of Insulator 162>

Next, cross-sectional structures of a region including the insulator 162 and its periphery in the display apparatus 1000 will be described.

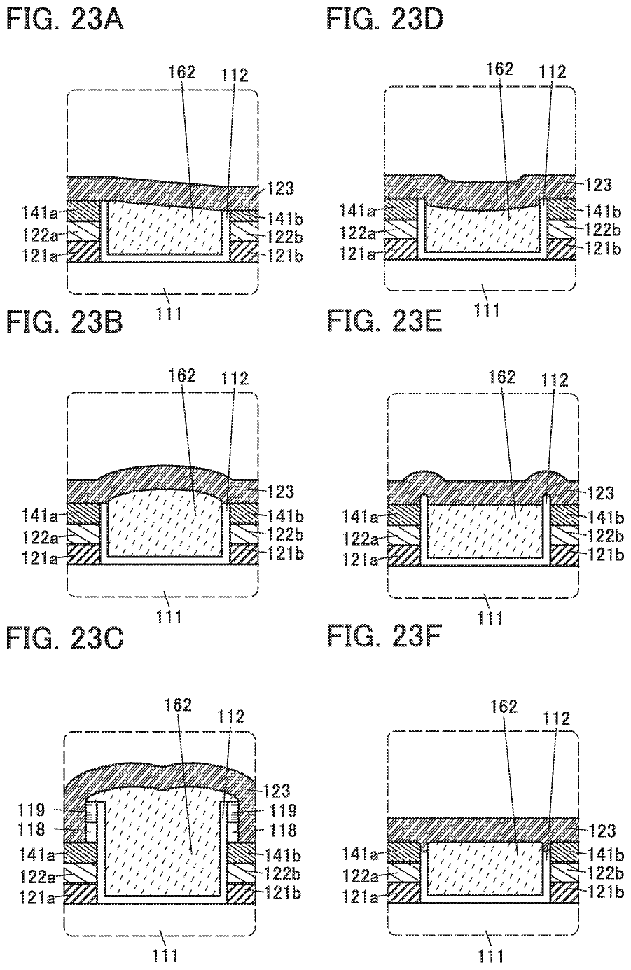

FIG. 23A illustrates an example in which the EL layer 141a and the EL layer 141b have different thicknesses. The top surface level of the insulator 112 is equal to or substantially equal to the top surface level of the EL layer 141a on the EL layer 141a side, and is equal to or substantially equal to the top surface level of the EL layer 141b on the EL layer 141b side. The top surface of the insulator 112 has a gentle slope such that the side closer to the EL layer 141a is higher and the side closer to the EL layer 141b is lower. In this manner, the top surfaces of the insulator 112 and the insulator 162 are preferably level with the top surface of an adjacent EL layer. Alternatively, the top surface levels of the insulators may be equal to the top surface level of any adjacent EL layer so that their top surfaces have a flat portion.

In FIG. 23B, the top surface of the insulator 162 includes a region that is at a higher level than the top surface of the EL layer 141a and the top surface of the EL layer 141b. Moreover, the top surface of the insulator 162 has a convex shape that is gently bulged toward the center.

In FIG. 23C, the top surface of the insulator 112 includes a region that is at a higher level than the top surface of the EL layer 141a and the top surface of the EL layer 141b. In a region including the insulator 162 and its periphery, the display apparatus 1000 includes a first region positioned over at least one of a mask layer 118 and a mask layer 119. The first region is at a higher level than the top surface of the EL layer 141a and the top surface of the EL layer 141b, and part of the insulator 162 is formed in the first region. In the region including the insulator 162 and its periphery, the display apparatus 1000 includes a second region positioned over at least one of the mask layer 118 and the mask layer 119. The second region is at a higher level than the top surface of the EL layer 141a and the top surface of the EL layer 141b, and part of the insulator 162 is formed in the second region.

In FIG. 23D, the top surface of the insulator 162 includes a region that is at a lower level than the top surface of the EL layer 141a and the top surface of the EL layer 141b. Moreover, the top surface of the insulator 162 has a concave shape that is gently recessed toward the center.

In FIG. 23E, the top surface of the insulator 112 includes a region that is at a higher level than the top surface of the EL layer 141a and the top surface of the EL layer 141b. That is, the insulator 112 protrudes from the formation surface of the EL layer 141 and forms a projecting portion.

In formation of the insulator 112, for example, when the insulator 112 is formed to be level with or substantially level with the mask layer, a shape such that the insulator 112 protrudes is sometimes formed as illustrated in FIG. 23E.

In FIG. 23F, the top surface of the insulator 112 includes a region that is at a lower level than the top surface of the EL layer 141a and the top surface of the EL layer 141b. That is, the insulator 112 forms a depressed portion on the formation surface of the EL layer 141.

As described above, the insulator 112 and the insulator 162 can have a variety of shapes.

### <Structure Example of Pixel Circuit>

Here, structure examples of a pixel circuit that can be included in the pixel layer PXAL will be described.

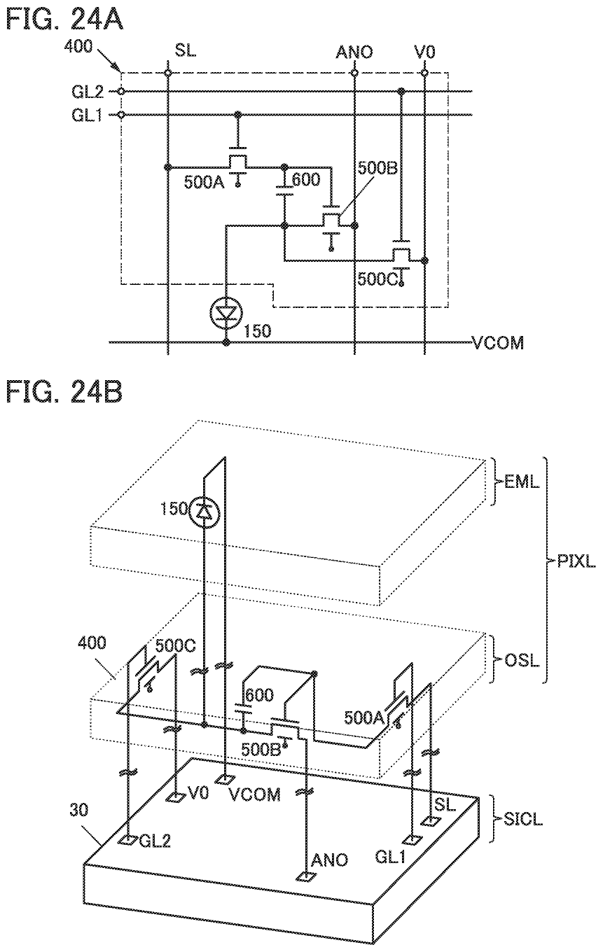

FIG. 24A and FIG. 24B illustrate a structure example of a pixel circuit that can be included in the pixel layer PXAL and the light-emitting device 150 connected to the pixel circuit. FIG. 24A is a diagram illustrating connection of circuit elements included in a pixel circuit 400 provided in the pixel layer PXAL, and FIG. 24B is a diagram schematically illustrating the vertical positional relationship of the circuit layer SICL that is provided with a circuit 30 including the circuit SD, the driver circuit GD, and the like, a layer OSL that is provided with a plurality of transistors of the pixel circuit, and a layer EML that is provided with the light-emitting device 150. Note that the pixel layer PXAL of the display apparatus 1000 illustrated in FIG. 24B includes the layer OSL and the layer EML, for example. A transistor 500A, a transistor 500B, a transistor 500C, or the like included in the layer OSL illustrated in FIG. 24B corresponds to the transistor 200 in FIG. 16. The light-emitting device 150 included in the layer EML illustrated in FIG. 24B corresponds to the light-emitting device 150a or the light-emitting device 150b in FIG. 16.

The pixel circuit 400 illustrated as an example in FIG. 24A and FIG. 24B includes the transistor 500A, the transistor 500B, the transistor 500C, and a capacitor 600. The transistor 500A, the transistor 500B, and the transistor 500C can be transistors that can be used as the transistor 200 described above as an example. That is, the transistor 500A, the transistor 500B, and the transistor 500C can be Si transistors. Alternatively, the transistor 500A, the transistor 500B, and the transistor 500C can be, for example, transistors that can be used as the transistor 500 described above. That is, the transistor 500A, the transistor 500B, and the transistor 500C can be OS transistors. In particular, in the case where the transistor 500A, the transistor 500B, and the transistor 500C are OS transistors, each of the transistor 500A, the transistor 500B, and the transistor 500C preferably includes a back gate electrode, in which case a structure in which the back gate electrode is supplied with the same signals as the gate electrode or a structure in which the back gate electrode is supplied with signals different from those supplied to the gate electrode can be employed. Although each of the transistor 500A, the transistor 500B, and the transistor 500C illustrated in FIG. 24A and FIG. 24B includes a back gate electrode, each of the transistor 500A, the transistor 500B, and the transistor 500C does not necessarily include a back gate electrode.

The transistor 500B includes a gate electrode electrically connected to the transistor 500A, a first electrode electrically connected to the light-emitting device 150, and a second electrode electrically connected to a wiring ANO. The wiring ANO supplies a potential for supplying current to the light-emitting device 150.

The transistor 500A includes a first terminal electrically connected to the gate electrode of the transistor 500B, a second terminal electrically connected to the wiring SL functioning as a source line, and the gate electrode having a function of controlling the conducting state or the non-conducting state on the basis of the potential of a wiring GL1 functioning as a gate line.

The transistor 500C includes a first terminal electrically connected to a wiring V0, a second terminal electrically connected to the light-emitting device 150, and the gate electrode having a function of controlling the conducting state or the non-conducting state on the basis of the potential of a wiring GL2 functioning as a gate line. The wiring V0 is a wiring for supplying a reference potential and a wiring for outputting current flowing through the pixel circuit 400 to the driver circuit 30.

The capacitor 600 includes a conductive film electrically connected to the gate electrode of the transistor 500B and a conductive film electrically connected to the second electrode of the transistor 500C.

The light-emitting device 150 includes a first electrode electrically connected to the first electrode of the transistor 500B and a second electrode electrically connected to a wiring VCOM. The wiring VCOM supplies a potential for supplying current to the light-emitting device 150.

Accordingly, the intensity of light emitted from the light-emitting device 150 can be controlled in accordance with an image signal supplied to the gate electrode of the transistor 500B. Furthermore, variations in the gate-source voltage of the transistor 500B can be inhibited by the reference potential of the wiring V0 supplied through the transistor 500C.

A current value that can be used for setting pixel parameters can be output from the wiring V0. Specifically, the wiring V0 can function as a monitor line for outputting current flowing through the transistor 500B or current flowing through the light-emitting device 150 to the outside. Current output to the wiring V0 is converted into voltage by a source follower circuit or the like and output to the outside, for example. Alternatively, for example, current output to the wiring V0 can be converted into a digital signal by an A-D converter or the like and output to the AI accelerator described in the above embodiment.

Note that in the structure illustrated as an example in FIG. 24B, the wirings electrically connecting the pixel circuit 400 and the driver circuit 30 can be shortened, so that wiring resistance of the wirings can be reduced. Thus, data writing can be performed at high speed, leading to high-speed operation of the display apparatus 1000. Therefore, even when the number of pixel circuits 400 included in the display apparatus 1000 is large, a sufficiently long frame period can be ensured and thus the pixel density of the display apparatus 1000 can be increased. In addition, the increased pixel density of the display apparatus 1000 can increase the resolution of an image displayed on the display apparatus 1000. For example, the pixel density of the display apparatus 1000 can be higher than or equal to 1000 ppi, higher than or equal to 5000 ppi, or higher than or equal to 7000 ppi. Thus, the display apparatus 1000 can be, for example, a display apparatus for AR or VR and can be suitably used in an electronic device with a short distance between a display portion and the user, such as an HMD.

Although FIG. 24A and FIG. 24B illustrate, as an example, the pixel circuit 400 including three transistors in total, the pixel circuit of the electronic device of one embodiment of the present invention is not limited thereto. Structure examples of a pixel circuit that can be used as the pixel circuit 400 will be described below.

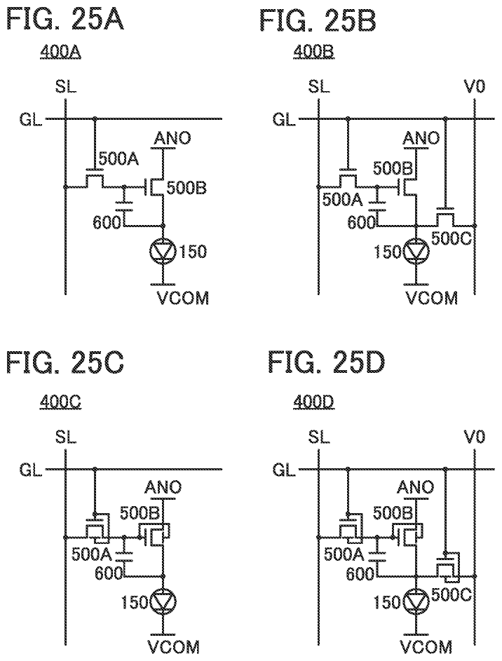

A pixel circuit 400A illustrated in FIG. 25A includes the transistor 500A, the transistor 500B, and the capacitor 600. FIG. 25A illustrates the light-emitting device 150 connected to the pixel circuit 400A. The wiring SL, the wiring GL, the wiring ANO, and the wiring VCOM are electrically connected to the pixel circuit 400A.

A gate of the transistor 500A is electrically connected to the wiring GL, one of a source and a drain of the transistor 500A is electrically connected to the wiring SL, and the other of the source and the drain of the transistor 500A is electrically connected to a gate of the transistor 500B and one electrode of the capacitor 600. One of a source and a drain of the transistor 500B is electrically connected to the wiring ANO and the other of the source and the drain of the transistor 500B is electrically connected to an anode of the light-emitting device 150. The other electrode of the capacitor 600 is electrically connected to the anode of the light-emitting device 150. A cathode of the light-emitting device 150 is electrically connected to the wiring VCOM.

A pixel circuit 400B illustrated in FIG. 25B has a structure in which the transistor 500C is added to the pixel circuit 400A. In addition, the wiring V0 is electrically connected to the pixel circuit 400B.

A pixel circuit 400C illustrated in FIG. 25C is an example of the case where a transistor in which a gate and a back gate are electrically connected to each other is used as each of the transistor 500A and the transistor 500B of the pixel circuit 400A. A pixel circuit 400D illustrated in FIG. 25D is an example of the case where such transistors are used in the pixel circuit 400B. Thus, current that can flow through the transistors can be increased. Note that although a transistor in which a pair of gates are electrically connected to each other is used as all the transistors here, one embodiment of the present invention is not limited thereto. A transistor that includes a pair of gates electrically connected to different wirings may be used. For example, when a transistor in which one of gates is electrically connected to a source is used, the reliability can be increased.

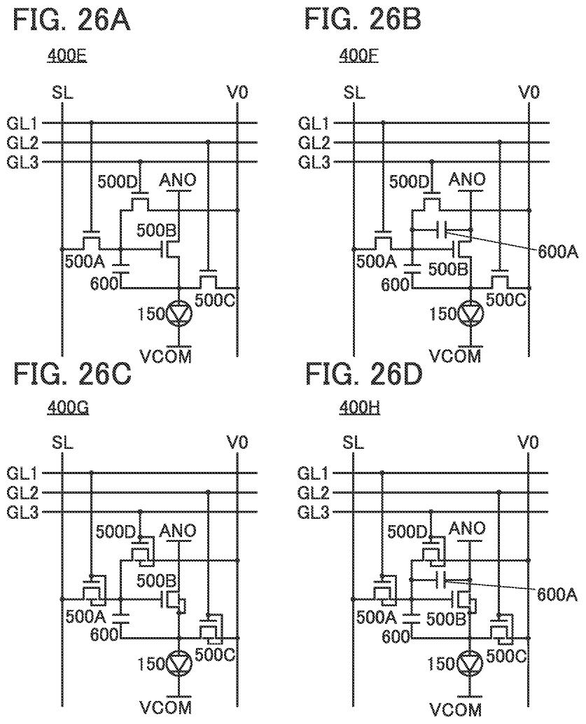

A pixel circuit 400E illustrated in FIG. 26A has a structure in which a transistor 500D is added to the pixel circuit 400B. Three wirings (the wiring GL1, the wiring GL2, and a wiring GL3) functioning as gate lines are electrically connected to the pixel circuit 400E.

A gate of the transistor 500D is electrically connected to the wiring GL3, one of a source and a drain of the transistor 500D is electrically connected to the gate of the transistor 500B, and the other of the source and the drain of the transistor 500D is electrically connected to the wiring V0. The gate of the transistor 500A is electrically connected to the wiring GL1, and the gate of the transistor 500C is electrically connected to the wiring GL2.

When the transistor 500C and the transistor 500D are turned on at the same time, the source and the gate of the transistor 500B have the same potential, so that the transistor 500B can be turned off. Thus, current flowing through the light-emitting device 150 can be blocked forcibly. Such a pixel circuit is suitable for the case of using a display method in which a display period and a non-lighting period are alternately provided.

A pixel circuit 400F illustrated in FIG. 26B is an example of the case where a capacitor 600A is added to the pixel circuit 400E. The capacitor 600A functions as a storage capacitor.

A pixel circuit 400G illustrated in FIG. 26C and a pixel circuit 400H illustrated in FIG. 26D are respectively examples of the cases where transistors each including a gate and a back gate that are electrically connected to each other are used in the pixel circuit 400E and the pixel circuit 400F. A transistor in which a gate and a back gate are electrically connected to each other is used as each of the transistor 500A, the transistor 500C, and the transistor 500D, and a transistor in which a gate is electrically connected to a source is used as the transistor 500B.

### <Schematic Plan View and Schematic Cross-Sectional View of Light-Emitting Device>

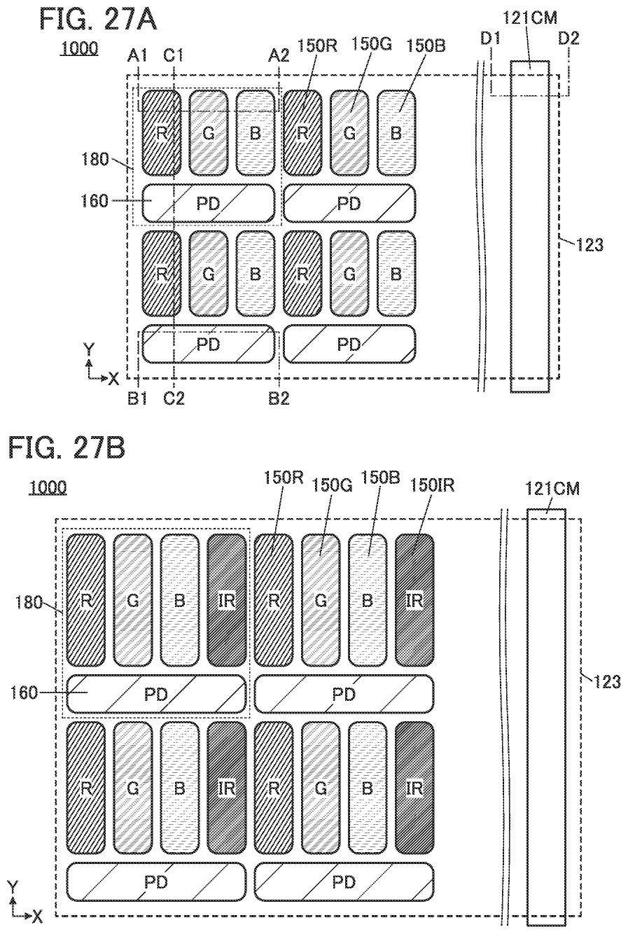

FIG. 27A is a schematic plan view illustrating a structure example of the case where light-emitting devices and a light-receiving device are arranged in one pixel in the display apparatus 1000 of one embodiment of the present invention. The display apparatus 1000 includes a plurality of light-emitting devices 150R that emit red light, a plurality of light-emitting devices 150G that emit green light, a plurality of light-emitting devices 150B that emit blue light, and a plurality of light-receiving devices 160. In FIG. 27A, light-emitting regions of the light-emitting devices 150 are denoted by R, G, and B to easily differentiate the light-emitting devices 150. In addition, light-receiving regions of the light-receiving devices 160 are denoted by PD.

The light-emitting devices 150R, the light-emitting devices 150G, the light-emitting devices 150B, and the light-receiving devices 160 are each arranged in a matrix. FIG. 27A illustrates an example in which the light-emitting devices 150R, the light-emitting devices 150G, and the light-emitting devices 150B are arranged in the X direction and the light-receiving devices 160 are arranged thereunder. FIG. 27A also illustrates a structure example in which the light-emitting devices 150 that emit light of the same color are arranged in the Y direction intersecting the X direction. In the display apparatus 1000 illustrated in FIG. 27A, a pixel 180 can be composed of, for example, a sub-display pixel including the light-emitting device 150R, a sub-display pixel including the light-emitting device 150G, and a sub-display pixel including the light-emitting device 150B, which are arranged in the X direction, and an image capturing pixel including the light-receiving device 160 and provided under the sub-display pixels.

As each of the light-emitting device 150R, the light-emitting device 150G, and the light-emitting device 150B, an organic EL element such as an OLED (Organic Light Emitting Diode) or a QLED (Quantum-dot Light Emitting Diode) is preferably used. Examples of a light-emitting substance contained in the organic EL element include a substance that emits fluorescent light (a fluorescent material), a substance that emits phosphorescent light (a phosphorescent material), an inorganic compound (e.g., a quantum dot material), and a substance exhibiting thermally activated delayed fluorescence (a thermally activated delayed fluorescent (TADF) material). Note that as a TADF material, a material in which a singlet excited state and a triplet excited state are in a thermal equilibrium state may be used. Since such a TADF material enables a short emission lifetime (excitation lifetime), an efficiency decrease of a light-emitting device in a high-luminance region can be inhibited.

For example, a pn-type or pin-type light-receiving device can be used as the light-receiving device 160. The light-receiving device 160 functions as a photoelectric conversion element that detects light incident on the light-receiving device 160 and generates charge. The amount of generated charge depends on the amount of incident light.

It is particularly preferable to use, as the light-receiving device 160, an organic light-receiving device including a layer containing an organic compound. An organic light-receiving device, which is easily made thin, lightweight, and large in area and has a high degree of freedom for shape and design, can be used in a variety of display apparatuses.

In an electronic device of one embodiment of the present invention, an organic EL element is used as the light-emitting device 150, and an organic light-receiving device is used as the light-receiving device 160. The organic EL elements and the organic light-receiving devices can be formed over one substrate. Thus, the organic light-receiving devices can be incorporated in a display apparatus that includes the organic EL elements. A photolithography method is preferably employed to separate the organic EL elements from each other, separate the organic light-receiving devices from each other, and separate the organic EL element and the organic light-receiving device from each other. This can reduce the interval between the light-emitting devices, that between the organic light-receiving devices, and that between the light-emitting device and the organic light-receiving device, achieving a display apparatus having a higher aperture ratio than that formed using, for example, a shadow mask such as a metal mask.

FIG. 27A illustrates the conductor 123 functioning as a common electrode and the conductor 121CM functioning as a connection electrode. Here, the conductor 121CM is electrically connected to the conductor 123. The conductor 121CM is provided outside a display portion where the light-emitting devices 150 and the light-receiving devices 160 are arranged. In FIG. 27A, the conductor 123 including a region overlapping with the light-emitting devices 150, the light-receiving devices 160, and the conductor 121CM is shown by dashed lines.

The conductor 121CM can be provided along the outer periphery of the display portion. For example, the conductor 121CM may be provided along one side of the outer periphery of the display portion or two or more sides of the outer periphery of the display portion. That is, the top surface shape of the conductor 121CM can be a band shape, an L shape, a square bracket shape, or a tetragon in the case where the top surface shape of the display portion is a rectangle.

FIG. 27B is a schematic plan view illustrating a structure example of the display apparatus 1000 and is a modification example of the display apparatus 1000 illustrated in FIG. 27A. The display apparatus 1000 illustrated in FIG. 27B differs from the display apparatus 1000 illustrated in FIG. 27A in that light-emitting devices 150IR that emit infrared light are included. The light-emitting devices 150IR can emit near-infrared light (light with a wavelength greater than or equal to 750 nm and less than or equal to 1300 nm), for example.

In the example illustrated in FIG. 27B, the light-emitting devices 150IR as well as the light-emitting devices 150R, the light-emitting devices 150G, and the light-emitting devices 150B are arranged in the X direction, and the light-receiving devices 160 are arranged thereunder. The light-receiving device 160 has a function of detecting infrared light.

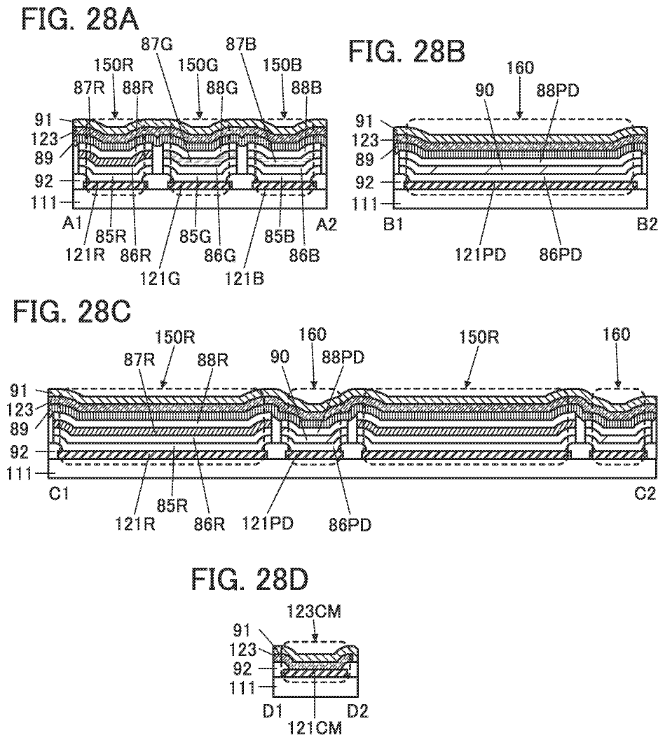

FIG. 28A is a cross-sectional view taken along the dashed-dotted line A1-A2 in FIG. 27A, and FIG. 28B is a cross-sectional view taken along the dashed-dotted line B1-B2 in FIG. 27A. FIG. 28C is a cross-sectional view taken along the dashed-dotted line C1-C2 in FIG. 27A, and FIG. 28D is a cross-sectional view taken along the dashed-dotted line D1-D2 in FIG. 27A. The light-emitting devices 150R, the light-emitting devices 150G, the light-emitting devices 150B, and the light-receiving devices 160 are provided over an insulator 111. In the case where the display apparatus 1000 includes the light-emitting devices 150IR, the light-emitting devices 150IR are provided over the insulator 111.

In the case where the expression “B over A” or “B under A” is used in this specification and the like, for example, A and B do not always need to include a region where they are in contact with each other.

FIG. 28A illustrates a cross-sectional structure example of the light-emitting device 150R, the light-emitting device 150G, and the light-emitting device 150B in FIG. 27A. FIG. 28B illustrates a cross-sectional structure example of the light-receiving device 160 in FIG. 27A.

The light-emitting device 150R includes a conductor 121R functioning as a pixel electrode, a hole-injection layer 85R, a hole-transport layer 86R, a light-emitting layer 87R, an electron-transport layer 88R, a common layer 89, and the conductor 123. The light-emitting device 150G includes a conductor 121G functioning as a pixel electrode, a hole-injection layer 85G, a hole-transport layer 86G, a light-emitting layer 87G, an electron-transport layer 88G, the common layer 89, and the conductor 123. The light-emitting device 150B includes a conductor 121B functioning as a pixel electrode, a hole-injection layer 85B, a hole-transport layer 86B, a light-emitting layer 87B, an electron-transport layer 88B, the common layer 89, and the conductor 123. The light-receiving device 160 includes a conductor 121PD functioning as a pixel electrode, a hole-transport layer 86PD, a light-receiving layer 90, an electron-transport layer 88PD, the common layer 89, and the conductor 123.

As the conductor 121R, the conductor 121G, and the conductor 121B, for example, the conductor 121a, the conductor 121b, and the conductor 121c illustrated in FIG. 21A to FIG. 22B can be used.

The common layer 89 has a function of an electron-injection layer in the light-emitting device 150. Meanwhile, the common layer 89 has a function of an electron-transport layer in the light-receiving device 160. Therefore, the light-receiving device 160 does not necessarily include the electron-transport layer 88PD.

The hole-injection layer 85R, the hole-injection layer 85G, the hole-injection layer 85B, the hole-transport layer 86R, the hole-transport layer 86G, the hole-transport layer 86B, the electron-transport layer 88R, the electron-transport layer 88G, the electron-transport layer 88B, and the common layer 89 can also be referred to as functional layers.

In FIG. 28A, as the pixel electrodes, the conductor 121R, the conductor 121B, and the conductor 121G are provided separately for the respective elements. As the hole-injection layers, the hole-injection layer 85R, the hole-injection layer 85G, and the hole-injection layer 85B are provided separately for the respective elements; as the hole-transport layers, the hole-transport layer 86R, the hole-transport layer 86G, and the hole-transport layer 86B are provided separately for the respective elements; as the light-emitting layers, the light-emitting layer 87R, the light-emitting layer 87G, and the light-emitting layer 87B are provided separately for the respective elements; and as the electron-transport layers, the electron-transport layer 88R, the electron-transport layer 88G, and the electron-transport layer 88B are provided separately for the respective elements. The common layer 89 and the conductor 123 are provided to be shared by the light-emitting device 150R, the light-emitting device 150G, the light-emitting device 150B, and the light-receiving device 160.

The light-emitting device 150 and the light-receiving device 160 may each include a hole-blocking layer and an electron-blocking layer other than the layers illustrated in FIG. 28A. The light-emitting device 150 and the light-receiving device 160 may each include a layer containing, for example, a substance with a bipolar property (a substance with a high electron-transport property and a high hole-transport property).

An insulating layer 92 is provided to cover an end portion of the conductor 121R, an end portion of the conductor 121G, an end portion of the conductor 121B, and an end portion of the conductor 121PD. An end portion of the insulating layer 92 is preferably tapered. The insulating layer 92 is not necessarily provided when not needed.

Note that the insulating layer 92 may be provided to prevent adjacent pixels (e.g., the light-emitting device 150R and the light-emitting device 150G, or the light-emitting device 150G and the light-emitting device 150B) from being electrically short-circuited and emitting light unintentionally, for example. In the case where the light-emitting devices are formed using a metal mask, the insulating layer 92 may be provided to cover end portions of the conductor 121R, the conductor 121G, the conductor 121B, and the conductor 121PD so as to prevent the metal mask from being in contact with the conductor 121R, the conductor 121G, the conductor 121B, and the conductor 121PD. With this structure, the surface of the insulating layer 92 is higher in level than the surfaces of the conductor 121R, the conductor 121G, the conductor 121B, and the conductor 121PD; thus, the metal mask is not in contact with the conductor 121R, the conductor 121G, the conductor 121B, or the conductor 121PD, whereby damage to the surfaces of the conductor 121R, the conductor 121G, the conductor 121B, and the conductor 121PD can be prevented.

For example, the hole-injection layer 85R, the hole-injection layer 85G, the hole-injection layer 85B, and the hole-transport layer 86PD each include a region in contact with the top surface of the conductor 121 and a region in contact with the surface of the insulating layer 92. In addition, an end portion of the hole-injection layer 85R, an end portion of the hole-injection layer 85G, an end portion of the hole-injection layer 85B, and an end portion of the hole-transport layer 86PD are positioned over the insulating layer 92.

A gap is provided between the common layer 89 and the insulating layer 92. This can inhibit contact between the common layer 89 and each of the side surface of the light-emitting layer 87, the side surface of the light-receiving layer 90, the side surface of the hole-transport layer 86, and the side surface of the hole-injection layer 85. Thus, a short circuit in the light-emitting device 150 and a short circuit in the light-receiving device 160 can be inhibited. Note that the gap may be filled with an insulating layer containing an organic material usable for the insulator 162.

The shorter the distance between the adjacent light-emitting layers 87 is, for example, the more easily the gap is formed. For example, when the distance is less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm, the gap can be suitably formed.

A protective layer 91 is provided over the conductor 123. The protective layer 91 has a function of preventing diffusion of impurities such as water into each light-emitting device from above.

The protective layer 91 can have, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 91, for example.

A stacked-layer film of an inorganic insulating film and an organic insulating film can be used as the protective layer 91. For example, a structure in which an organic insulating film is interposed between a pair of inorganic insulating films is preferable. Furthermore, the organic insulating film preferably functions as a planarization film. In that case, the top surface of the organic insulating film can be flat, and accordingly, coverage with the inorganic insulating film thereover is improved, leading to an improvement in barrier property. Since the top surface of the protective layer 91 is flat, in the case where a component (e.g., a color filter, an electrode of a touch sensor, or a lens array) is provided above the protective layer 91, the component is less affected by an uneven shape caused by components therebelow, which is preferable.

FIG. 28A illustrates the light-emitting device 150R in which the conductor 121R, the hole-injection layer 85R, the hole-transport layer 86R, the light-emitting layer 87R, the electron-transport layer 88R, the common layer 89 (electron-injection layer), and the conductor 123 are provided in this order from the bottom, the light-emitting device 150G in which the conductor 121G, the hole-injection layer 85G, the hole-transport layer 86G, the light-emitting layer 87G, the electron-transport layer 88G, the common layer 89 (electron-injection layer), and the conductor 123 are provided in this order from the bottom, and the light-emitting device 150B in which the conductor 121B, the hole-injection layer 85B, the hole-transport layer 86B, the light-emitting layer 87B, the electron-transport layer 88B, the common layer 89 (electron-injection layer), and the conductor 123 are provided in this order from the bottom, and FIG. 28B illustrates the light-receiving device 160 in which the conductor 121PD, the hole-transport layer 86PD, the light-receiving layer 90, the electron-transport layer 88PD, the common layer 89, and the conductor 123 are provided in this order from the bottom; however, the structure of the light-emitting device or the light-receiving device of an electronic device of one embodiment of the present invention is not limited to this example. For example, the light-emitting device 150 may include a conductor functioning as a pixel electrode, an electron-injection layer, an electron-transport layer, a light-emitting layer, a hole-transport layer, a hole-injection layer, and a conductor functioning as a common electrode in this order from the bottom, and the light-receiving device 160 may include a conductor functioning as a pixel electrode, an electron-transport layer, a light-receiving layer, a hole-transport layer, and a conductor functioning as a common electrode in this order from the bottom. In that case, the hole-injection layer included in the light-emitting device 150 can be a common layer, and the common layer can be provided between the hole-transport layer included in the light-receiving device 160 and the common electrode. In addition, the electron-injection layers can be separated between the light-emitting devices 150.

### <Pixel Layout>

Here, a pixel layout that is different from those illustrated in FIG. 27A and FIG. 27B will be described. There is no particular limitation on the arrangement of sub-display pixels, and any of a variety of methods can be employed. Examples of the arrangement of sub-display pixels include stripe arrangement, S-stripe arrangement, matrix arrangement, delta arrangement, Bayer arrangement, and pentile arrangement.

Examples of the top surface shape of the sub-display pixel include polygons such as a triangle, a tetragon (e.g., a rectangle or a square), and a pentagon. Other examples of the top surface shape of the sub-display pixel include the above polygons with rounded corners; an ellipse; and a circle. Here, the top surface shape of the sub-display pixel corresponds to the top surface shape of a light-emitting region of the light-emitting device.

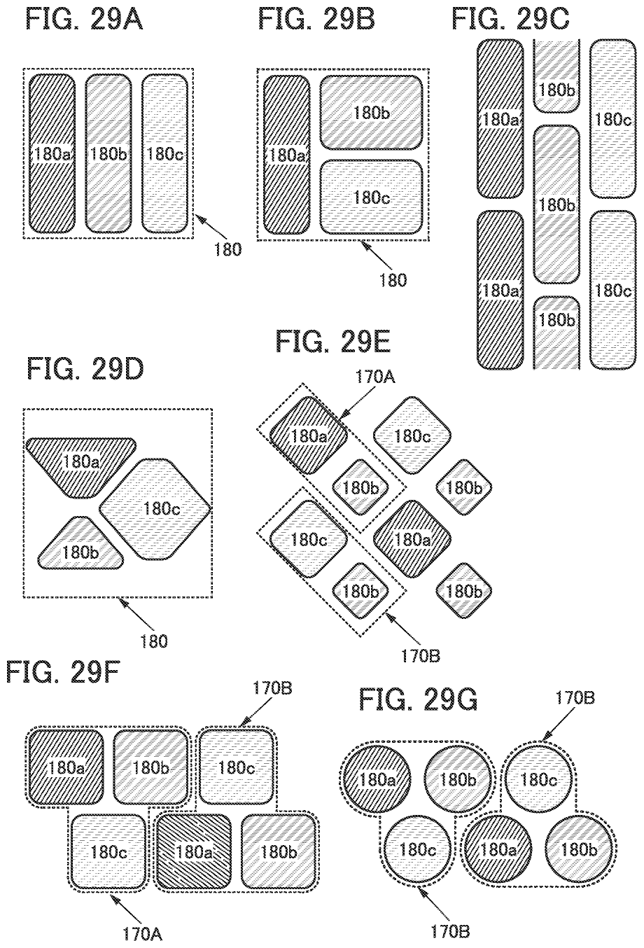

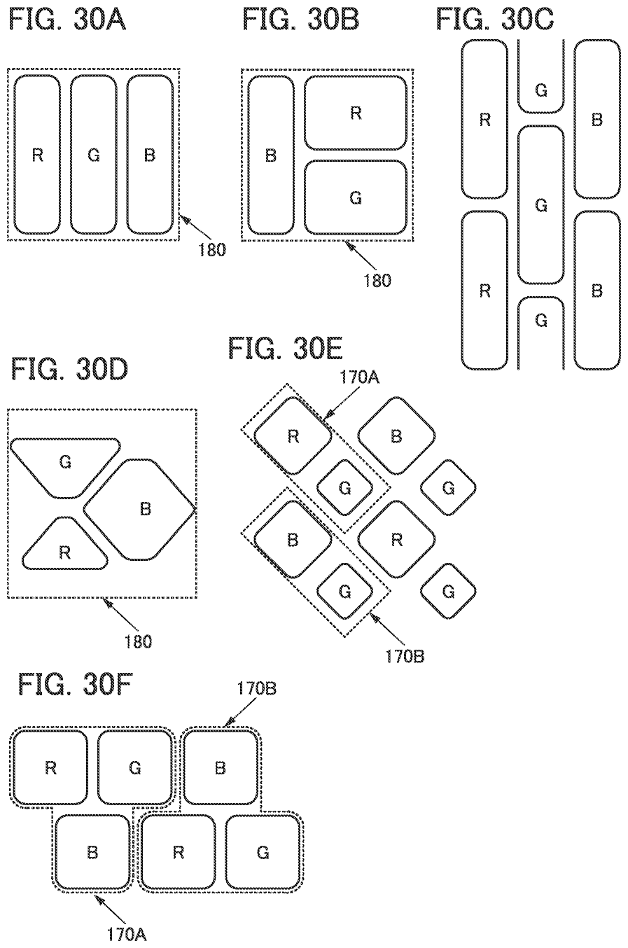

The pixel 180 illustrated in FIG. 29A employs stripe arrangement. The pixel 180 illustrated in FIG. 29A is composed of three sub-display pixels: a sub-display pixel 180a, a sub-display pixel 180b, and a sub-display pixel 180c. For example, as illustrated in FIG. 30A, the sub-display pixel 180a may be a red sub-display pixel R, the sub-display pixel 180b may be a green sub-display pixel G, and the sub-display pixel 180c may be a blue sub-display pixel B.

The pixel 180 illustrated in FIG. 29B employs S-stripe arrangement. The pixel 180 illustrated in FIG. 29B is composed of three sub-display pixels: the sub-display pixel 180a, the sub-display pixel 180b, and the sub-display pixel 180c. For example, as illustrated in FIG. 30B, the sub-display pixel 180a may be the blue sub-display pixel B, the sub-display pixel 180b may be the red sub-display pixel R, and the sub-display pixel 180c may be the green sub-display pixel G.

FIG. 29C illustrates an example in which sub-display pixels of different colors are arranged in a zigzag manner. Specifically, the positions of the top sides of two sub-display pixels arranged in the column direction (e.g., the sub-display pixel 180a and the sub-display pixel 180b or the sub-display pixel 180b and the sub-display pixel 180c) are not aligned in the plan view. For example, as illustrated in FIG. 30C, the sub-display pixel 180a may be the red sub-display pixel R, the sub-display pixel 180b may be the green sub-display pixel G, and the sub-display pixel 180c may be the blue sub-display pixel B.

The pixel 180 illustrated in FIG. 29D includes the sub-display pixel 180a whose top surface has a substantially trapezoidal shape with rounded corners, the sub-display pixel 180b whose top surface has a substantially triangle shape with rounded corners, and the sub-display pixel 180c whose top surface has a substantially tetragonal or substantially hexagonal shape with rounded corners. The sub-display pixel 180a has a larger light-emitting area than the sub-display pixel 180b. In this manner, the shapes and sizes of the sub-display pixels can be determined independently. For example, the size of a sub-display pixel including a light-emitting device with higher reliability can be smaller. For example, as illustrated in FIG. 30D, the sub-display pixel 180a may be the green sub-display pixel G, the sub-display pixel 180b may be the red sub-display pixel R, and the sub-display pixel 180c may be the blue sub-display pixel B.

A pixel 170A and a pixel 170B illustrated in FIG. 29E employ pentile arrangement. FIG. 29E illustrates an example in which the pixels 170A including the sub-display pixel 180a and the sub-display pixel 180b and the pixels 170B including the sub-display pixel 180b and the sub-display pixel 180c are alternately arranged. For example, as illustrated in FIG. 30E, the sub-display pixel 180a may be the red sub-display pixel R, the sub-display pixel 180b may be the green sub-display pixel G, and the sub-display pixel 180c may be the blue sub-display pixel B.

The pixel 170A and the pixel 170B illustrated in FIG. 29F and FIG. 29G employ delta arrangement. The pixel 170A includes two sub-display pixels (the sub-display pixel 180a and the sub-display pixel 180b) in the upper row (first row) and one sub-display pixel (the sub-display pixel 180c) in the lower row (second row). The pixel 170B includes one sub-display pixel (the sub-display pixel 180c) in the upper row (first row) and two sub-display pixels (the sub-display pixel 180a and the sub-display pixel 180b) in the lower row (second row). For example, as illustrated in FIG. 30F, the sub-display pixel 180a may be the red sub-display pixel R, the sub-display pixel 180b may be the green sub-display pixel G, and the sub-display pixel 180c may be the blue sub-display pixel B.

FIG. 29F illustrates an example in which the top surface of each sub-display pixel has a substantially tetragonal shape with rounded corners, and FIG. 29G illustrates an example in which the top surface of each sub-display pixel has a circular shape.

Although the sub-display pixel 180a, the sub-display pixel 180b, and the sub-display pixel 180c are used as display pixels in the above description of the pixel layouts shown in FIG. 29A to FIG. 29G, one or more sub-display pixels selected from the sub-display pixel 180a, the sub-display pixel 180b, and the sub-display pixel 180c may be alternatively used as an image capturing pixel.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a sub-display pixel can have a polygonal shape with rounded corners, an elliptical shape, or a circular shape in some cases.

Furthermore, in the method for fabricating the display apparatus of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, or a circular shape. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance such that a transferred pattern agrees with a design pattern (OPC (Optical Proximity Correction) technique) may be used. Specifically, with the OPC technique, a pattern for correction is added to a corner portion or the like of a figure on a mask pattern.

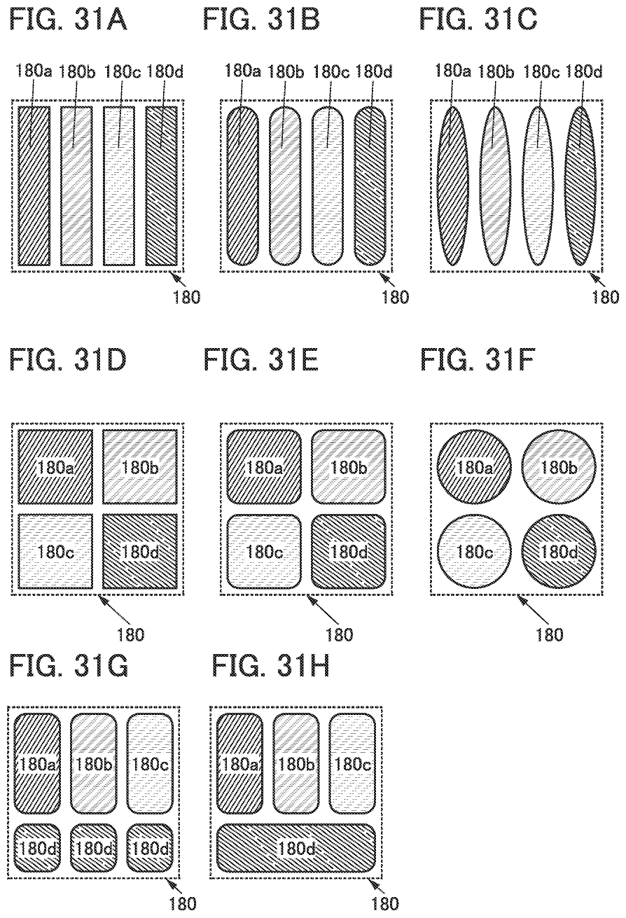

The pixel 180 illustrated in each of FIG. 31A to FIG. 31C employs stripe arrangement.

FIG. 31A illustrates an example in which each sub-display pixel has a rectangular top surface shape, FIG. 31B illustrates an example in which each sub-display pixel has a top surface shape formed by combining two half circles and a rectangle, and FIG. 31C illustrates an example in which each sub-display pixel has an elliptical top surface shape.

The pixel 180 illustrated in each of FIG. 31D to FIG. 31F employs matrix arrangement.

FIG. 31D illustrates an example in which each sub-display pixel has a square top surface shape, FIG. 31E illustrates an example in which each sub-display pixel has a substantially square top surface shape with rounded corners, and FIG. 31F illustrates an example in which each sub-display pixel has a circular top surface shape.

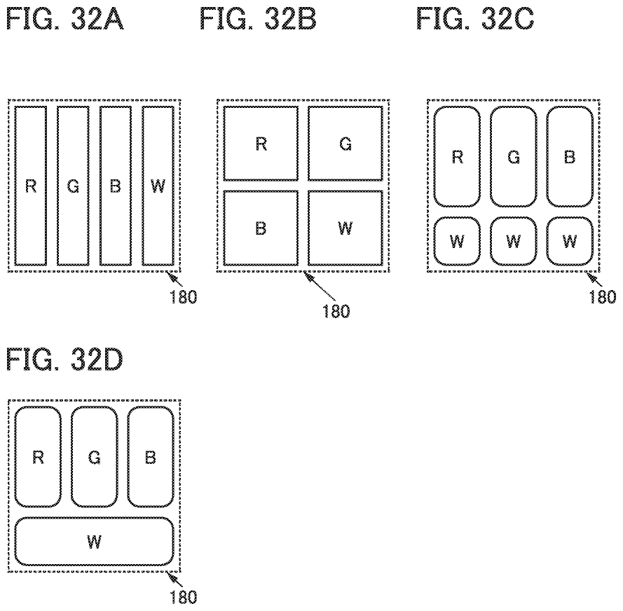

The pixel 180 illustrated in each of FIG. 31A to FIG. 31F is composed of four sub-display pixels: the sub-display pixel 180a, the sub-display pixel 180b, the sub-display pixel 180c, and a sub-display pixel 180d. The sub-display pixel 180a, the sub-display pixel 180b, the sub-display pixel 180c, and the sub-display pixel 180d emit light of different colors. For example, the sub-display pixel 180a, the sub-display pixel 180b, the sub-display pixel 180c, and the sub-display pixel 180d can be red, green, blue, and white sub-display pixels, respectively, as illustrated in FIG. 32A and FIG. 32B. Alternatively, the sub-display pixel 180a, the sub-display pixel 180b, the sub-display pixel 180c, and the sub-display pixel 180d can be red-, green-, blue-, and infrared-light-emitting sub-display pixels, respectively.

The sub-display pixel 180d includes a light-emitting device. The light-emitting device includes, for example, a pixel electrode, an EL layer, and the conductor 121CM functioning as a common electrode. For the pixel electrode, a material similar to those for the conductor 121a, the conductor 121b, the conductor 121c, the conductor 122a, the conductor 122b, and the conductor 122c can be used. For the EL layer, a material similar to that for the EL layer 141a, the EL layer 141b, or the EL layer 141c can be used, for example.

FIG. 31G illustrates an example in which one pixel 180 is composed of two rows and three columns. The pixel 180 includes three sub-display pixels (the sub-display pixel 180a, the sub-display pixel 180b, and the sub-display pixel 180c) in the upper row (first row) and three of the sub-display pixels 180d in the lower row (second row). In other words, the pixel 180 includes the sub-display pixel 180a and the sub-display pixel 180d in the left column (first column), the sub-display pixel 180b and another sub-display pixel 180d in the center column (second column), and the sub-display pixel 180c and another sub-display pixel 180d in the right column (third column). Aligning the positions of the sub-display pixels in the upper row and the lower row as illustrated in FIG. 31G enables dust and the like that would be produced in the manufacturing process to be removed efficiently. Thus, a display apparatus with high display quality can be provided.

FIG. 31H illustrates an example in which one pixel 180 is composed of two rows and three columns. The pixel 180 includes three sub-display pixels (the sub-display pixel 180a, the sub-display pixel 180b, and the sub-display pixel 180c) in the upper row (first row) and one sub-display pixel (the sub-display pixel 180d) in the lower row (second row). In other words, the pixel 180 includes the sub-display pixel 180a in the left column (first column), the sub-display pixel 180b in the center column (second column), the sub-display pixel 180c in the right column (third column), and the sub-display pixel 180d across these three columns.

In the pixel 180 illustrated in each of FIG. 31G and FIG. 31H, for example, the sub-display pixel 180a can be the red sub-display pixel R, the sub-display pixel 180b can be the green sub-display pixel G, the sub-display pixel 180c can be the blue sub-display pixel B, and the sub-display pixel 180d can be a white sub-display pixel W, as illustrated in FIG. 32C and FIG. 32D.

The display apparatus of one embodiment of the present invention may include a light-receiving device in the pixel.

Three of the four sub-display pixels included in the pixel 180 illustrated in FIG. 31G may each include a light-emitting device and the other one may include a light-receiving device. For example, in Embodiment 1, the three light-emitting devices included in the pixel 180 may be applied to the circuit PX_R, the circuit PX_G, and the circuit PX_B in FIG. 5C, and the light-receiving device included in the pixel 180 may be applied to the circuit PV in FIG. 5C.

For example, a pn-type or pin-type light-receiving device can be used as the light-receiving device. The light-receiving device functions as a photoelectric conversion device (also referred to as a photoelectric conversion element) that detects light incident on the light-receiving device and generates charge. The amount of charge generated from the light-receiving device depends on the amount of light incident on the light-receiving device.

It is particularly preferable to use, as the light-receiving device, an organic light-receiving device including a layer containing an organic compound. An organic light-receiving device, which is easily made thin, lightweight, and large in area and has a high degree of freedom for shape and design, can be used in a variety of display apparatuses.

In one embodiment of the present invention, an organic EL device is used as the light-emitting device, and an organic light-receiving device is used as the light-receiving device. The organic EL device and the organic light-receiving device can be formed over one substrate. Thus, the organic light-receiving device can be incorporated in the display apparatus that includes the organic EL device.

The light-receiving device includes at least an active layer that functions as a photoelectric conversion layer between a pair of electrodes. In this specification and the like, one of the pair of electrodes may be referred to as a pixel electrode and the other may be referred to as a common electrode.

For example, the sub-display pixel 180a, the sub-display pixel 180b, and the sub-display pixel 180c may be sub-display pixels for three colors of R, G, and B, and the sub-display pixel 180d may be a sub-display pixel including the light-receiving device. In that case, a fourth layer includes at least an active layer.

One of the pair of electrodes of the light-receiving device functions as an anode, and the other electrode functions as a cathode. Hereinafter, the case where the pixel electrode functions as an anode and the common electrode functions as a cathode is described as an example. When the light-receiving device is driven by application of reverse bias between the pixel electrode and the common electrode, light incident on the light-receiving device can be detected and charge can be generated and extracted as current. Alternatively, the pixel electrode may function as a cathode and the common electrode may function as an anode.

A fabrication method similar to that of the light-emitting device can be employed for the light-receiving device. An island-shaped active layer (also referred to as a photoelectric conversion layer) included in the light-receiving device is formed by processing a film that is to be the active layer and formed on the entire surface, not by using a pattern of a metal mask; thus, the island-shaped active layer with a uniform thickness can be formed. In addition, a mask layer provided over the active layer can reduce damage to the active layer in the fabrication process of the display apparatus, increasing the reliability of the light-receiving device.

Here, a layer shared by the light-receiving device and the light-emitting device might have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device might have the same function in both the light-emitting device and the light-receiving device. A hole-transport layer functions as a hole-transport layer in both the light-emitting device and the light-receiving device, and an electron-transport layer functions as an electron-transport layer in both the light-emitting device and the light-receiving device.

The active layer included in the light-receiving device includes a semiconductor. Examples of the semiconductor include an inorganic semiconductor such as silicon and an organic semiconductor including an organic compound. This embodiment describes an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

Examples of an n-type semiconductor material contained in the active layer include electron-accepting organic semiconductor materials such as fullerene (e.g., C₆₀ and C₇₀) and fullerene derivatives. Fullerene has a soccer ball-like shape, which is energetically stable. Both the HOMO (highest occupied molecular orbital) level and the LUMO (lowest unoccupied molecular orbital) level of fullerene are deep (low). Having a deep LUMO level, fullerene has an extremely high electron-accepting property (acceptor property). When I-electron conjugation (resonance) spreads on a plane as in benzene, an electron-donating property (donor property) usually becomes high; however, having a spherical shape, fullerene has a high electron-accepting property despite x-electron conjugation widely spreading therein. The high electron-accepting property efficiently causes rapid charge separation and is advantageous to the light-receiving device. Both C₆₀ and C₇₀ have a wide absorption band in the visible light range, and C₇₀ is especially preferable because of having a larger π-electron conjugated system and a wider absorption band in the long wavelength range than C₆₀. Other examples of fullerene derivatives include [6,6]-Phenyl-C71-butyric acid methyl ester (abbreviation: PC70BM), [6,6]-Phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C60 (abbreviation: ICBA).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper (II) phthalocyanine (CuPc), tetraphenyldibenzoperiflanthene (DBP), zinc phthalocyanine (ZnPc), tin phthalocyanine (SnPc), and quinacridone.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For example, the active layer is preferably formed by co-evaporation of an n-type semiconductor and a p-type semiconductor. Alternatively, the active layer may be formed by stacking an n-type semiconductor and a p-type semiconductor.

In addition to the active layer, the light-receiving device may further include a layer containing any of a substance with a high hole-transport property, a substance with a high electron-transport property, a substance with a bipolar property (a substance with a high electron-transport property and a high hole-transport property), and the like. Without limitation to the above, a layer containing one or more selected from a substance with a high hole-injection property, a hole-blocking material, a material with a high electron-injection property, and an electron-blocking material may be further included.

Either a low molecular compound or a high molecular compound can be used in the light-receiving device, and an inorganic compound may also be included. Each layer included in the light-receiving device can be formed by a method such as an evaporation method (including a vacuum evaporation method), a transfer method, a printing method, an inkjet method, or a coating method.

As the hole-transport material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material, an inorganic compound such as zinc oxide (ZnO) can be used.

For the active layer, a high molecular compound such as Poly[[4,8-bis[5-(2-ethylhexyl)-2-thienyl] benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′] dithiophene-1,3-diyl]] polymer (abbreviation: PBDB-T) or a PBDB-T derivative, which functions as a donor, can be used. For example, a method in which an acceptor material is dispersed in PBDB-T or a PBDB-T derivative can be used.

The active layer may contain a mixture of three or more kinds of materials. For example, a third material may be mixed with an n-type semiconductor material and a p-type semiconductor material in order to extend the wavelength range. In that case, the third material may be a low molecular compound or a high molecular compound.

In the display apparatus that includes the light-emitting device and the light-receiving device in the pixel, the pixel has a light-receiving function; thus, the display apparatus can detect touch or proximity of an object while displaying an image. For example, all the sub-display pixels included in the display apparatus can display an image; alternatively, some of the sub-display pixels can emit light as a light source and the other sub-display pixels can display an image.

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or proximity or touch of an object (e.g., a finger, a hand, or a pen) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced.

In the display apparatus of one embodiment of the present invention, when an object reflects (or scatters) light emitted from the light-emitting device included in the display portion, the light-receiving device can detect the reflected light (or scattered light); thus, image capturing or touch detection is possible even in a dark place.

In the case where the light-receiving devices are used as the image sensor, the display apparatus can capture an image with the use of the light-receiving devices. For example, the display apparatus of this embodiment can be used as a scanner.

For example, data on biological information such as a fingerprint or a palm print can be obtained with the use of the image sensor. That is, a biometric authentication sensor can be incorporated in the display apparatus. When the display apparatus incorporates a biometric authentication sensor, the number of components of an electronic device can be reduced as compared to the case where a biometric authentication sensor is provided separately from the display apparatus; thus, the size and weight of the electronic device can be reduced.

In the case where the light-receiving devices are used as the touch sensor, the display apparatus can detect proximity or touch of an object with the use of the light-receiving devices.

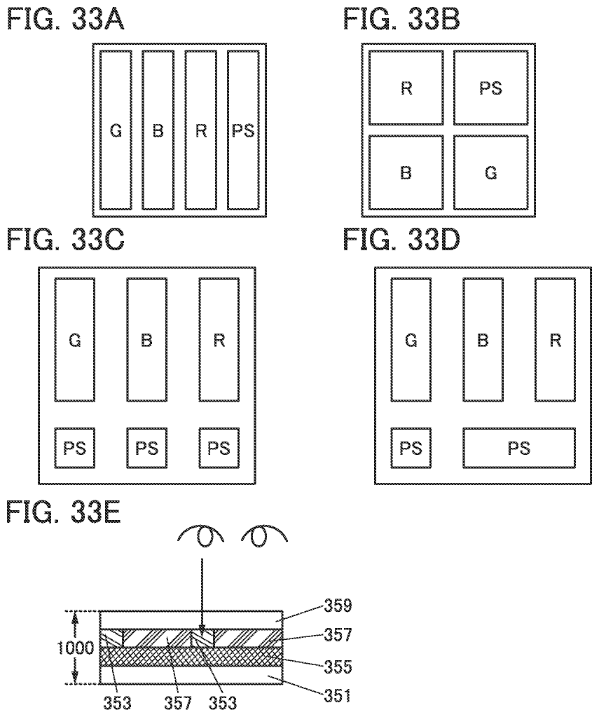

Pixels illustrated in FIG. 33A to FIG. 33D each include the sub-display pixel G, the sub-display pixel B, the sub-display pixel R, and an image capturing pixel PS.

The pixel illustrated in FIG. 33A employs stripe arrangement. The pixel illustrated in FIG. 33B employs matrix arrangement.

FIG. 33C and FIG. 33D each illustrate an example in which one pixel is provided in two rows and three columns. Three sub-display pixels (the sub-display pixel G, the sub-display pixel B, and the sub-display pixel R) are provided in the upper row (first row). In FIG. 33C, three of the image capturing pixels PS are provided in the lower row (second row). In FIG. 33D, two of the image capturing pixels PS are provided in the lower row (second row). Aligning the positions of the pixels in the upper row and the lower row as illustrated in FIG. 33C enables dust and the like that would be produced in the manufacturing process to be removed efficiently. Thus, a display apparatus with high display quality can be provided. Note that the layout of the pixels is not limited to the structures illustrated in FIG. 33A to FIG. 33D.

Each of the sub-display pixel R, the sub-display pixel G, and the sub-display pixel B includes a light-emitting device that emits white light. In each of the sub-display pixel R, the sub-display pixel G, and the sub-display pixel B, the corresponding coloring layer is provided to overlap with the light-emitting device.

The image capturing pixel PS includes a light-receiving device. There is no particular limitation on the wavelength of light detected by the image capturing pixel PS.

The light-receiving device included in the image capturing pixel PS preferably detects visible light, and preferably detects one or more selected from blue light, violet light, bluish violet light, green light, yellowish green light, yellow light, orange light, and red light. The light-receiving device included in the image capturing pixel PS may detect infrared light.

The display apparatus 1000 illustrated in FIG. 33E includes, between a substrate 351 and a substrate 359, a layer 353 including a light-receiving device, a functional layer 355, and a layer 357 including a light-emitting device.

The functional layer 355 includes a circuit for driving a light-receiving device and a circuit for driving a light-emitting device. For example, one or more selected from a switch, a transistor, a capacitor, a resistor, a wiring, and a terminal can be provided in the functional layer 355. Note that in the case where the light-emitting device and the light-receiving device are driven by a passive-matrix method, a structure including neither a switch nor a transistor may be employed.

For example, after light emitted from the light-emitting device in the layer 357 including the light-emitting device is reflected by a human eye and its surroundings as illustrated in FIG. 33E, the light-receiving device in the layer 353 including the light-receiving device detects the reflected light. Accordingly, information on the surroundings, surface, or inside of the human eye (e.g., the number of blinks, the movement of an eyeball, or the movement of an eyelid) can be detected.

Note that the insulators, the conductors, the semiconductors, and the like disclosed in this specification and the like can be formed by a PVD (Physical Vapor Deposition) method or a CVD method. Examples of a PVD method include a sputtering method, a resistance heating evaporation method, an electron beam evaporation method, and a PLD method. Examples of the CVD method include a plasma CVD method and a thermal CVD method. In particular, examples of a thermal CVD method include an MOCVD (Metal Organic Chemical Vapor Deposition) method and an ALD method.

A thermal CVD method, which is a film formation method not using plasma, has an advantage that a defect due to plasma damage is not generated.

Film formation by a thermal CVD method may be performed in the following manner: a source gas and an oxidizer are supplied into a chamber at a time, the pressure in the chamber is set to an atmospheric pressure or a reduced pressure, and they are made to react with each other in the vicinity of the substrate or over the substrate to be deposited on the substrate.

Film formation by an ALD method may be performed in the following manner: the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of the plurality of kinds of source gases, an inert gas (e.g., argon or nitrogen) or the like is introduced at the same time as or after the introduction of a first source gas and then a second source gas is introduced. Note that in the case where the first source gas and the inert gas are introduced at a time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on the surface of the substrate to form a first thin layer, and then the second source gas is introduced to react with the first thin layer; as a result, a second thin layer is stacked over the first thin layer, so that a thin film is formed. The sequence of the gas introduction is controlled and repeated a plurality of times until a desired thickness is obtained, so that a thin film with excellent step coverage can be formed. The thickness of the thin film can be adjusted by the number of repetition times of the sequence of the gas introduction; therefore, an ALD method makes it possible to accurately adjust the film thickness and is thus suitable for fabricating a minute FET.

A variety of films such as the metal film, the semiconductor film, and the inorganic insulating film disclosed in the above-described embodiments can be formed by a thermal CVD method such as an MOCVD method and an ALD method; for example, in the case of forming an In—Ga—Zn—O film, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can also be used instead of trimethylgallium, and diethylzinc (Zn(C₂H₅)₂) can also be used instead of dimethylzinc.

For example, in the case where a hafnium oxide film is formed with a film formation apparatus utilizing an ALD method, two kinds of gases, ozone (O₃) as an oxidizer and a source gas which is obtained by vaporizing liquid containing a solvent and a hafnium precursor compound (e.g., hafnium alkoxide or hafnium amide such as tetrakis(dimethylamide)hafnium (TDMAH, Hf[N(CH₃)_{2]4})), are used. Examples of another material include tetrakis(ethylmethylamide)hafnium.

For example, in the case where an aluminum oxide film is formed with a film formation apparatus utilizing an ALD method, two kinds of gases, H₂O as an oxidizer and a source gas which is obtained by vaporizing liquid containing a solvent and an aluminum precursor compound (e.g., trimethylaluminum (TMA, Al(CH₃)₃)), are used. Examples of another material include tris(dimethylamide)aluminum, triisobutylaluminum, and aluminum tris(2,2,6,6-tetramethyl-3,5-heptanedionate).

For example, in the case where a silicon oxide film is formed by a film formation apparatus utilizing an ALD method, hexachlorodisilane is adsorbed on a surface on which a film is to be formed, and radicals of an oxidizing gas (e.g., O₂ or dinitrogen monoxide) are supplied to react with the adsorbate.

For example, in the case where a tungsten film is formed by a film formation apparatus utilizing an ALD method, a WF₆ gas and a B₂H₆ gas are sequentially and repeatedly introduced to form an initial tungsten film, and then a WF₆ gas and an H₂ gas are sequentially and repeatedly introduced to form a tungsten film. Note that a SiH₄ gas may be used instead of a B₂H₆ gas.

In the case where an In—Ga—Zn—O film is formed as an oxide semiconductor film with a film formation apparatus utilizing an ALD method, for example, a precursor (generally referred to as a metal precursor or the like in some cases) and an oxidizer (generally referred to as a reactant, a non-metal precursor, or the like in some cases) are sequentially and repeatedly introduced. Specifically, for example, an In(CH₃)₃ gas as a precursor and an O₃ gas as an oxidizer are introduced to form an In—O layer; a Ga(CH₃)₃ gas as a precursor and an O₃ gas as an oxidizer are introduced to form a GaO layer; and then, a Zn(CH₃)₂ gas as a precursor and an O₃ gas as an oxidizer are introduced to form a ZnO layer. Note that the order of these layers is not limited to this example. A mixed oxide layer such as an In—Ga—O layer, an In—Zn—O layer, or a Ga—Zn—O layer may be formed with the use of these gases. Note that although an H₂O gas which is obtained by bubbling water with an inert gas such as Ar may be used instead of an O₃ gas, it is preferable to use an O₃ gas which does not contain H. Furthermore, instead of an In(CH₃)₃ gas, an In(C₂H₅)₃ gas may be used. Furthermore, instead of a Ga(CH₃)₃ gas, a Ga(C₂H₅)₃ gas may be used. Furthermore, instead of a Zn(CH₃)₂ gas, a Zn(C₂H₅)₂ gas may be used.

There is no particular limitation on the screen ratio (aspect ratio) of the display portion of the electronic device of one embodiment of the present invention. For example, the display portion is compatible with a variety of screen ratios such as 1:1 (a square), 4:3, 16:9, and 16:10.

There is no particular limitation on the shape of the display portion of the electronic device of one embodiment of the present invention. The display portion can have any of various shapes such as a rectangular shape, a polygonal shape (e.g., octagon), a circular shape, and an elliptical shape.

Note that this embodiment can be combined with any of the other embodiments described in this specification as appropriate.

### Embodiment 4

In this embodiment, a display module that can be used for the electronic device of one embodiment of the present invention will be described.

### <Structure Example of Display Module>

First, a display module including the display apparatus that can be used for the electronic device of one embodiment of the present invention will be described.

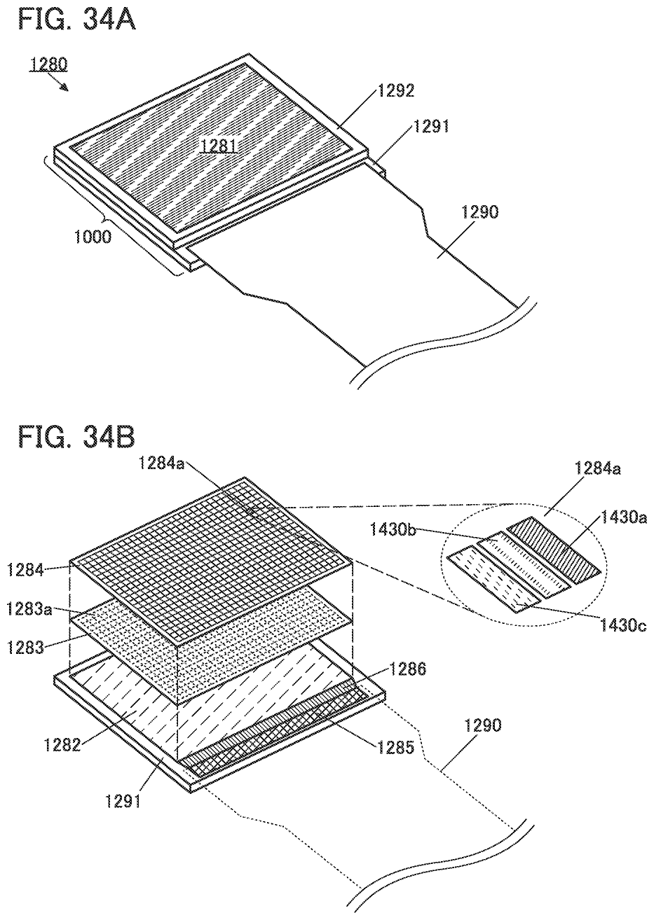

FIG. 34A is a perspective view of a display module 1280. The display module 1280 includes the display apparatus 1000 and an FPC 1290.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 34B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are electrically connected to each other through a wiring portion 1286 formed of a plurality of wirings.

Note that the pixel portion 1284 and the pixel circuit portion 1283 correspond to the pixel layer PXAL described above, for example. The circuit portion 1282 corresponds to the circuit layer SICL described above, for example.

The pixel portion 1284 includes a plurality of pixels 1284a arranged periodically. An enlarged view of one pixel 1284a is illustrated on the right side in FIG. 34B. The pixel 1284a includes a light-emitting device 1430a, a light-emitting device 1430b, and a light-emitting device 1430c that emit light of different colors. Note that the light-emitting device 1430a, the light-emitting device 1430b, and the light-emitting device 1430c correspond to the light-emitting device 150a, the light-emitting device 150b, and the light-emitting device 150c described above, for example. The above-described light-emitting devices may be arranged in a stripe pattern as illustrated in FIG. 34B. Alternatively, a variety of arrangement methods, such as delta arrangement and pentile arrangement, can be employed.

The pixel circuit portion 1283 includes a plurality of pixel circuits 1283a arranged periodically.

One pixel circuit 1283a is a circuit that controls light emission from three light-emitting devices included in one pixel 1284a. One pixel circuit 1283a may be provided with three circuits each of which controls light emission from one light-emitting device. For example, the pixel circuit 1283a can include one or more selected from one selection transistor, one current control transistor (driving transistor), and a capacitor for one light-emitting device. In that case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, one or both of a gate line driver circuit and a source line driver circuit are preferably included. In addition, one or more selected from an arithmetic circuit, a memory circuit, and a power supply circuit may be included.

The FPC 1290 functions as a wiring for supplying a video signal or a power supply potential to the circuit portion 1282 from the outside. In addition, an IC may be mounted on the FPC 1290.

The display module 1280 can have a structure in which one or both of the pixel circuit portion 1283 and the circuit portion 1282 are stacked below the pixel portion 1284; thus, the aperture ratio (the effective display area ratio) of the display portion 1281 can be significantly high. For example, the aperture ratio of the display portion 1281 can be higher than or equal to 40% and lower than 100%, preferably higher than or equal to 50% and lower than or equal to 95%, further preferably higher than or equal to 60% and lower than or equal to 95%. Furthermore, the pixels 1284a can be arranged extremely densely and thus, the display portion 1281 can have an extremely high resolution. For example, the pixels 1284a are preferably arranged in the display portion 1281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 1280 has an extremely high resolution and thus can be suitably used for a VR device such as a head-mounted display or a glasses-type AR device. For example, even with a structure in which the display portion of the display module 1280 is seen through a lens, pixels of the extremely-high-resolution display portion 1281 included in the display module 1280 are prevented from being perceived when the display portion is enlarged by the lens, so that display providing a strong sense of immersion can be performed. Without being limited thereto, the display module 1280 can be suitably used for electronic devices including relatively small display portions. For example, the display module 1280 can be suitably used for a display portion of a wearable electronic device such as a wristwatch.

Note that this embodiment can be combined with any of the other embodiments described in this specification as appropriate.

### Embodiment 5

In this embodiment, examples of electronic devices each including a display apparatus will be described as examples of an electronic device of one embodiment of the present invention.

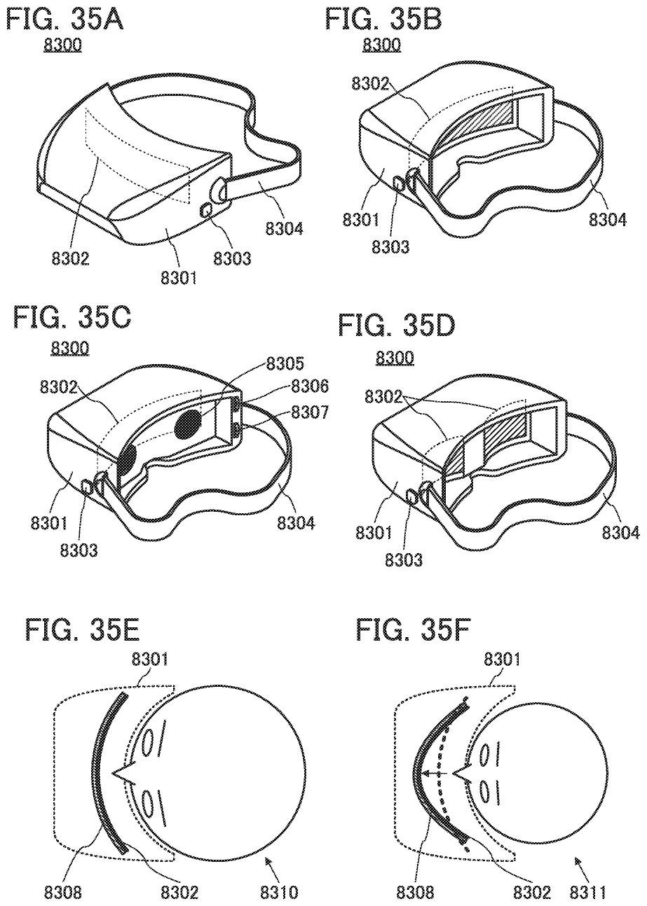

FIG. 35A and FIG. 35B each illustrate an appearance of an electronic device 8300 that is a head-mounted display.

The electronic device 8300 includes a housing 8301, a display portion 8302, an operation button 8303, and a band-shaped fixing unit 8304.

The operation button 8303 has a function of a power button or the like. The electronic device 8300 may include a button other than the operation button 8303.

As illustrated in FIG. 35C, lenses 8305 may be included between the display portion 8302 and the positions of the user's eyes. The user can see magnified images on the display portion 8302 through the lenses 8305, leading to a higher realistic sensation. In that case, as illustrated in FIG. 35C, a dial 8306 for changing the positions of the lenses and adjusting visibility may be included.

For the display portion 8302, a display apparatus with an extremely high resolution is preferably used, for example. When a high-resolution display apparatus is used for the display portion 8302, it is possible to display a more realistic video that does not allow the user to perceive pixels even when the video is magnified using the lenses 8305 as illustrated in FIG. 35C.

FIG. 35A to FIG. 35C illustrate an example in which one display portion 8302 is provided. Such a structure can reduce the number of components.

The display portion 8302 can display an image for the right eye and an image for the left eye side by side on a right region and a left region, respectively. Thus, a three-dimensional video using binocular disparity can be displayed.

One image that can be seen by both eyes may be displayed on the entire display portion 8302. A panorama video can thus be displayed from end to end of the field of view, which can provide a stronger sense of reality.

Here, the electronic device 8300 preferably has, for example, a mechanism for changing the curvature of the display portion 8302 to an optimal value in accordance with the size of the user's head, the positions of the user's eyes, or the like. For example, the user himself or herself may adjust the curvature of the display portion 8302 by operating a dial 8307 for adjusting the curvature of the display portion 8302. Alternatively, a sensor for detecting the size of the user's head, the positions of the user's eyes, or the like (e.g., a camera, a contact sensor, or a noncontact sensor) may be provided on the housing 8301, and a mechanism for adjusting the curvature of the display portion 8302 on the basis of detection data obtained by the sensor may be provided.

In the case where the lenses 8305 are used, a mechanism for adjusting the positions and angles of the lenses 8305 in synchronization with the curvature of the display portion 8302 is preferably provided. Alternatively, the dial 8306 may have a function of adjusting the angles of the lenses.

FIG. 35E and FIG. 35F illustrate an example in which a driver portion 8308 controlling the curvature of the display portion 8302 is provided. The driver portion 8308 is fixed to at least part of the display portion 8302. The driver portion 8308 has a function of changing the shape of the display portion 8302 when the part that is fixed to the display portion 8302 changes in shape or moves.

FIG. 35E is a schematic view illustrating the case where a user 8310 having a relatively large head wears the housing 8301. In this case, the driver portion 8308 adjusts the shape of the display portion 8302 such that the curvature is relatively small (the radius of curvature is large). By contrast, FIG. 35F illustrates the case where a user 8311 having a smaller head than the user 8310 wears the housing 8301. The user 8311 has a shorter distance between the eyes than the user 8310. In this case, the driver portion 8308 adjusts the shape of the display portion 8302 such that the curvature of the display portion 8302 is large (the radius of curvature is small). In FIG. 35F, the position and shape of the display portion 8302 in FIG. 35E are denoted by a dashed line.

When the electronic device 8300 has such a mechanism for adjusting the curvature of the display portion 8302, optimal display can be offered to a variety of users of all ages and genders.

When the curvature of the display portion 8302 is changed in accordance with contents displayed on the display portion 8302, the user can have a more realistic sensation. For example, shaking can be expressed by fluctuating the curvature of the display portion 8302. In this way, it is possible to produce various effects depending on the scene in contents, and provide the user with new experiences. Further realistic display can be achieved when the display portion 8302 operates in conjunction with a vibration module provided in the housing 8301.

Note that the electronic device 8300 may include two of the display portions 8302 as illustrated in FIG. 35D.

Since the two display portions 8302 are included, the user's eyes can see their respective display portions. This allows a high-definition video to be displayed even when three-dimensional display using parallax is performed, for example. In addition, the display portion 8302 is curved around an arc with the user's eye as an approximate center. This allows a uniform distance between the user's eye and the display surface of the display portion; thus, the user can see a more natural video. Even when the luminance or chromaticity of light from the display portion is changed depending on the angle at which the user sees it, since the user's eye is positioned in a normal direction of the display surface of the display portion, the influence of the change can be substantially ignorable and thus a more realistic video can be displayed.

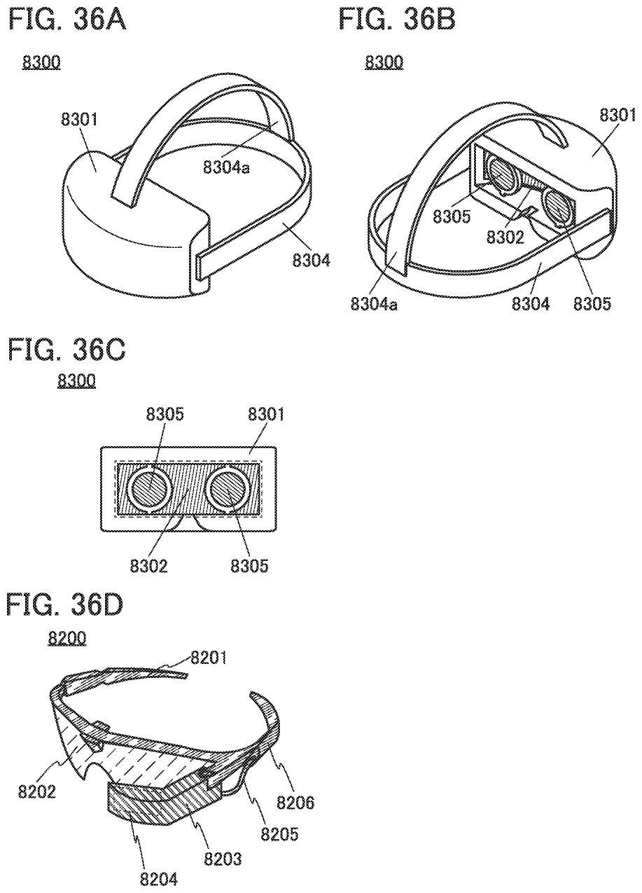

FIG. 36A to FIG. 36C are diagrams illustrating an appearance of another electronic device 8300, which is different from the electronic devices 8300 illustrated in FIG. 35A to FIG. 35D. Specifically, FIG. 36A to FIG. 36C are different from FIG. 35A to FIG. 35D in including a fixing unit 8304a to be worn on a head and a pair of lenses 8305, for example.

A user can see display on the display portion 8302 through the lenses 8305. The display portion 8302 is preferably curved, in which case the user can feel high realistic sensation. Another image displayed on another region of the display portion 8302 is seen through the lenses 8305, so that three-dimensional display using parallax can be performed, for example. Note that the structure is not limited to the structure in which one display portion 8302 is provided; two of the display portions 8302 may be provided and one display portion may be provided per eye of the user.

For the display portion 8302, a display apparatus with an extremely high resolution is preferably used, for example. When a high-resolution display apparatus is used for the display portion 8302, it is possible to display a more realistic video that does not allow the user to perceive pixels even when the video is magnified using the lenses 8305 as illustrated in FIG. 36C.

The head-mounted display, which is an electronic device of one embodiment of the present invention, may be an electronic device 8200 illustrated in FIG. 36D, which is a glasses-type head-mounted display.

The electronic device 8200 includes a wearing portion 8201, a lens 8202, a main body 8203, a display portion 8204, and a cable 8205. A battery 8206 is incorporated in the wearing portion 8201.

The cable 8205 supplies power from the battery 8206 to the main body 8203. The main body 8203 includes a wireless receiver or the like and can display received video information on the display portion 8204. The main body 8203 includes a camera, and information on the movement of the eyeballs or the eyelids of the user can be used as an input means.

The wearing portion 8201 may include a plurality of electrodes capable of sensing current flowing accompanying with the movement of the user's eyeballs at a position in contact with the user to recognize the user's gaze. The wearing portion 8201 may also have a function of monitoring the user's pulse with use of current flowing through the electrodes. The wearing portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, and the like.

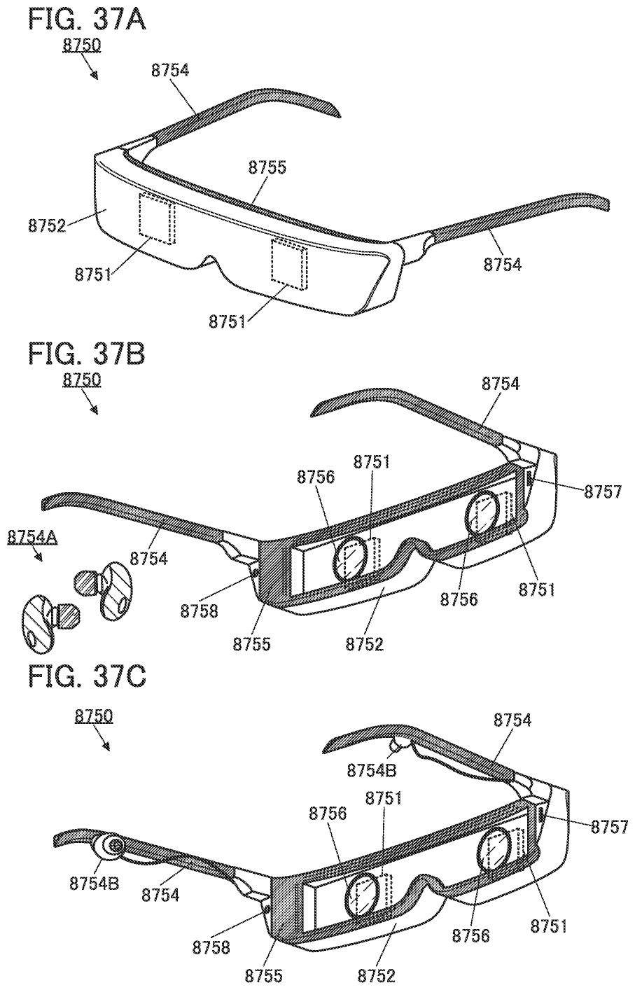

FIG. 37A to FIG. 37C are diagrams illustrating an appearance of an electronic device 8750, which is different from the electronic devices 8300 illustrated in FIG. 35A to FIG. 35D and FIG. 36A to FIG. 36C and the electronic device 8200 illustrated in FIG. 36D.

FIG. 37A is a perspective view illustrating the front surface, the top surface, and the left side surface of the electronic device 8750, and FIG. 37B and FIG. 37C are each a perspective view illustrating the back surface, the bottom surface, and the right side surface of the electronic device 8750.

The electronic device 8750 includes a pair of display apparatuses 8751, a housing 8752, a pair of wearing portions 8754, a cushion 8755, a pair of lenses 8756, and the like. The pair of display apparatuses 8751 are positioned to be seen through the lenses 8756 inside the housing 8752.

Here, one of the pair of display apparatuses 8751 corresponds to the display apparatus DSP illustrated in FIG. 10, for example. Although not illustrated, the electronic device 8750 illustrated in FIG. 37A to FIG. 37C includes an electronic component including the processing portion described in the above embodiment (e.g., the peripheral circuit PRPH described in Embodiment 1). Although not illustrated, the electronic device 8750 illustrated in FIG. 37A to FIG. 37C includes a camera (e.g., the image capturing pixel described in Embodiment 1). The camera can capture an image of the user's eye and its periphery. Although not illustrated, in the housing 8752 of the electronic device 8750 illustrated in FIG. 37A to FIG. 37C, a motion detection portion, an audio, a control portion, a communication portion, and a battery are provided.

The electronic device 8750 is an electronic device for VR. A user wearing the electronic device 8750 can see an image displayed on the display apparatus 8751 through the lenses 8756. Furthermore, the pair of display apparatuses 8751 may display different images, whereby three-dimensional display using parallax can be performed.

An input terminal 8757 and an output terminal 8758 are provided on the back side of the housing 8752. To the input terminal 8757, a cable for supplying a video signal from a video output device or power for charging a battery provided in the housing 8752 can be connected. The output terminal 8758 can function as, for example, an audio output terminal to which earphones or headphones can be connected.

The housing 8752 preferably includes a mechanism by which the left and right positions of the lenses 8756 and the display apparatus 8751 can be adjusted to the optimal positions in accordance with the position of the user's eye. In addition, the housing 8752 preferably includes a mechanism for adjusting focus by changing the distance between the lenses 8756 and the display apparatus 8751.

With use of the camera, the display apparatus 8751, and the electronic component, the electronic device 8750 can estimate the state of a user of the electronic device 8750 and can display information on the estimated user's state on the display apparatus 8751. Alternatively, information on a state of a user of an electronic device connected to the electronic device 8750 through a network can be displayed on the display apparatus 8751.

The cushion 8755 is a portion to be in contact with the user's face (e.g., forehead or cheek). When the cushion 8755 is in close contact with the user's face, light leakage can be prevented, which increases the sense of immersion. A soft material is preferably used for the cushion 8755 so that the cushion 8755 is in close contact with the face of the user wearing the electronic device 8750. For example, a material such as rubber, silicone rubber, urethane, or sponge can be used. Furthermore, when a sponge whose surface is covered with cloth, leather (e.g., natural leather or synthetic leather), or the like is used, a gap is unlikely to be generated between the user's face and the cushion 8755, whereby light leakage can be favorably prevented. Furthermore, using such a material is preferable because it has a soft texture and does not give cold feeling to the user wearing the device in a cold season, for example. The member to be in contact with the user's skin, such as the cushion 8755 or the wearing portion 8754, is preferably detachable, in which case cleaning or replacement can be easily performed.

The electronic device in this embodiment may further include earphones 8754A. The earphones 8754A include a communication portion (not illustrated) and have a wireless communication function. The earphones 8754A can output audio data with the wireless communication function. Note that the earphones 8754A may include a vibration mechanism to function as bone-conduction earphones.

Like earphones 8754B illustrated in FIG. 37C, the earphones 8754A can be connected to the wearing portion 8754 directly or by wiring. The earphones 8754B and the wearing portion 8754 may each have a magnet. This structure is preferably employed, in which case the earphones 8754B can be fixed to the wearing portion 8754 with magnetic force and thus can be easily housed.

The earphones 8754A may include a sensor portion. With use of the sensor portion, the state of the user of the electronic device can be estimated.

The electronic device of one embodiment of the present invention may include one or more selected from an antenna, a battery, a camera, a speaker, a microphone, a touch sensor, and an operation button, in addition to any one of the above example components.

The electronic device of one embodiment of the present invention may include a secondary battery, and it is preferable that the secondary battery be capable of being charged by contactless power transmission.

Examples of the secondary battery include a lithium ion secondary battery (e.g., a lithium polymer battery using a gel electrolyte (lithium ion polymer battery)), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display a video and information on a display portion. When the electronic device includes an antenna and a secondary battery, the antenna may be used for contactless power transmission.

A display portion in an electronic device of one embodiment of the present invention can display a video with a definition of, for example, full high definition, 4K2K, 8K4K, 16K8K, or higher.

Note that this embodiment can be combined with any of the other embodiments described in this specification as appropriate.

### REFERENCE NUMERALS

DSP: display apparatus, DSP_L: display apparatus, DSP_R: display apparatus, DIS: display portion, MA: image capturing region, LEA: image capturing light source region, STA: standby region, CSB: center portion, ARA: region, ARA[1,1]: region, ARA[1,2]: region, ARA[1,n−1]: region, ARA[1,n]: region, ARA[2,1]: region, ARA[2,2]: region, ARA[2,n−1]: region, ARA[2,n]: region, ARA[m−1,1]: region, ARA[m−1,2]: region, ARA[m−1,n−1]: region, ARA[m−1,n]: region, ARA[m,1]: region, ARA[m,2]: region, ARA[m,n−1]: region, ARA[m,n]: region, ARD[1,1]: circuit region, ARD[1,2]: circuit region, ARD[1,n−1]: circuit region, ARD[1,n]: circuit region, ARD[2,1]: circuit region, ARD[2,2]: circuit region, ARD[2,n−1]: circuit region, ARD[2,n]: circuit region, ARD[m−1,1]: circuit region, ARD[m−1,2]: circuit region, ARD[m−1,n−1]: circuit region, ARD[m−1,n]: circuit region, ARD[m,1]: circuit region, ARD[m,2]: circuit region, ARD[m,n−1]: circuit region, ARD[m,n]: circuit region, LIG: light, ME: user's eye, ME_L: left eye of user, ME_R: right eye of user, HMD: electronic device, KYT: housing, AP: circuit, PX: circuit, PX_L: circuit, PX_R: circuit, PX_G: circuit, PX_B: circuit, PV: circuit, SL: wiring, SL_R: wiring, SL_G: wiring, SL_B: wiring, OL: wiring, FS: wiring, PWL: wiring, SE: wiring, RS: wiring, TX: wiring, GL: wiring, CT1: wiring, CT2: wiring, PXAL: pixel layer, LINL: wiring layer, SICL: circuit layer, LIA: region, DRV: driver circuit region, BS: substrate, PRPH: peripheral circuit, SD: driver circuit, SDS: circuit, DMS: distribution circuit, GD: driver circuit, GDS: circuit, DMG: distribution circuit, RD: driver circuit, RDS: circuit, RMG: distribution circuit, TD: driver circuit, TDS: circuit, TMG: distribution circuit, CTR: control portion, MD: memory device, PG: voltage generation circuit, GPS: image processing portion, CKS: clock signal generation circuit, TMC: timing controller, BW: bus wiring, MCS: microscope, KYI: housing, CYL: cylindrical shape, CNE: conical shape, KKB: opening portion, RNS: lens, ISP: light-emitting apparatus, LGT1: light, LGT2: light, SMP: smartphone, USR: user, EML: layer, OSL: layer, GL1: wiring, GL2: wiring, GL3: wiring, V0: wiring, VCOM: wiring, ANO: wiring, R: sub-display pixel, G: sub-display pixel, B: sub-display pixel, W: sub-display pixel, PS: image capturing pixel, 30: circuit, 85R: hole-injection layer, 85G: hole-injection layer, 85B: hole-injection layer, 86R: hole-transport layer, 86G: hole-transport layer, 86B: hole-transport layer, 86PD: hole-transport layer, 87R: light-emitting layer, 87G: light-emitting layer, 87B: light-emitting layer, 88R: electron-transport layer, 88G: electron-transport layer, 88B: electron-transport layer, 88PD: electron-transport layer, 89: common layer, 90: light-receiving layer, 91: protective layer, 92: insulating layer, 102: substrate, 111: insulator, 111a: insulator, 111b: insulator, 112: insulator, 113: insulator, 113a: insulator, 113b: insulator, 113c: insulator, 118: mask layer, 119: mask layer, 121a: conductor, 121b: conductor, 121c: conductor, 121CM: conductor, 121B: conductor, 121G: conductor, 121R: conductor, 121PD: conductor, 122a: conductor, 122b: conductor, 122c: conductor, 123: conductor, 123CM: region, 141a: EL layer, 141b: EL layer, 141c: EL layer, 142: EL layer, 150a: light-emitting device, 150b: light-emitting device, 150c: light-emitting device, 150B: light-emitting device, 150G: light-emitting device, 150R: light-emitting device, 150IR: light-emitting device, 160: light-receiving device, 162: insulator, 163: resin layer, 164: adhesive layer, 165: adhesive layer, 166a: coloring layer, 166b: coloring layer, 166c: coloring layer, 170A: pixel, 170B: pixel, 180: pixel, 180a: sub-display pixel, 180b: sub-display pixel, 180c: sub-display pixel, 180d: sub-display pixel, 200: transistor, 202: insulator, 210: substrate, 214: insulator, 216: conductor, 220: insulator, 222: insulator, 224: insulator, 226: insulator, 228: conductor, 230: conductor, 250: insulator, 300: transistor, 310: substrate, 312: element isolation layer, 313: semiconductor region, 314a: low-resistance region, 314b: low-resistance region, 315: insulator, 316: conductor, 317: insulator, 320: insulator, 322: insulator, 324: insulator, 326: insulator, 328: conductor, 330: conductor, 350: insulator, 351: substrate, 352: insulator, 353: layer, 354: insulator, 355: functional layer, 356: conductor, 357: layer, 359: substrate, 360: insulator, 362: insulator, 364: insulator, 366: conductor, 370: insulator, 372: insulator, 376: conductor, 380: insulator, 400: pixel circuit, 400A: pixel circuit, 400B: pixel circuit, 400C: pixel circuit, 400D: pixel circuit, 400E: pixel circuit, 400F: pixel circuit, 400G: pixel circuit, 400H: pixel circuit, 410: driver circuit, 500: transistor, 500A: transistor, 500B: transistor, 500C: transistor, 500D: transistor, 501: substrate, 512: insulator, 514: insulator, 540: conductor, 576: insulator, 581: insulator, 600: capacitor, 600A: capacitor, 1000: display apparatus, 1280: display module, 1281: display portion, 1290: FPC, 1282: circuit portion, 1283: pixel circuit portion, 1283a: pixel circuit, 1284: pixel portion, 1284a: pixel, 1285: terminal portion, 1286: wiring portion, 1291: substrate, 1292: substrate, 1430a: light-emitting device, 1430b: light-emitting device, 1430c: light-emitting device, 4400a: light-emitting unit, 4400b: light-emitting unit, 4411: light-emitting layer, 4412: light-emitting layer, 4413: light-emitting layer, 4420: layer, 4420-1: layer, 4420-2: layer, 4430: layer, 4430-1: layer, 4430-2: layer, 4440: intermediate layer, 8200: electronic device, 8201: wearing portion, 8202: lens, 8203: main body, 8204: display portion, 8205: cable, 8206: battery, 8300: electronic device, 8301: housing, 8302: display portion, 8303: operation button, 8304: fixing unit, 8304a: fixing unit, 8305: lens, 8306: dial, 8307: dial, 8308: driver portion, 8310: user, 8311: user, 8750: electronic device, 8751: display apparatus, 8752: housing, 8754: wearing portion, 8754A: earphone, 8754B: earphone, 8756: lens, 8757: input terminal, 8758: output terminal

1. A display apparatus comprising:
a display portion comprising a first region and a second region,
wherein the first region comprises an image capturing pixel,
wherein the second region comprises a light-emitting pixel,
wherein the light-emitting pixel comprises a light-emitting device configured to emit one of infrared light and visible light,
wherein the image capturing pixel comprises a light-receiving device configured to receive light emitted from the light-emitting pixel,
wherein a center portion of the display portion is a region of a circle centered at an intersection of two diagonal lines running across the display portion,
wherein a radius of the circle is less than or equal to ⅛ of a length of one of the two diagonal lines of the display portion, and
wherein the first region comprises a region overlapping with the center portion.

2. The display apparatus according to claim 1,
wherein the second region has a tetragonal frame shape, and
wherein the first region is positioned inside the frame shape.

3. An electronic device comprising:
the display apparatus according to claim 1; and
a housing,
wherein the housing is shaped to be capable of being worn on a head of a human, and
wherein when the housing is worn on a head of a human, the first region comprises a region overlapping with an eye of the human in a front view.

4. An operation method of a light-emitting apparatus,
wherein the light-emitting apparatus comprises an image capturing portion comprising a plurality of light-emitting pixels and a plurality of image capturing pixels, the light-emitting pixels each comprising a light-emitting device emitting one of infrared light and visible light, the image capturing pixels each comprising a light-receiving device receiving one of infrared light and visible light,
wherein the operation method comprises a first step and a second step,
wherein the first step comprises a step of setting a first region, a second region, and a third region in the image capturing portion,
wherein the second step comprises a step of resetting, to the second region or the third region, the first region set in the image capturing portion, resetting, to the first region or the third region, the second region set in the image capturing portion, and resetting, to the first region or the second region, part of the third region set in the image capturing portion,
wherein in the first region, the light-receiving device performs image capturing,
wherein in the second region, the light-emitting device emits light, and
wherein in the third region, the light-emitting pixel and the image capturing pixel are in a standby state.

5. An operation method of a light-emitting apparatus,
wherein the light-emitting apparatus comprises an image capturing portion comprising a plurality of light-emitting pixels and a plurality of image capturing pixels, the light-emitting pixels each comprising a light-emitting device emitting one of infrared light and visible light, the image capturing pixels each comprising a light-receiving device receiving one of infrared light and visible light,
wherein the operation method comprises a first step and a second step,
wherein the first step comprises a step of setting a first region and a second region in the image capturing portion,
wherein the second step comprises a step of resetting, to the second region, the first region set in the image capturing portion, and resetting, to the first region, the second region set in the image capturing portion,
wherein in the first region, the light-receiving device performs image capturing, and
wherein in the second region, the light-emitting device emits light.
